(19) United States
(12) Patent Application Publication
(10) Pub. No.: US 2020/0274027 A1
(43) Pub. Date: Aug. 27, 2020

(54) LIGHT EMITTING DIODE AND MANUFACTURING METHOD THEREOF

(71) Applicant: Genesis Photonics Inc., Tainan City (TW)

(72) Inventors: Yi-Ru Huang, Tainan City (TW); Yu-Chen Kuo, Tainan City (TW); Sheng-Tsung Hsu, Tainan City (TW); Chih-Ming Shen, Tainan City (TW); Yao-Tang Li, Tainan City (TW); Tung-Lin Chuang, Tainan City (TW); Tsung-Syun Huang, Tainan City (TW); Jing-En Huang, Tainan City (TW)

(73) Assignee: Genesis Photonics Inc., Tainan City (TW)

(21) Appl. No.: 16/792,312

(22) Filed: Feb. 17, 2020

Related U.S. Application Data
(63) Continuation-in-part of application No. 15/727,545, filed on Oct. 6, 2017.
Application No. 15/727,545 is a continuation-in-part of application No. 15/045,279, filed on Feb. 17, 2016, now Pat. No. 10,038,121.
(60) Provisional application No. 62/805,974, filed on Feb. 15, 2019.
(60) Provisional application No. 62/923,638, filed on Oct. 21, 2019.
(60) Provisional application No. 62/405,257, filed on Oct. 7, 2016.
(60) Provisional application No. 62/116,923, filed on Feb. 17, 2015.
(60) Provisional application No. 62/151,377, filed on Apr. 22, 2015.
(60) Provisional application No. 62/168,921, filed on Jun. 1, 2015.

(30) Foreign Application Priority Data
Feb. 15, 2020 (TW) 109104901

(51) Int. Cl. H01L 33/10; H01L 33/64; H01L 33/40

(52) U.S. Cl. CPC H01L 33/10; H01L 33/405; H01L 33/644

(57) ABSTRACT

A light emitting diode and manufacturing method thereof are provided. The light emitting diode includes a first-type semiconductor layer, a light emitting layer, a second-type semiconductor layer, a first metal layer, a first current conducting layer, a first bonding layer and a second current conducting layer. The light emitting layer is located between the first-type semiconductor layer and the second-type semiconductor layer. The first metal layer is located on and electrically connected to the first-type semiconductor layer. The first metal layer is located between the first current conducting layer and the first-type semiconductor layer. The first current conducting layer is located between the first bonding layer and the first metal layer. The first current conducting layer is connected to the first-type semiconductor layer by the first current conducting layer and the first metal layer. The first bonding layer has through holes overlapped with the first metal layer. The second current conducting layer is electrically connected to the second-type semiconductor layer.

### CROSS-REFERENCE TO RELATED APPLICATION

This application is a continuation-in-part application of and claims the priority benefit of U.S. application Ser. No. 15/727,545, filed on Oct. 6, 2017, now pending, which claims the priority benefit of U.S. provisional application Ser. No. 62/405,257, filed on Oct. 7, 2016. The prior U.S. application Ser. No. 15/727,545 is a continuation-in-part application of and claims the priority benefit of U.S. application Ser. No. 15/045,279, filed on Feb. 17, 2016, now patented. The prior U.S. application Ser. No. 15/045,279 claims the priority benefits of U.S. provisional application Ser. No. 62/116,923, filed on Feb. 17, 2015, U.S. provisional application Ser. No. 62/151,377, filed on Apr. 22, 2015 and U.S. provisional application Ser. No. 62/168,921, filed on Jun. 1, 2015. This application also claims the priority benefits of U.S. provisional application Ser. No. 62/805,974, filed on Feb. 15, 2019 and U.S. provisional application Ser. No. 62/923,638, filed on Oct. 21, 2019. The entirety of each of the above-mentioned patent applications is hereby incorporated by reference herein and made a part of this specification.

### BACKGROUND OF THE INVENTION

### Field of the Invention

The invention relates to a semiconductor device a manufacturing method thereof, and more particularly, relates to a light emitting diode (LED) and a manufacturing method thereof.

### Description of Related Art

Generally speaking, LEDs include those applied to vertical packaging and those applied to flip chip packaging. The LED applied to flip chip packaging includes a first-type semiconductor layer, a light emitting layer, a second-type semiconductor layer, a first metal layer, a second metal layer, a first insulating layer, a first current conducting layer, a second current conducting layer, a second insulating layer, a first bonding layer, and a second bonding layer. The first-type semiconductor layer has a first portion and a second portion. The light emitting layer is disposed on the first portion of the first-type semiconductor layer. The second portion of the first-type semiconductor layer extends outward from the first portion to protrude outside the area of the light emitting layer. The second-type semiconductor layer is disposed on the light emitting layer. The first metal layer is disposed on the second portion of the first-type semiconductor layer and electrically connected to the first-type semiconductor layer. The second metal layer is disposed on the second-type semiconductor layer and electrically connected to the second-type semiconductor layer. The first insulating layer covers the first metal layer and the second metal layer, and has a plurality of through holes that respectively expose the first metal layer and the second metal layer. The first current conducting layer and the second current conducting layer are disposed on the first insulating layer and filled into the through holes of the first insulating layer to be electrically connected to the first metal layer and the second metal layer respectively. The second insulating layer covers the first current conducting layer and the second current conducting layer, and has a plurality of through holes that respectively overlap with the first current conducting layer and the second current conducting layer. The first bonding layer and the second bonding layer are disposed on the second insulating layer and filled into the through holes to be electrically connected to the first current conducting layer and the second current conducting layer respectively. The first bonding layer and the second bonding layer are for eutectic bonding to an external circuit board. However, in the process of eutectic bonding, the bonding material (e.g., solder paste) may easily penetrate into the LED from the interface between the second insulating layer and the first bonding layer and/or the interface between the second insulating layer and the second bonding layer, thereby causing a short circuit problem.

### SUMMARY OF THE INVENTION

The invention provides an LED having good performance.

In an embodiment of the invention, an LED includes a first-type semiconductor layer, a light emitting layer, a second-type semiconductor layer, a first metal layer, a first current conducting layer, a first bonding layer, and a second current conducting layer. The light emitting layer is located between the first-type semiconductor layer and the second-type semiconductor layer. The first metal layer is located on the first-type semiconductor layer and electrically connected to the first-type semiconductor layer. The first metal layer is located between the first current conducting layer and the first-type semiconductor layer. The first current conducting layer is located between the first bonding layer and the first metal layer. The first bonding layer is electrically connected to the first-type semiconductor layer via the first current conducting layer and the first metal layer. The first bonding layer has through holes that overlap with the first metal layer. The second current conducting layer is electrically connected to the second-type semiconductor layer.

In another embodiment of the invention, an LED includes a first-type semiconductor layer, a light emitting layer, a second-type semiconductor layer, a distributed Bragg reflector structure, a first metal layer, a first current conducting layer, a first insulating layer, a first bonding layer, and a second current conducting layer. The light emitting layer is located between the first-type semiconductor layer and the second-type semiconductor layer. The distributed Bragg reflector structure is disposed on the second-type semiconductor layer and overlaps with the light emitting layer. The first metal layer is located on the first-type semiconductor layer and electrically connected to the first-type semiconductor layer. The distributed Bragg reflector structure has a through hole, and the first metal layer is located in the through hole of the distributed Bragg reflector structure. The first current conducting layer is disposed on the distributed Bragg reflector structure and filled into the through hole of the distributed Bragg reflector structure to be electrically connected to the first metal layer. The first insulating layer is disposed on the first current conducting layer and has a through hole. The first bonding layer is disposed on the first insulating layer and filled into the through hole of the first insulating layer to be electrically connected to the first current conducting layer. The through hole of the distributed Bragg reflector structure and the through hole of the first insulating layer are displaced and do not overlap with each other. The second current conducting layer is electrically connected to the second-type semiconductor layer.

In an embodiment of the invention, the LED further includes: a first insulating layer located between the first current conducting layer and the first metal layer and having a plurality of through holes, wherein the first current conducting layer is filled into the through holes of the first insulating layer to be electrically connected to the first metal layer, an area of one through hole of the first insulating layer is smaller than the area of one through hole of the first bonding layer, and the through hole of the first insulating layer is located within the area of the through hole of the first bonding layer.

In an embodiment of the invention, an area of the first bonding layer is smaller than an area of the first current conducting layer and the first bonding layer is located within the area of the first current conducting layer.

In an embodiment of the invention, the LED further includes: a second metal layer and a second bonding layer. The second metal layer is located on the second-type semiconductor layer and electrically connected to the second-type semiconductor layer. The second current conducting layer is located between the second bonding layer and the second metal layer. The second bonding layer is electrically connected to the second-type semiconductor layer via the second current conducting layer and the second metal layer.

In an embodiment of the invention, the second bonding layer has a plurality of through holes, and the through holes of the second bonding layer overlap with the second metal layer.

In an embodiment of the invention, the LED further includes: a first insulating layer located between the second current conducting layer and the second metal layer and having a plurality of through holes, wherein the second current conducting layer is filled into the through holes of the first insulating layer to be electrically connected to the second metal layer, an area of one through hole of the first insulating layer is smaller than an area of one through hole of the second bonding layer, and the through hole of the first insulating layer is located within the area of the through hole of the second bonding layer.

In an embodiment of the invention, the first metal layer includes: a welding portion and a finger portion. The welding portion is electrically connected to the first current conducting layer. The finger portion extends outside the second current conducting layer from the welding portion, wherein the finger portion overlaps with the second bonding layer.

In an embodiment of the invention, the first metal layer includes: a welding portion and a finger portion. The welding portion is electrically connected to the first current conducting layer. The finger portion extends outside the first current conducting layer from the welding portion, wherein the second bonding layer has a recess, and the finger portion extends into an area of the recess of the second bonding layer.

In an embodiment of the invention, the first-type semiconductor layer includes: a first portion and a second portion. The light emitting layer is stacked on the first portion. The second portion extends outward from the first portion to protrude outside an area of the light emitting layer. The second portion of the first-type semiconductor layer has a first surface, a second surface opposite to the first surface, and a sidewall connected between the first surface and the second surface. The LED further includes: a first insulating layer covering the sidewall of the second portion of the first-type semiconductor layer.

In an embodiment of the invention, the first insulating layer further covers the second-type semiconductor layer and the first surface of the second portion of the first-type semiconductor layer, and the LED further includes a distributed Bragg reflector structure disposed on the first insulating layer and overlapping with the light emitting layer.

In an embodiment of the invention, the distributed Bragg reflector structure covers the sidewall of the second portion of the first-type semiconductor layer.

In an embodiment of the invention, the LED further includes: a second insulating layer. The distributed Bragg reflector structure is located between the first insulating layer and the second insulating layer, and the second insulating layer covers the sidewall of the second portion of the first-type semiconductor layer.

In an embodiment of the invention, the LED further includes: a third insulating layer covering the first current conducting layer. The first bonding layer is disposed on the third insulating layer, and the third insulating layer covers the sidewall of the second portion of the first-type semiconductor layer.

In an embodiment of the invention, the light emitting layer has a first surface, a second surface, and a sidewall. The second-type semiconductor layer is disposed on the first surface of the light emitting layer, the second surface is opposite to the first surface, and the sidewall is connected between the first surface and the second surface. The LED further includes: a distributed Bragg reflector structure. The first current conducting layer and the second current conducting layer are located on a same side of the distributed Bragg reflector structure. The distributed Bragg reflector structure includes: a plurality of first refractive layers and a plurality of second refractive layers stacked alternately, wherein a refractive index of each of the first refractive layers is different from a refractive index of each of the second refractive layers, and a stacked structure of the first refractive layers and the second refractive layers covers the sidewall of the light emitting layer.

In an embodiment of the invention, the LED further includes: a distributed Bragg reflector structure. The first current conducting layer and the second current conducting layer are located on a same side of the distributed Bragg reflector structure. The distributed Bragg reflector structure includes: a plurality of first refractive layers and a plurality of second refractive layers stacked alternately, wherein a refractive index of each of the first refractive layers is different from a refractive index of each of the second refractive layers, and a stacking density of the first refractive layers and the second refractive layers in an edge region of the distributed Bragg reflector structure is higher than a stacking density of the first refractive layers and the second refractive layers in an internal region of the distributed Bragg reflector structure.

In an embodiment of the invention, the LED further includes: a distributed Bragg reflector structure and a reflector structure. The first current conducting layer and the second current conducting layer are located on a same side of the distributed Bragg reflector structure. The reflector structure is located between the distributed Bragg reflector structure and the first current conducting layer and between the distributed Bragg reflector structure and the second current conducting layer, wherein the reflector structure is electrically isolated from the first current conducting layer and the second current conducting layer.

In an embodiment of the invention, the LED further includes: a first insulating layer and a second insulating layer. The first insulating layer covers the distributed Bragg reflector structure, wherein the reflector structure is disposed on the first insulating layer. The second insulating layer covers the reflector structure, wherein the first bonding layer is disposed on the second insulating layer. A main function of the reflector structure is to reflect. Although the reflector structure may include a conductive material, the reflector structure may not serve as a conductive path for conducting an electrical signal that drives the LED. An area of the reflector structure projected to the LED is smaller than or equal to an area of the distributed Bragg reflector structure projected to the LED.

In an embodiment of the invention, the reflector structure is directly disposed on the distributed Bragg reflector structure and in contact with the distributed Bragg reflector structure, and the LED further includes: a first insulating layer. The first insulating layer covers the reflector structure, wherein the first bonding layer is disposed on the first insulating layer.

In an embodiment of the invention, the LED further includes: a conductive layer disposed on the second-type semiconductor layer, wherein the second current conducting layer is electrically connected to the second-type semiconductor layer via the conductive layer, the conductive layer includes a plurality of conductive blocks, and the first metal layer separates the conductive blocks.

In an embodiment of the invention, the conductive blocks have a gap, and the first metal layer is located within an area of the gap.

In an embodiment of the invention, the first metal layer includes: a plurality of welding portions and a plurality of finger portions. The welding portions are electrically connected to the first current conducting layer. The finger portions extend outside the first current conducting layer from the welding portions, wherein each conductive block of the conductive layer is located between adjacent finger portions of the first metal layer.

In an embodiment of the invention, the LED further includes: a first insulating layer and a second insulating layer. The first insulating layer covers the distributed Bragg reflector structure, wherein the reflector structure is disposed on the first insulating layer. The second insulating layer covers the reflector structure, wherein the first bonding layer is disposed on the second insulating layer.

In an embodiment of the invention, the reflector structure is directly disposed on the distributed Bragg reflector structure and in contact with the distributed Bragg reflector structure. The LED further includes: a first insulating layer covering the reflector structure, wherein the first bonding layer is disposed on the first insulating layer.

In an embodiment of the invention, the LED further includes: a conductive layer disposed on the second-type semiconductor layer, wherein the second current conducting layer is electrically connected to the second-type semiconductor layer via the conductive layer, the conductive layer includes a plurality of conductive blocks, and the first metal layer separates the conductive blocks.

In an embodiment of the invention, the conductive blocks have a gap, and the first metal layer is located within an area of the gap.

In an embodiment of the invention, the first metal layer includes: a plurality of welding portions and a plurality of finger portions. The welding portions are electrically connected to the first current conducting layer. The finger portions extend outside the first current conducting layer from the welding portions, wherein each conductive block of the conductive layer is located between adjacent finger portions of the first metal layer.

In an embodiment of the invention, the second metal layer includes: a plurality of welding portions and a plurality of finger portions. The welding portions are electrically connected to the second current conducting layer. The finger portions extend outside the second current conducting layer from the welding portions, wherein at least one finger portion of the second metal layer is disposed within the area of each conductive block of the conductive layer.

In an embodiment of the invention, the conductive blocks are separated from one another.

In an embodiment of the invention, the conductive blocks are partially connected.

In an embodiment of the invention, the LED further includes a first insulating layer and a bump. The first insulating layer covers the second-type semiconductor layer, wherein the first current conducting layer and the second current conducting layer are disposed on the first insulating layer. The bump is disposed on a part of the first insulating layer on the second-type semiconductor layer. The bump and the first current conducting layer and the second current conducting layer are displaced, and a ductility of the bump is higher than a ductility of the first insulating layer. The bump may include a conductive or insulating material, but the bump may not serve as a conductive path for conducting an electrical signal that drives the LED. An area of the bump projected to the LED is smaller than or equal to an area of the bump projected to the LED.

In an embodiment of the invention, the LED further includes: a distributed Bragg reflector structure, wherein the first current conducting layer and the second current conducting layer are located on a same side of the distributed Bragg reflector structure, and the bump is disposed on a stacked structure of the second-type semiconductor layer, the distributed Bragg reflector structure, and the first insulating layer.

In an embodiment of the invention, a gap exists between the first current conducting layer and the second current conducting layer, and the bump is located within an area of the gap.

In an embodiment of the invention, the bump, the first current conducting layer, and the second current conducting layer belong to a same layer.

In an embodiment of the invention, the LED further includes: a second bonding layer, wherein the second current conducting layer is located between the second bonding layer and the second-type semiconductor layer, the second bonding layer is electrically connected to the second-type semiconductor layer via the second current conducting layer, and the bump and the first bonding layer and the second bonding layer are displaced.

In an embodiment of the invention, a gap exists between the first bonding layer and the second bonding layer, and the bump is located within an area of the gap.

In an embodiment of the invention, the bump, the first bonding layer, and the second bonding layer belong to a same layer.

In an embodiment of the invention, the bump, the first bonding layer, and the second current conducting layer are electrically isolated.

In an embodiment of the invention, the bump overlaps with a mass center line of the LED.

In an embodiment of the invention, the first metal layer includes a welding portion and a finger portion. The welding portion is electrically connected to the first current conducting layer. The finger portion extends outside the first current conducting layer from the welding portion. A width of the welding portion is larger than a width of the finger portion and the width of the welding portion changes gradually.

In an embodiment of the invention, the LED further includes: a second metal layer located between the second current conducting layer and the second-type semiconductor layer, wherein the second current conducting layer is electrically connected to the second-type semiconductor layer via the second metal layer. The second metal layer includes: a welding portion and a finger portion. The welding portion is electrically connected to the second current conducting layer. The finger portion extends outside the second current conducting layer from the welding portion, wherein a width of the welding portion is larger than a width of the finger portion and the width of the welding portion changes gradually.

In an embodiment of the invention, the width of the welding portion gradually increases and then gradually decreases from a side close to the finger portion.

In another embodiment of the invention, an LED includes a first-type semiconductor layer, a light emitting layer, a second-type semiconductor layer, a distributed Bragg reflector structure, a first metal layer, a first current conducting layer, a first insulating layer, a first bonding layer, and a second current conducting layer. The light emitting layer is located between the first-type semiconductor layer and the second-type semiconductor layer. The distributed Bragg reflector structure is disposed on the second-type semiconductor layer and overlaps with the light emitting layer. The first metal layer is located on the first-type semiconductor layer and electrically connected to the first-type semiconductor layer, wherein the distributed Bragg reflector structure has a through hole, and the first metal layer is located in the through hole of the distributed Bragg reflector structure. The first current conducting layer is disposed on the distributed Bragg reflector structure and filled into the through hole of the distributed Bragg reflector structure to be electrically connected to the first metal layer. The first insulating layer is disposed on the first current conducting layer and has a through hole. The first bonding layer is disposed on the first insulating layer and filled into the through hole of the first insulating layer to be electrically connected to the first current conducting layer, wherein the through hole of the distributed Bragg reflector structure and the through hole of the first insulating layer are displaced and do not overlap with each other. The second current conducting layer is electrically connected to the second-type semiconductor layer.

In an embodiment of the invention, a width of the through hole of the first insulating layer is larger than a width of the through hole of the distributed Bragg reflector structure.

In an embodiment of the invention, the LED further includes: a second metal layer located on the second-type semiconductor layer and electrically connected to the second-type semiconductor layer, wherein the distributed Bragg reflector structure has another through hole, at least a part of the second metal layer is located in the another through hole of the distributed Bragg reflector structure, and the second current conducting layer is disposed on the distributed Bragg reflector structure and filled into the another through hole of the distributed Bragg reflector structure to be electrically connected to the second metal layer.

In an embodiment of the invention, the first insulating layer is disposed on the second current conducting layer and has another through hole, and the LED further includes: a second bonding layer disposed on the first insulating layer and filled into the another through hole of the first insulating layer to be electrically connected to the second current conducting layer, wherein the another through hole of the distributed Bragg reflector structure and the another through hole of the first insulating layer are displaced and do not overlap with each other.

In an embodiment of the invention, a width of the another through hole of the first insulating layer is larger than a width of the another through hole of the distributed Bragg reflector structure.

In an embodiment of the invention, the first current conducting layer includes: a plurality of conductive portions separated from one another, wherein the second current conducting layer has a plurality of recesses, and the conductive portions of the first current conducting layer are disposed within areas of the recesses of the second current conducting layer.

In an embodiment of the invention, the first metal layer includes a plurality of welding portions separated from one another, and each of the conductive portions is electrically connected to the welding portions.

In an embodiment of the invention, the LED further includes: a second bonding layer. The second bonding layer is disposed on the first insulating layer and filled into the another through hole of the first insulating layer to be electrically connected to the second current conducting layer, wherein each of the conductive portions includes a middle portion located between the first bonding layer and the second bonding layer.

In an embodiment of the invention, a width of one middle portion of the conductive portion is larger than a width of another middle portion.

In an embodiment of the invention, a manufacturing method of an LED includes: forming a plurality of light emitting elements on a growth substrate, wherein each of the light emitting elements includes a first-type semiconductor layer, a second-type semiconductor layer, and a light emitting layer located between the first-type semiconductor layer and the second-type semiconductor layer, the growth substrate includes a groove, and a sidewall of the first-type semiconductor layer of each of the light emitting elements is aligned with an edge of the groove; forming a first insulating layer on the light emitting elements and the groove of the growth substrate, wherein the first insulating layer covers the sidewall of the first-type semiconductor layer of each of the light emitting elements and has a plurality of first through holes and a plurality of second through holes; forming a plurality of first current conducting layers and a plurality of second current conducting layers filled into the first through holes and the second through holes respectively to be electrically connected to the first-type semiconductor layers and the second-type semiconductor layers of the light emitting elements respectively; and dividing the growth substrate along the groove of the growth substrate to form a plurality of LEDs.

In an embodiment of the invention, a method of forming the light emitting elements on the growth substrate includes: sequentially forming a first-type semiconductor material layer, a light emitting material layer, and a second-type semiconductor material layer on the growth substrate; patterning the first-type semiconductor material layer, the light emitting material layer, and the second-type semiconductor material layer to form the first-type semiconductor material layer including a first portion and a second portion, the second-type semiconductor layer, and the light emitting layer, wherein the first portion overlaps with the light emitting layer, and the second portion extends outward from the first portion to protrude outside an area of the light emitting layer; and scribing the second portion of the first-type semiconductor material layer and the growth substrate to form the sidewall of the first-type semiconductor layer and the groove of the growth substrate.

In an embodiment of the invention, the method of forming the light emitting elements on the growth substrate further includes: forming a first sacrificial layer to cover the first-type semiconductor material layer including the first portion and the second portion, the second-type semiconductor layer, and the light emitting layer, wherein when the second portion of the first-type semiconductor material layer and the growth substrate are cut, the first sacrificial layer is further cut.

In an embodiment of the invention, the method of forming the light emitting elements on the growth substrate includes: sequentially forming a first-type semiconductor material layer, a light emitting material layer, a second-type semiconductor material layer, and a first sacrificial material layer on the growth substrate; patterning the second-type semiconductor material layer, the light emitting material layer, and the first sacrificial material layer to form the second-type semiconductor layer, the light emitting layer, and the first sacrificial layer, wherein the first-type semiconductor material layer includes a first portion that overlaps with the light emitting layer and a second portion that extends outward from the first portion to protrude outside an area of the light emitting layer; and forming a second sacrificial layer to cover the first sacrificial layer and the second portion of the first-type semiconductor material layer.

In an embodiment of the invention, when the second portion of the first-type semiconductor material layer and the growth substrate are cut, the second sacrificial layer is further cut.

Based on the above, the LED according to an embodiment of the invention includes the first-type semiconductor layer, the second-type semiconductor layer, the light emitting layer located between the first-type semiconductor layer and the second-type semiconductor layer, the first metal layer located on the first-type semiconductor layer and electrically connected to the first-type semiconductor layer, the first current conducting layer, the first bonding layer, and the second current conducting layer electrically connected to the second-type semiconductor layer. In particular, the first bonding layer has a plurality of through holes that overlap with the first metal layer. In other words, the first bonding layer and the first metal layer are displaced, and a path exists between the first bonding layer and the first metal layer. Thereby, in the process of using the first bonding layer to bond an external circuit board, the bonding material (e.g., solder paste) does not easily flow through the path completely to cause a short circuit problem. Therefore, the LED has good performance.

In an embodiment of the invention, an LED includes a first-type semiconductor layer, a second-type semiconductor layer, a light emitting layer, a first metal layer, a second metal layer, a first current conducting layer, a second current conducting layer, at least one functional stacking layer, a first bonding layer, and a second bonding layer. The light emitting layer is located between the first-type semiconductor layer and the second-type semiconductor layer. The first metal layer is located on the first-type semiconductor layer and is electrically connected to the first-type semiconductor layer. The second metal layer is located on the second-type semiconductor layer and is electrically connected to the second-type semiconductor layer. The first metal layer is located between the first current conducting layer and the first-type semiconductor layer, and the first current conducting layer is electrically connected to the first-type semiconductor layer via the first metal layer. The second metal layer is located between the second current conducting layer and the second-type semiconductor layer, and the second current conducting layer is electrically connected to the second-type semiconductor layer via the second metal layer. The at least one functional stacking layer is disposed on the first-type semiconductor layer, the light emitting layer, and the second-type semiconductor layer. The functional stacking layer includes at least one insulating layer and a functional layer stacked on each other. The functional layer includes a reflector structure layer which is electrically floating or a buffer layer. The first bonding layer is electrically connected to the first-type semiconductor layer via the first current conducting layer and the first metal layer. The second bonding layer is electrically connected to the second-type semiconductor layer via the second current conducting layer and the second metal layer.

In an embodiment of the invention, the at least one insulating layer includes an upper insulating layer and a lower insulating layer. The functional layer is located between the upper insulating layer and the lower insulating layer.

In an embodiment of the invention, the at least one functional stacking layer includes a first functional stacking layer and a second functional stacking layer. The first functional stacking layer includes a first upper insulating layer, a first functional layer, and a first lower insulating layer. The second functional stacking layer includes a second upper insulating layer, a second functional layer, and a second lower insulating layer. The first functional layer includes the reflector structure layer which is electrically floating. The second functional layer includes the buffer layer. The first functional stacking layer is located between the second-type semiconductor layer and the second functional stacking layer.

In an embodiment of the invention, the second upper insulating layer and the second lower insulating layer are exposed to an outside and completely cover the buffer layer.

In an embodiment of the invention, the second upper insulating layer, the buffer layer, and the second lower insulating layer are exposed to the outside.

In an embodiment of the invention, the first current conducting layer and the second current conducting layer are located between the first functional stacking layer and the second functional stacking layer, and the first functional stacking layer is located between the first current conducting layer and the second-type semiconductor layer and is located between the second current conducting layer and the second-type semiconductor layer.

In an embodiment of the invention, a number of the at least one functional stacking layer is one, and the functional layer includes the reflector structure layer which is electrically floating.

In an embodiment of the invention, the first current conducting layer is located between the functional stacking layer and the second-type semiconductor layer, and the second current conducting layer is located between the functional stacking layer and the second-type semiconductor layer.

In an embodiment of the invention, the reflector structure layer includes a first reflector structure portion, a second reflector structure portion, and a third reflector structure portion separated from one another. The first bonding layer overlaps with the first reflector structure portion, the second bonding layer overlaps with and the second reflector structure portion, and the third reflector structure portion is located between the first reflector structure portion and the second reflector structure portion.

In an embodiment of the invention, the upper insulating layer and the lower insulating layer are exposed to the outside and completely cover the reflector structure layer.

In an embodiment of the invention, the upper insulating layer, the first reflector structure portion, the second reflector structure portion, and the lower insulating layer are exposed to the outside.

In an embodiment of the invention, the LED further includes a growth substrate. The first-type semiconductor layer, the light emitting layer, the second-type semiconductor layer, the first metal layer, the second metal layer, the first current conducting layer, the second current conducting layer, the at least one functional stacking layer, the first bonding layer, and the second bonding layer are disposed on the growth substrate. A partial surface of the growth substrate is exposed by the first-type semiconductor layer. The first reflector structure portion and the third reflector structure portion overlap with the partial surface.

In an embodiment of the invention, the LED further includes a growth substrate. The first-type semiconductor layer, the light emitting layer, the second-type semiconductor layer, the first metal layer, the second metal layer, the first current conducting layer, the second current conducting layer, the at least one functional stacking layer, the first bonding layer, and the second bonding layer are disposed on the growth substrate. A partial surface of the growth substrate is exposed by the first-type semiconductor layer. The first reflector structure portion and the second reflector structure portion do not overlap with the partial surface.

In an embodiment of the invention, the light emitting layer and the second-type semiconductor layer have a plurality of through holes. the first metal layer is disposed in the through holes. the first bonding layer and the second bonding layer respectively overlap with the second-type semiconductor layer, and the first bonding layer and the second bonding layer and the first metal layer are respectively displaced.

In an embodiment of the invention, parts of the first-type semiconductor layer, parts of the light emitting layer, and parts of the second-type semiconductor layer form a first light emitting unit. Other parts of the first-type semiconductor layer, other parts of the light emitting layer, and other parts of the second-type semiconductor layer form a second light emitting unit. The first light emitting unit is different from the second light emitting unit. The parts of the first-type semiconductor layer are separated from the other parts of the first-type semiconductor layer. The parts of the light emitting layer are separated from the other parts of the light emitting layer. The parts of the second-type semiconductor layer are separated from the other parts of the second-type semiconductor layer. The first current conducting layer connects the first light emitting unit and the second light emitting unit so that the two are connected in series.

In an embodiment of the invention, the upper insulating layer and the lower insulating layer are exposed to the outside and completely cover the reflector structure layer.

In an embodiment of the invention, the upper insulating layer, the first reflector structure portion, the second reflector structure portion, and the lower insulating layer are exposed to the outside.

In an embodiment of the invention, the reflector structure layer is a continuous reflector structure layer. Parts of the first-type semiconductor layer, parts of the light emitting layer, and parts of the second-type semiconductor layer form a first light emitting unit. Other parts of the first-type semiconductor layer, other parts of the light emitting layer, and other parts of the second-type semiconductor layer form a second light emitting unit. The first light emitting unit is different from the second light emitting unit. The parts of the first-type semiconductor layer are separated from the other parts of the first-type semiconductor layer. The parts of the light emitting layer are separated from the other parts of the light emitting layer. The parts of the second-type semiconductor layer are separated from the other parts of the second-type semiconductor layer. The first current conducting layer connects the first light emitting unit and the second light emitting unit so that the two are connected in series.

In an embodiment of the invention, a number of the at least one functional stacking layer is one, and the functional layer includes the buffer layer.

In an embodiment of the invention, the upper insulating layer and the lower insulating layer are exposed to the outside and completely cover the buffer layer.

In an embodiment of the invention, the upper insulating layer, the buffer layer, and the lower insulating layer are exposed to the outside.

In an embodiment of the invention, the functional stacking layer is located between the second bonding layer and the first current conducting layer and is located between the second bonding layer and the second current conducting layer.

In an embodiment of the invention, the buffer layer includes a first buffer portion, a second buffer portion, and a third buffer portion separated from one another. The first bonding layer overlaps with the first buffer portion. The second bonding layer overlaps with the second buffer portion, and the third buffer portion is located between the first buffer portion and the second buffer portion.

In an embodiment of the invention, a plurality of through holes of the first buffer portion overlap with the first bonding layer, and a plurality of through holes of the second buffer portion overlap with the second bonding layer.

In an embodiment of the invention, the buffer layer is a continuous buffer layer.

In an embodiment of the invention, the LED further includes a heat dissipation pad. The heat dissipation pad is located on the functional stacking layer and is located between a first electrode pad and a second electrode pad. The heat dissipation pad does not overlap with the first buffer portion and the second buffer portion.

In an embodiment of the invention, the LED further includes a heat dissipation pad. The heat dissipation pad is located on the functional stacking layer and is located between a first electrode pad and a second electrode pad. The heat dissipation pad overlaps with the first buffer portion and the second buffer portion.

In an embodiment of the invention, the first bonding layer and the second bonding layer respectively overlap with the second-type semiconductor layer.

In an embodiment of the invention, a number of the at least one insulating layer of the functional stacking layer is one, and the insulating layer is disposed at one side of the functional layer.

In an embodiment of the invention, the at least one insulating layer of the at least one functional stacking layer includes a first insulating layer and a second insulating layer. The second insulating layer is located between the functional layer and the first insulating layer. The first insulating layer is located between the second insulating layer and the second-type semiconductor layer. The first bonding layer is covered by the first insulating layer and the second insulating layer together, and the second bonding layer is covered by the first insulating layer and the second insulating layer together.

In an embodiment of the invention, the LED further includes a plurality of electrode stacked layers. The electrode stacked layers include a first electrode stacked layer and a second electrode stacked layer electrically connected to the first bonding layer and the second bonding layer respectively, and the first electrode stacked layer and the second electrode stacked layer and the functional layer are displaced. Each of the electrode stacked layers includes an adhesive layer, a protection layer, and a connection layer. The connection layer connects the adhesive layer and the protection layer, and each of the electrode stacked layers is electrically connected to the corresponding bonding layer via the adhesive layer.

In an embodiment of the invention, a manufacturing method of an LED is provided, and the method includes the following steps. At least one light emitting unit is formed on a growth substrate. Herein, each of the at least one light emitting unit includes a first-type semiconductor layer, a second-type semiconductor layer, and a light emitting layer located between the first-type semiconductor layer and the second-type semiconductor layer. A first insulating layer is formed on the at least one light emitting unit and a groove of the growth substrate. The first insulating layer covers a side wall of the first-type semiconductor layer of each of the at least one light emitting unit and has a plurality of first through holes and a plurality of second through holes. A plurality of first current conducting layers and a plurality of second current conducting layers are formed and filled into the first through holes and the second through holes respectively, so as to be electrically connected to the first-type semiconductor layer and the second-type semiconductor layer of the at least one light emitting unit respectively. At least one functional stacking layer is formed on the at least one light emitting unit. The at least one functional stacking layer includes an upper insulating layer, a lower insulating layer, and a functional layer located between the upper insulating layer and the lower insulating layer. The functional layer includes a reflector structure layer which is electrically floating or a buffer layer, and the at least one functional stacking layer has a plurality of third through holes. A first bonding layer and a second bonding layer are formed on the at least one functional stacking layer. The first bonding layer and the second bonding layer respectively are filled into some of the third through holes, so as to be electrically connected to first current conducting layers and the second current conducting layers respectively. Further, the growth substrate is divided along the groove of the growth substrate to form a plurality of light emitting diodes.

In an embodiment of the invention, in the step of forming the at least one functional stacking layer on the at least one light emitting unit, the upper insulating layer and the lower insulating layer completely cover the functional layer.

In an embodiment of the invention, in the step of forming the at least one functional stacking layer on the at least one light emitting unit, the upper insulating layer, the functional layer, and the lower insulating layer are exposed to the outside.

In an embodiment of the invention, the step of forming the at least one functional stacking layer is performed after the step of forming the first current conducting layers and the second current conducting layers is performed.

In an embodiment of the invention, the step of forming the at least one functional stacking layer is performed before the step of forming the first current conducting layers and the second current conducting layers is performed.

In an embodiment of the invention, in the step of forming the at least one functional stacking layer, a number of the at least one functional stacking layer to be formed is plural. The step of forming the first current conducting layers and the second current conducting layers is performed next after some of the functional stacking layers are formed, and the step of forming the other functional stacking layers is then performed.

To sum up, in the LED of the embodiments of the invention, the at least one functional stacking layer is disposed, and the functional layer in the at least one functional stacking layer may be the reflector structure layer which is electrically floating or the buffer layer. When the functional layer is the reflector structure layer, increased light beams from the light emitting layer are emitted from the LED, and that light emission efficiency is improved. When the functional layer is the buffer layer, even though the LED may generate heat owing to long-term use and an internal device in the LED may generate thermal stress owing to such heat, an effect generated by such stress may be effectively reduced by the buffer layer. Therefore, the LED exhibits good device reliability. In addition, the manufacturing method of manufacturing the LED is also provided by the embodiments of the invention.

To make the aforementioned and other features and advantages of the invention more comprehensible, several embodiments accompanied with drawings are described in detail as follows.

### BRIEF DESCRIPTION OF THE DRAWINGS

FIG. 1A is a schematic cross-sectional view of an LED according to an embodiment of the invention.

FIG. 1B is a reflection spectrum of a distributed Bragg reflector structure according to an embodiment of the invention.

FIG. 1C is a reflection spectrum of a distributed Bragg reflector structure according to an embodiment of the invention.

FIG. 2 is a schematic cross-sectional view of an LED according to another embodiment of the invention.

FIG. 3 is a schematic cross-sectional view of an LED according to another embodiment of the invention.

FIG. 4 is a schematic cross-sectional view of an LED according to another embodiment of the invention.

FIG. 5 is a schematic cross-sectional view of an LED according to yet another embodiment of the invention.

FIG. 6A is a schematic cross-sectional view of a metal layer according to an embodiment of the invention.

FIG. 6B is a schematic cross-sectional view of a metal layer according to another embodiment of the invention.

FIG. 7 is a schematic top view of an LED according to an embodiment of the invention.

FIG. 8 is a schematic cross-sectional view along a line A-B of FIG. 7.

FIG. 9 is a schematic cross-sectional view along a line B-C of FIG. 7.

FIG. 10 is a schematic cross-sectional view along a line C-D of FIG. 7.

FIG. 11 is a schematic cross-sectional view along a line E-F of FIG. 7.

FIG. 12 is a schematic cross-sectional view along a line G-H of FIG. 7.

FIG. 13 is a schematic cross-sectional view of a distributed Bragg reflector structure according to an embodiment of the invention.

FIG. 14 is a schematic cross-sectional view of a distributed Bragg reflector structure according to another embodiment of the invention.

FIG. 15 is a schematic cross-sectional view of a distributed Bragg reflector structure according to another embodiment of the invention.

FIG. 16 is a schematic cross-sectional view of a distributed Bragg reflector structure according to yet another embodiment of the invention.

FIG. 17 is a schematic top view of an LED according to an embodiment of the invention.

FIG. 18 is a schematic cross-sectional view along a line A-B of FIG. 17.

FIG. 19 is a schematic cross-sectional view along a line C-D of FIG. 17.

FIG. 20 is a schematic top view of an LED according to another embodiment of the invention.

FIG. 21 is a schematic cross-sectional view along a line C′-D′ of FIG. 20.

FIG. 22 is a flowchart of manufacturing an LED according to an embodiment of the invention.

FIG. 23A to FIG. 24C are schematic cross-sectional views showing a manufacturing method of an LED according to an embodiment of the invention.

FIG. 25 is a schematic partially enlarged view of a part R1 of FIG. 23Q.

FIG. 26 is a schematic partially enlarged view of a part R2 of FIG. 23R.

FIG. 27 is a schematic partially enlarged view of a part R3 of FIG. 23V.

FIG. 28 is a flowchart of manufacturing an LED according to another embodiment of the invention.

FIG. 29A to FIG. 29G are schematic cross-sectional views showing a part of a manufacturing method of an LED according to another embodiment of the invention.

FIG. 30 is a flowchart of manufacturing an LED according to yet another embodiment of the invention.

FIG. 31A to FIG. 31H are schematic cross-sectional views showing a part of a manufacturing method of an LED according to yet another embodiment of the invention.

FIG. 32A to FIG. 32G are schematic cross-sectional views showing a part of a manufacturing method of an LED according to yet another embodiment of the invention.

FIG. 33 is a schematic top view of an LED according to an embodiment of the invention.

FIG. 34 is a schematic cross-sectional view along a line A1-B1 of FIG. 33.

FIG. 35 is a schematic cross-sectional view along a line E-F of FIG. 33.

FIG. 36 is a schematic cross-sectional view along a line G-H of FIG. 33.

FIG. 37 is a schematic top view of a conductive layer, a first metal layer, and a second metal layer of the LED of FIG. 33.

FIG. 38 is a schematic top view of an LED according to an embodiment of the invention.

FIG. 39 is a schematic cross-sectional view along a line L-M of FIG. 38.

FIG. 40 is a schematic top view of a conductive layer, a first metal layer, and a second metal layer of the LED of FIG. 38.

FIG. 41 is a schematic top view of an LED according to an embodiment of the invention.

FIG. 42 is a schematic cross-sectional view along a line I-J of FIG. 41.

FIG. 43 is a schematic top view of an LED according to an embodiment of the invention.

FIG. 44 is a schematic cross-sectional view along a line I1-J1 of FIG. 43.

FIG. 45 is a schematic top view of an LED according to an embodiment of the invention.

FIG. 46 is a schematic cross-sectional view along a line P-P′ of FIG. 45.

FIG. 47 is a schematic cross-sectional view along a line K-K′ of FIG. 45.

FIG. 48 is a schematic cross-sectional view along a line N-N′ of FIG. 45.

FIG. 49 is a schematic cross-sectional view along a line L-L′ of FIG. 45.

FIG. 50 is a schematic cross-sectional view along a line M-M′ of FIG. 45.

FIG. 51 is a schematic cross-sectional view of an LED according to an embodiment of the invention.

FIG. 52 is a schematic cross-sectional view of an LED according to an embodiment of the invention.

FIG. 53 is a schematic top view of an LED according to an embodiment of the invention.

FIG. 54 is a schematic cross-sectional view along a line N1-N1′ of FIG. 53.

FIG. 55 illustrates an embodiment of arrangement of a welding portion of a first metal layer and a welding portion of a second metal layer in the LED of FIG. 45.

FIG. 56 illustrates another embodiment of arrangement of the welding portion of the first metal layer and the welding portion of the second metal layer in the LED of FIG. 45.

FIG. 57 to FIG. 64 are schematic cross-sectional views of an LED according to different embodiments of the invention.

FIG. 65 is a partial flowchart of manufacturing the LED of the embodiment of FIG. 57.

FIG. 66 to FIG. 68 are schematic cross-sectional views of an LED according to different embodiments of the invention.

FIG. 69A is a schematic top view of an LED according to an embodiment of the invention.

FIG. 69B is a schematic top view of a cross-section A-A′.

FIG. 70 to FIG. 75 are schematic cross-sectional views of an LED according to different embodiments of the invention.

FIG. 76A to FIG. 76I are flowcharts illustrating manufacturing of an LED 800 of FIG. 66.

FIG. 77 is a schematic cross-sectional view of an LED according to an embodiment of the invention.

FIG. 78A to FIG. 78D are partial flowcharts of manufacturing the LED of FIG. 77.

FIG. 79 is a schematic cross-sectional view of an LED according to an embodiment of the invention.

FIG. 80A to FIG. 80B are partial flowcharts of manufacturing the LED of FIG. 79.

FIG. 81 is a schematic cross-sectional view of an LED according to an embodiment of the invention.

FIG. 82A to FIG. 82C are partial flowcharts of manufacturing the LED of FIG. 81.

FIG. 83 is a schematic cross-sectional view of an LED according to another embodiment of the invention.

FIG. 84 is a schematic cross-sectional view of an LED according to still another embodiment of the invention.

FIG. 85A to FIG. 85E are schematic partial flowcharts of manufacturing the LED of FIG. 84.

### DESCRIPTION OF THE EMBODIMENTS

Descriptions of the invention are given with reference to the exemplary embodiments illustrated by the accompanying drawings. Wherever possible, the same reference numerals are used in the drawings and the descriptions to refer to the same or similar parts.

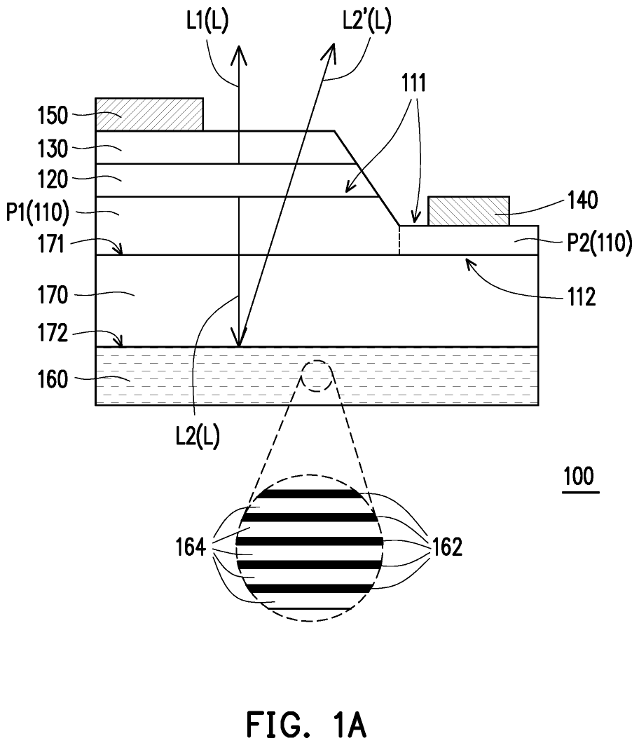

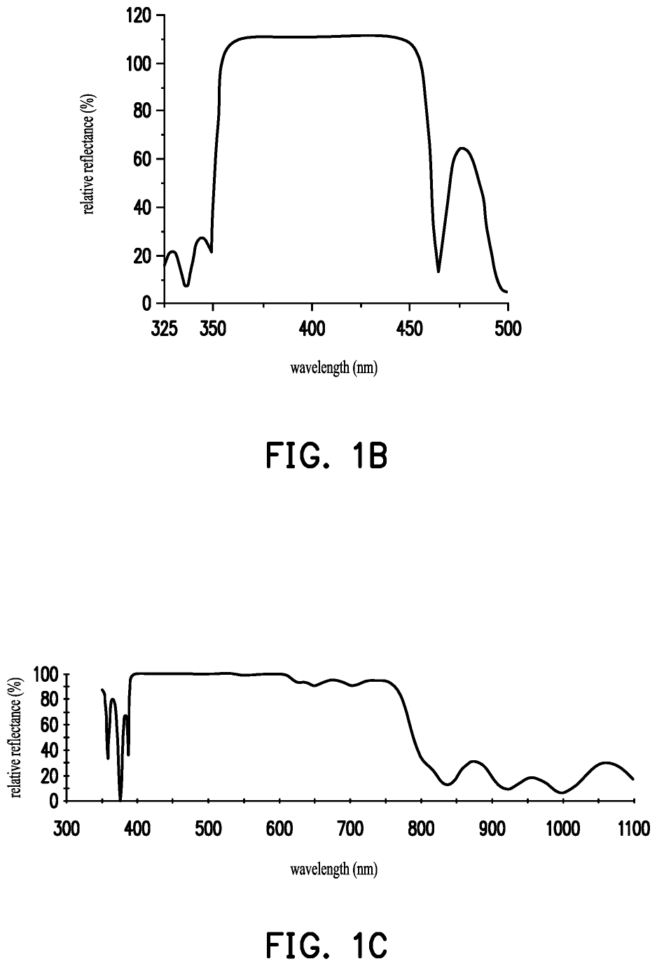

FIG. 1A is a schematic cross-sectional view of an LED according to an embodiment of the invention. Referring to FIG. 1A, specifically, FIG. 1A illustrates a horizontal type LED, which is an LED applicable to wire bonding. The LED 100 includes a first-type semiconductor layer 110, a light emitting layer 120, a second-type semiconductor layer 130, a first current conducting layer 140, a second current conducting layer 150, and a distributed Bragg reflector structure 160. In the present embodiment, one of the first-type semiconductor layer 110 and the second-type semiconductor layer 130 is an N-type semiconductor layer (e.g., n-GaN), and the other one is a P-type semiconductor layer (e.g., p-GaN). The light emitting layer 120 is located between the first-type semiconductor layer 110 and the second-type semiconductor layer 130, and the light emitting layer 120 is configured to emit a light beam L, wherein a light emitting wavelength range of the light beam L has at least one peak wavelength. The first current conducting layer 140 is electrically connected to the first-type semiconductor layer 110. The second current conducting layer 150 is electrically connected to the second-type semiconductor layer 130. The first-type semiconductor layer 110, the light emitting layer 120, and the second-type semiconductor layer 130 are located on the same side of the distributed Bragg reflector structure 160. A reflectance of the distributed Bragg reflector structure 160 is greater than or equal to 90% in a reflective wavelength range at least covering 0.8X nm to 1.8X nm, and the reflectance is greater than or equal to 95% in a reflective wavelength range at least covering 0.9X nm to 1.6X nm, wherein X is the peak wavelength of the light emitting wavelength range.

In an embodiment, the light emitting layer 120 may be a quantum well (QW) structure. In other embodiments, the light emitting layer 120 may be a multiple quantum well (MQW) structure, and the MQW structure includes disposing a plurality of well layers and a plurality of barrier layers alternately in a repeating manner. In addition, a material composition of the light emitting layer 120 includes the composites of compound semiconductors able to emit the light beam L having the peak wavelength that falls in the light emitting wavelength range of 320 nm to 430 nm (ultraviolet light), 430 nm to 500 nm (blue light), or 500 nm to 550 nm (green light). The variation in the composition or structural design of the light emitting layer 120 may alter the light emitting wavelength range of the light beam L, but the invention is not limited thereto.

In detail, in the present embodiment, the first-type semiconductor layer 110 includes a first portion P1 and a second portion P2. The light emitting layer 120 is stacked on the first portion P1. The second portion P2 extends outward from the first portion P1 to protrude outside an area of the light emitting layer 120, so as to be electrically connected to the first current conducting layer 140. The first-type semiconductor layer 110 has a first surface 111 and a second surface 112 opposite to the first surface 111. The light emitting layer 120, the second-type semiconductor layer 130, the first current conducting layer 140, and the second current conducting layer 150 are located on the first surface 111 of the first-type semiconductor layer 110. The distributed Bragg reflector structure 160 is located on the second surface 112 of the first-type semiconductor layer 110.

In particular, the LED 100 of the present embodiment further includes a growth substrate 170. The growth substrate 170 has a first surface 171 and a second surface 172 opposite to the first surface 171. A material of the growth substrate 170 is, for example, C-Plane, R-Plane, or A-plane sapphire substrate or other transparent materials. Additionally, single crystalline compounds having a lattice constant close to the first-type semiconductor layer 110 are also suitable to be used as the material for the growth substrate 170. The first-type semiconductor layer 110, the light emitting layer 120, and the second-type semiconductor layer 130 of the present embodiment are sequentially grown and stacked on the first surface 171 of the growth substrate 170. The distributed Bragg reflector structure 160 is disposed on the second surface 172 of the growth substrate 170. In other embodiments, the LED 100 may not have the growth substrate 170, and the distributed Bragg reflector structure 160 may be disposed on the second surface 112 of the first-type semiconductor layer 110.

Generally, the light beam L emitted from the light emitting layer 120 travels in all directions. For example, the light beam L1 and the light beam L2 emit toward different directions from the light emitting layer 120. However, when the light emitting direction of the light beam L1 is designed as the main light emitting direction of the LED 100, the light beam L2 may not be utilized, resulting in limitation to the light emission efficiency. Therefore, in the present embodiment, the distributed Bragg reflector structure 160 is used for reflecting the light beam L2 traveling downward and for guiding the light beam L2 toward the upper side of the growth substrate 170 for emission to constitute a reflecting light beam L2′. In this way, the light beam emitted from the light emitting layer 120 can effectively emit toward a predetermined light emitting direction to render good light emission efficiency.

In particular, the distributed Bragg reflector structure 160 is mainly formed by a combination of at least one primary stacked layer region, at least one buffer stacked layer region, and at least one repair stacked layer region. The primary stacked layer region, the buffer stacked layer region, and the repair stacked layer region respectively include a plurality of first refractive layers 162 and a plurality of second refractive layers 164, and the first refractive layers 162 and the second refractive layers 164 are stacked alternately. A refractive index of each of the first refractive layers 162 is different from a refractive index of each of the second refractive layers 164. The buffer stacked layer region may be located between two adjacent primary stacked layer regions, so as to increase the reflectance of the two adjacent primary stacked layer regions. The repair stacked layer region is at least located on one side of the primary stacked layer region, so as to increase the reflectance of the primary stacked layer region. In addition, a structure for increasing the reflectance of the distributed Bragg reflector structure is added, in which the buffer stacked layer region may be located between two adjacent repair stacked layer regions, and the primary stacked layer region is located between the repair stacked layer region and two adjacent repair stacked layer regions which are located between two sides of the buffer stacked layer region, so as to increase the reflectance of the two adjacent primary stacked layer regions. In other words, the distributed Bragg reflector structure 160 is formed by a periodic structure, a partial periodic structure, a gradually increasing structure, or a gradually decreasing structure of alternately stacked first refractive layers 162 and second refractive layers 164. That is, in the distributed Bragg reflector structure 160, one of the at least one pair of the adjacent two layers is the first refractive layer 162 and the other one is the second refractive layer 164. In an embodiment, materials and thicknesses of the first refractive layers 162 and the second refractive layers 164 are respectively related to the reflective wavelength range of the distributed Bragg reflector structure 160. The structure of the primary stacked layer region, the buffer stacked layer region, or the repair stacked layer region is formed by arranging the first refractive layers 162 and the second refractive layers 164 alternately, and may have the same periodic structure, a different periodic structure, a gradually increasing structure, or a gradually decreasing structure. The number of the layers of the periodic structure, the partial periodic structure, the gradually increasing structure, or the gradually decreasing structure of the primary stacked layer region is larger than the number of the layers of the periodic structure, the partial periodic structure, the gradually increasing structure, or the gradually decreasing structure of the buffer stacked layer region or the repair stacked layer region. The buffer stacked layer region at least includes a material contained in the two adjacent primary stacked layer regions, and the material thereof may be the same material or the same refractive material. Additionally, thicknesses of the first refractive layers 162 and the second refractive layers 164 may be the same or different.

A material of the first refractive layers 162 in the present embodiment includes tantalum pentoxide (Ta₂O₅), zirconium dioxide (ZrO₂), niobium pentoxide (Nb₂O₅), hafnium oxide (HfO₂), titanium dioxide (TiO₂), or combinations thereof. On the other hand, a material of the second refractive layers 164 includes silicon dioxide (SiO₂). By selecting the materials of the first refractive layer 162 and the second refractive layer 164, the probability of the light beam L2 being absorbed by the first refractive layer 162 and the second refractive layer 164 can be reduced, thereby increasing the possibility of the light beam L2 being reflected, and thus the light emission efficiency and brightness of the LED 100 can be increased. Especially, in the present embodiment, the distributed Bragg reflector structure 160 has excellent reflectance (greater than or equal to 95%) with respect to different reflectance wavelength ranges, thereby allowing the LED 100 to be suitable in applications of a light emitting device which requires to emit different light emitting wavelength ranges. Specifically, if the adjacent first refractive layer 162 and second refractive layer 164 are regarded as a stacked layer pair, the distributed Bragg reflector structure 160 applied to the LED 100 may include more than or equal to 4 to less than or equal to 100 or even more stacked layer pairs. In addition, the number of the stack layer pairs can be adjusted according to the desired reflective properties, and it construes no limitation in the invention. For example, 30 to 50 stacked layer pairs may be adopted to constitute the distributed Bragg reflector structure 160.

If the light beam L provided by the LED 100 is ultraviolet light, the peak wavelength of the light emitting wavelength range falls in a range of 320 nm to 430 nm. At this time, the material of the first refractive layers 162 in the distributed Bragg reflector structure 160 may be selected from materials containing tantalum (Ta), such as tantalum pentoxide (Ta₂O₅), and the material of the second refractive layers 164 may be selected from silicon dioxide (SiO₂), but they construe no limitation in the invention. For example, when the peak wavelength of the light emitting wavelength range is 400 nm, through adjusting the material, thickness, and the number of stacked layer pairs in the present embodiment, the distributed Bragg reflector structure 160 is able to provide a reflectance greater than or equal to 90% in the reflective wavelength range at least covering 320 nm (0.8 times the peak wavelength) to 720 nm (1.8 times the peak wavelength). Additionally, in other preferable embodiments, when the peak wavelength of the light emitting wavelength range is 400 nm, the distributed Bragg reflector structure 160 is able to provide a reflectance greater than or equal to 95% in the reflective wavelength range at least covering 360 nm (0.9 times the peak wavelength) to 560 nm (1.4 times the peak wavelength).

FIG. 1B is a reflection spectrum of a distributed Bragg reflector structure according to another embodiment of the invention. In FIG. 1B, the horizontal axis denotes wavelength and the vertical axis denotes relative reflectance, and the relative reflectance is the reflectance of the distributed Bragg reflector structure relative to a reflectance of an aluminum metal layer. In an embodiment, the distributed Bragg reflector structure having the reflection spectrum illustrated in FIG. 1B utilizes tantalum pentoxide (Ta₂O₅) as the first refractive layers and silicon dioxide (SiO₂) as the second refractive layers. Additionally, the first refractive layers and the second refractive layers in the distributed Bragg reflector structure respectively include 30 layers, and the first refractive layers and the second refractive layers are stacked alternately in a repeating manner to form the distributed Bragg reflector structure. As illustrated in FIG. 1B, as compared to the aluminum metal layer, the distributed Bragg reflector structure has a relative reflectance higher than 100% in the wavelength range of 350 nm to 450 nm. As a result, a light emitting chip having the distributed Bragg reflector structure can be used for an ultraviolet light emitting device, thereby enhancing the light extraction efficiency of the ultraviolet light emitting device.

Referring to FIG. 1A, if the light beam L provided by the LED 100 is blue light, the peak wavelength of the light emitting wavelength range falls in a range of 420 nm to 500 nm. At this time, the material of the first refractive layers 162 in the distributed Bragg reflector structure 160 may be selected from materials containing titanium (Ti), such as titanium dioxide (TiO₂), and the material of the second refractive layers 164 may be selected from silicon dioxide (SiO₂), but they construe no limitation in the invention. For example, when the peak wavelength of the light emitting wavelength range is 450 nm, through adjusting the material, thickness, and the number of stacked layer pairs in the present embodiment, the distributed Bragg reflector structure 160 is able to provide a reflectance greater than or equal to 90% in the reflective wavelength range at least covering 360 nm (0.8 times the peak wavelength) to 810 nm (1.8 times the peak wavelength). Additionally, in other embodiments, when the peak wavelength of the light emitting wavelength range is 450 nm, the distributed Bragg reflector structure 160 is able to provide a reflectance greater than or equal to 95% in the reflective wavelength range at least covering 405 nm (0.9 times the peak wavelength) to 720 nm (1.6 times the peak wavelength).

If the light beam L provided by the LED 100 is blue light while containing a wavelength conversion structure such as fluorescent powder through different packing types, the light beam L provided by the LED 100 is blue light and can be excited by the wavelength conversion structure to render another peak wavelength of an excitation wavelength. The another peak wavelength of the excitation wavelength is greater than the peak wavelength of the light beam L provided by the LED 100, so as to allow the light beam to at least include more than one peak wavelength, and the peak wavelengths of the light emitting wavelength range and the excitation wavelength range may fall in a range of 400 nm to 700 nm. At this time, the material of the first refractive layers 162 in the distributed Bragg reflector structure 160 may be selected from materials containing titanium (Ti), such as titanium dioxide (TiO₂), and the material of the second refractive layers 164 may be selected from silicon dioxide (SiO₂), but they construe no limitation in the invention.

For example, when at least one of the peak wavelength of the light emitting wavelength range is 445 nm and the peak wavelength of the excitation wavelength is 580 nm, or in addition, a peak wavelength of an excitation wavelength of 620 nm may be included, through adjusting the material, thickness, and the number of stacked layer pairs in the present embodiment, the distributed Bragg reflector structure 160 is able to provide a reflectance greater than or equal to 90% in the reflective wavelength range at least covering 356 nm (0.8 times the peak wavelength) to 801 nm (1.8 times the peak wavelength). Additionally, in other embodiments, when the peak wavelength of the light emitting wavelength range is 445 nm, the distributed Bragg reflector structure 160 is able to provide a reflectance greater than or equal to 95% in the reflective wavelength range at least covering 400.5 nm (0.9 times the peak wavelength) to 712 nm (1.6 times the peak wavelength).

If the light beam L provided by the LED 100 is green light, the peak wavelength of the light emitting wavelength range falls in a range of 500 nm to 550 nm. At this time, the material of the first refractive layers 162 in the distributed Bragg reflector structure 160 may be selected from materials containing titanium (Ti), such as titanium dioxide (TiO₂), and the material of the second refractive layers 164 may be selected from silicon dioxide (SiO₂), but they construe no limitation in the invention. For example, when the peak wavelength of the light emitting wavelength range is 525 nm, through adjusting the material, thickness, and the number of stacked layer pairs in the present embodiment, the distributed Bragg reflector structure 160 is able to provide a reflectance greater than or equal to 90% in the reflective wavelength range at least covering 420 nm (0.8 times the peak wavelength) to 997.5 nm (1.9 times the peak wavelength). Additionally, in other embodiments, when the peak wavelength of the light emitting wavelength range is 525 nm, the distributed Bragg reflector structure 160 is able to provide a reflectance greater than or equal to 95% in the reflective wavelength range at least covering 472.5 nm (0.9 times the peak wavelength) to 840 nm (1.6 times the peak wavelength).

FIG. 1C is a reflection spectrum of a distributed Bragg reflector structure according to another embodiment of the invention. In FIG. 1C, the horizontal axis denotes wavelength and the vertical axis denotes reflectance. In an embodiment, the distributed Bragg reflector structure having the reflection spectrum illustrated in FIG. 1C utilizes titanium dioxide (TiO₂) as the first refractive layers and silicon dioxide (SiO₂) as the second refractive layers. Additionally, the first refractive layers and the second refractive layers in the distributed Bragg reflector structure respectively include 24 layers, and the first refractive layers and the second refractive layers are stacked alternately in a repeating manner to form the distributed Bragg reflector structure. As illustrated in FIG. 1C, in the reflection spectrum of the distributed Bragg reflector structure, the reflectance is approximately higher than or equal to 90% in the wavelength range of 400 nm to 700 nm, and even more, the reflectance is maintained close to 100% in the wavelength range of 400 nm to 600 nm. Since the reflection spectrum of the distributed Bragg reflector structure has high reflectance in a broader wavelength range, the distributed Bragg reflector structure is able to provide reflection effects in the broader wavelength range for a wider view angle.

The reflection spectrum of the distributed Bragg reflector structure still has a high reflectance in a wavelength range slightly lower than 400 nm and close to 400 nm, and the reflection spectrum of the distributed Bragg reflector structure still has a high reflectance in a wavelength range slightly higher than 700 nm, and even has a decent reflectance in a wavelength range approximately close to 800 nm. As a result, a light emitting chip having the distributed Bragg reflector structure can be used for a visible light emitting device, thereby enhancing the light extraction efficiency of the visible light emitting device. Additionally, as illustrated in FIG. 1C, the distributed Bragg reflector structure at a longer wavelength range, for example, 800 nm to 900 nm, or even more than 900 nm, has a reflectance lower than 40%. In this way, the processability of the light emitting chip having the distributed Bragg reflector structure in laser scribing and batch sheet can be enhanced.

In the present embodiment, when the light emitting chip having the distributed Bragg reflector structure is applied on the light emitting device, the light emitting wavelength of the light emitting layer of the light emitting chip may only cover part of the visible light wavelength range. In addition, the light emitting device may further include fluorescent powder, and the excitation wavelength of the fluorescent powder may cover another part of the visible light wavelength range. For example, the light emitting wavelength of the light emitting layer may be blue light or green light, and the excitation wavelength of the fluorescent powder may be yellow light, green light, or red light, etc. In this way, through the disposition of the light emitting chip and the fluorescent powder, the light emitting device may emit white light, and the distributed Bragg reflector structure in the light emitting chip may efficiently reflect the wavelength range covered by the white light. In other words, in the light emitting chip, the light emitting wavelength of the light emitting layer and the reflective wavelength of the distributed Bragg reflector structure can overlap partially, and are not required to be consistent with each other. Certainly, in the light emitting chip, the light emitting wavelength of the light emitting layer and the reflective wavelength of the distributed Bragg reflector structure may also be designed corresponding to each other. For example, both may fall in the wavelength range of the blue light, both may fall in the wavelength range of the green light, or both may fall in the wavelength range of the red light.

It should be mentioned that reference numerals and some descriptions provided in the previous exemplary embodiment are also applied in the following exemplary embodiment. The same reference numerals are presented to denote identical or similar components in these exemplary embodiments, and repetitive descriptions are omitted. The omitted descriptions may be found in the previous exemplary embodiments, and will not be repeated hereinafter.

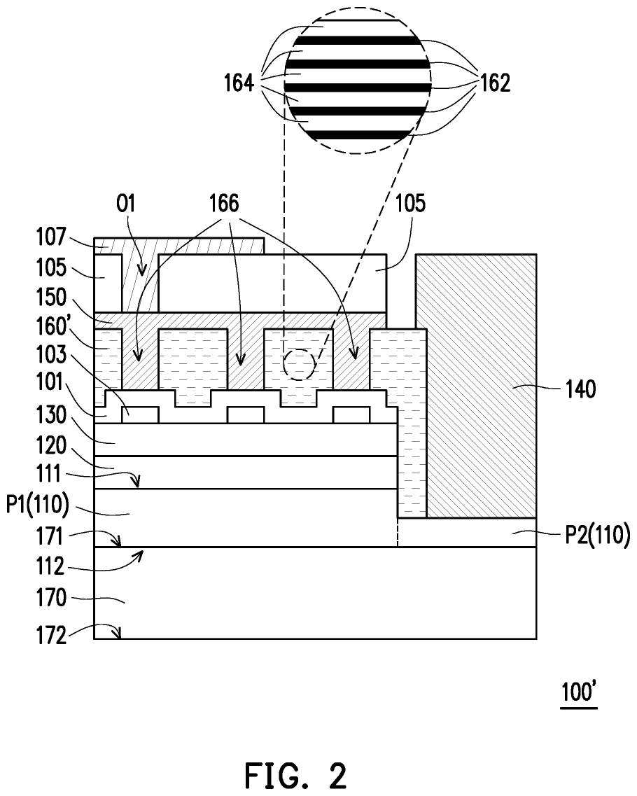

FIG. 2 is a schematic cross-sectional view of an LED according to another embodiment of the invention. Referring to FIG. 2, the LED 100′ illustrated in FIG. 2 is an LED applicable to flip chip packaging. The LED 100′ in the present embodiment is similar to the LED 100 in FIG. 1A, and a major difference lies in that: the distributed Bragg reflector structure 160′ is located between the second current conducting layer 150 and the second-type semiconductor layer 130, and the distributed Bragg reflector structure 160′ has a plurality of through holes 166. In other words, the first-type semiconductor layer 110, the light emitting layer 120, the second-type semiconductor layer 130, and the distributed Bragg reflector structure 160′ in the present embodiment are sequentially stacked on the first surface 171 of the growth substrate 170. In addition, the second current conducting layer 150 is filled into the through holes 166 to be electrically connected to the second-type semiconductor layer 130.

In particular, in the present embodiment, the LED 100′ further includes a conductive layer 101 and a plurality of insulating patterns 103, and the insulating patterns 103 may not be connected to one another. The conductive layer 101 is disposed between the distributed Bragg reflector structure 160′ and the second-type semiconductor layer 130, and the second current conducting layer 150 filled into the through holes 166 may be in contact with the conductive layer 101 to be electrically connected to the second-type semiconductor layer 130 via the conductive layer 101. A material of the conductive layer 101 is, for example, indium tin oxide (ITO) or other materials having characteristics of current dispersion and allowing light to pass through, such as transparent metal or atomic stack layer, etc.

On the other hand, the insulating patterns 103 are disposed between the conductive layer 101 and the second-type semiconductor layer 130, and part of the insulating patterns 103 are disposed corresponding to the through holes 166, such that an area of the conductive layer 101 outside the insulating patterns 103 is in contact with the second-type semiconductor layer 130. To take a step further, a material of the insulating patterns 103 includes, for example, silicon dioxide (SiO₂) or other materials having characteristic of current blocking. The conductive layer 101 and the insulating patterns 103 are disposed to uniformly disperse the current transferred in the light emitting layer 120 to avoid the current from concentrating at certain parts of the light emitting layer 120, thereby allowing uniform distribution of the light emitting region of the light emitting layer 120. Therefore, the above configuration enables better light emitting uniformity of the LED 100′.

In the present embodiment, since the LED 100′ is a flip chip packaging type LED, an insulating layer 105 and a bonding layer 107 may further be disposed on the second current conducting layer 150. The insulating layer 105 has a through hole O1, and the bonding layer 107 is filled into the through holes O1, such that the bonding layer 107 is electrically connected to the second current conducting layer 150. In order to electrically connect or physically connect with an external substrate during the bonding process of the flip chip, a material of the bonding layer 107 and the first current conducting layer 140 is, for example, gold (Au), gold/tin (Au/Sn) alloy, or other conductive materials applicable in eutectic bonding. Herein, the first current conducting layer 140 can be used for eutectic bonding directly, but it construes no limitation in the invention. In other embodiments, the first current conducting layer 140 and the second current conducting layer 150 may be formed by the same material, and an additional bonding layer used for eutectic bonding can be disposed above the first current conducting layer 140. A material of the insulating layer 150 is, for example, silicon dioxide (SiO₂), titanium dioxide (TiO₂), or other suitable materials.

In the present embodiment, the specific design and the material of the distributed Bragg reflector structure 160′ can be the same as the distributed Bragg reflector structure 160′ in the previous embodiment. Therefore, the reflectance of the distributed Bragg reflector structure 160′ has an excellent performance in the short wavelength range, thereby allowing the LED 100′ also to be suitable in applications of a light emitting device which requires to emit at the short wavelength range.

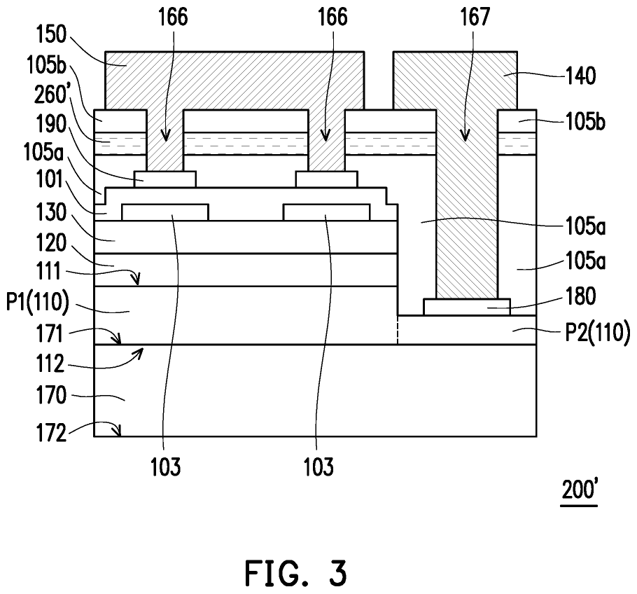

FIG. 3 is a schematic cross-sectional view of an LED according to another embodiment of the invention. Referring to FIG. 3, the LED illustrated in FIG. 3 is another LED applicable to flip chip packaging. The LED 200′ in the present embodiment is similar to the LED 100′ in FIG. 2, and a major difference lies in that: the distributed Bragg reflector structure 260′ is located between the second current conducting layer 150 and the second-type semiconductor layer 130, and the distributed Bragg reflector structure 160′ has a plurality of through holes 166 located between the second current conducting layer 150 and the second-type semiconductor layer 130 and a plurality of through holes 167 located between the first current conducting layer 140 and the first-type semiconductor layer 110. In other words, the first-type semiconductor layer 110, the light emitting layer 120, the second-type semiconductor layer 130, and the distributed Bragg reflector structure 260′ in the present embodiment are sequentially stacked on the first surface 171 of the growth substrate 170. In addition, the second current conducting layer 150 is filled into the through holes 166 to be electrically connected to the second-type semiconductor layer 130 and the first current conducting layer 140 is filled into the through holes 167 to be electrically connected to the first-type semiconductor layer 110. Although only one through hole 167 is illustrated in FIG. 3, in the specific implementation, the number of the through holes 167 may be adjusted based on the actual design.

In particular, in the present embodiment, the LED 200′ further includes a conductive layer 101 and a plurality of insulating patterns 103, and the insulating patterns 103 may not be connected to one another. The conductive layer 101 is disposed between the distributed Bragg reflector structure 260′ and the second-type semiconductor layer 130, and the second current conducting layer 150 filled into the through holes 166 may be in contact with the conductive layer 101 to be electrically connected to the second-type semiconductor layer 130 via the conductive layer 101. A material of the conductive layer 101 is, for example, indium tin oxide (ITO), or other materials having characteristics of current dispersion and allowing light to pass through.

On the other hand, the insulating patterns 103 are disposed between the conductive layer 101 and the second-type semiconductor layer 130, and part of the insulating patterns 103 are disposed corresponding to positions of the through holes 166, such that an area of the conductive layer 101 outside the insulating patterns 103 is in contact with the second-type semiconductor layer 130. To take a step further, a material of the insulating patterns 103 includes, for example, silicon dioxide (SiO₂) or other materials having characteristic of current blocking. The conductive layer 101 and the insulating patterns 103 are disposed to uniformly disperse the current transferred in the light emitting layer 120 to avoid the current from concentrating at certain parts of the light emitting layer 120, thereby allowing uniform distribution of the light emitting region of the light emitting layer 120. Therefore, the above configuration enables better light emitting uniformity of the LED 200′.

Additionally, in the present embodiment, the LED 200′ further includes at least one first metal layer 180 located between the first current conducting layer 140 and the first-type semiconductor layer 110 and at least one second metal layer 190 located between the second current conducting layer 150 and the second-type semiconductor layer 130. A part of the distributed Bragg reflector structure 260′ is located on the first metal layer 180 or the second metal layer 190. In other words, the first-type semiconductor layer 110, the light emitting layer 120, the second-type semiconductor layer 130, and the distributed Bragg reflector structure 260′ in the present embodiment are sequentially stacked on the first surface 171 of the growth substrate 170. In addition, the first current conducting layer 140 is filled into the through holes 167 to be electrically connected to the first metal layer 180 and the first-type semiconductor layer 130, and the second current conducting layer 150 is filled into the through holes 166 to be electrically connected to the second metal layer 190 and the second-type semiconductor layer 130.

In the present embodiment, on the other hand, the LED 200′ further includes a first insulating layer 105a and a second insulating layer 105b. The first insulating layer 105a is disposed on the first-type semiconductor layer 110, the second-type semiconductor layer 130, and sidewalls of the first-type semiconductor layer 110, the light emitting layer 120, and the second-type semiconductor layer 130. The first insulating layer 105a may further be disposed on a part of the first metal layer 180, a part of the second metal layer 190, and the conductive layer 101, and at least one part of the distributed Bragg reflector structure 260′ is located between the first insulating layer 105a and the second insulating layer 105b. Furthermore, the second insulating layer 105b may be disposed on the distributed Bragg reflector structure 260′. In other words, the first-type semiconductor layer 110, the light emitting layer 120, the second-type semiconductor layer 130, and the distributed Bragg reflector structure 260′ in the present embodiment are sequentially stacked on the first surface 171 of the growth substrate 170. In addition, the through holes 166 penetrate through the second insulating layer 105b, the distributed Bragg reflector structure 260′, and the first insulating layer 105a, so as to allow the second current conducting layer 150 to be filled into the through holes 166 and be electrically connected to the second metal layer 190 and the second-type semiconductor layer 130. Similarly, the through holes 167 penetrate through the second insulating layer 105b, the distributed Bragg reflector structure 260′, and the first insulating layer 105a, so as to allow the first current conducting layer 140 to be filled into the through holes 167 and be electrically connected to the first metal layer 180 and the first-type semiconductor layer 110. A material of the first insulating layer 105a and the second insulating layer 105b includes, for example, silicon dioxide (SiO₂), titanium dioxide (TiO₂), or the material thereof may be the same material or the same refractive material. Moreover, the material of the first insulating layer 105a and the second insulating layer 105b may further include a material contained in the distributed Bragg reflector structure 260′.

In the present embodiment, in order to electrically connect or physically connect with an external substrate during the bonding process of the flip chip, a material of the first current conducting layer 140 and the second current conducting layer 150 is, for example, gold/tin (Au/Sn) alloy or other conductive materials applicable in eutectic bonding. Herein, the first current conducting layer 140 and the second current conducting layer 150 can be used for eutectic bonding directly, but they construe no limitation in the invention. In other embodiments, the first current conducting layer 140 and the second current conducting layer 150 may be formed by the same material.

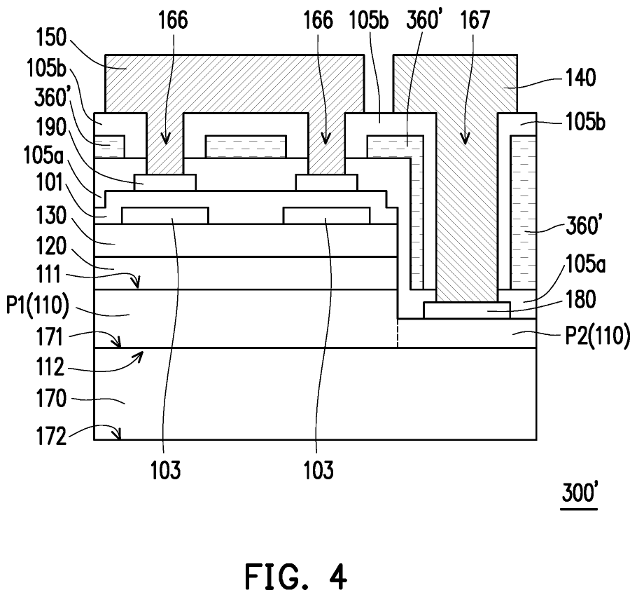

FIG. 4 is a schematic cross-sectional view of an LED according to another embodiment of the invention. Referring to FIG. 4, the LED illustrated in FIG. 4 is an LED applicable to flip chip packaging. The LED 300′ in the present embodiment is similar to the LED 200′ in FIG. 3, and a major difference lies in that: the LED 300′ further includes a first insulating layer 105a and a second insulating layer 105b, the distributed Bragg reflector structure 360′ is disposed between the first insulating layer 105a and the second insulating layer 105b, and the first insulating layer 105a and the second insulating layer 105b may partially overlap with and be in contact with each other. The first insulating layer 105a is disposed on the first-type semiconductor layer 110, the second-type semiconductor layer 130, and sidewalls of the first-type semiconductor layer 110, the light emitting layer 120, and the second-type semiconductor layer 130. The first insulating layer 105a may further be disposed on a part of the first metal layer 180, a part of the second metal layer 190, and the conductive layer 101, and the distributed Bragg reflector structure 360′ is located between the first insulating layer 105a and the second insulating layer 105b. Furthermore, the second insulating layer 105b may be disposed on the distributed Bragg reflector structure 360′, the first insulating layer 105a, a part of the first metal layer 180, and a part of the second metal layer 190, and the second insulating layer 105b may cover the distributed Bragg reflector structure 360′. In other words, the first-type semiconductor layer 110, the light emitting layer 120, the second-type semiconductor layer 130, and the distributed Bragg reflector structure 360′ in the present embodiment are sequentially stacked on the first surface 171 of the growth substrate 170. In addition, the through holes 166 penetrate through the second insulating layer 105b and the first insulating layer 105a, so as to allow the second current conducting layer 150 to be filled into the through holes 166 and be electrically connected to the second metal layer 190 and the second-type semiconductor layer 130. Similarly, the through holes 167 penetrate through the second insulating layer 105b and the first insulating layer 105a, so as to allow the first current conducting layer 140 to be filled into the through holes 167 and be electrically connected to the first metal layer 180 and the first-type semiconductor layer 110. A material of the first insulating layer 105a and the second insulating layer 105b includes, for example, silicon dioxide (SiO₂), or the material thereof may be the same material or the same refractive material. Moreover, the material of the first insulating layer 105a or the second insulating layer 105b may further include a material contained in the distributed Bragg reflector structure 360′.

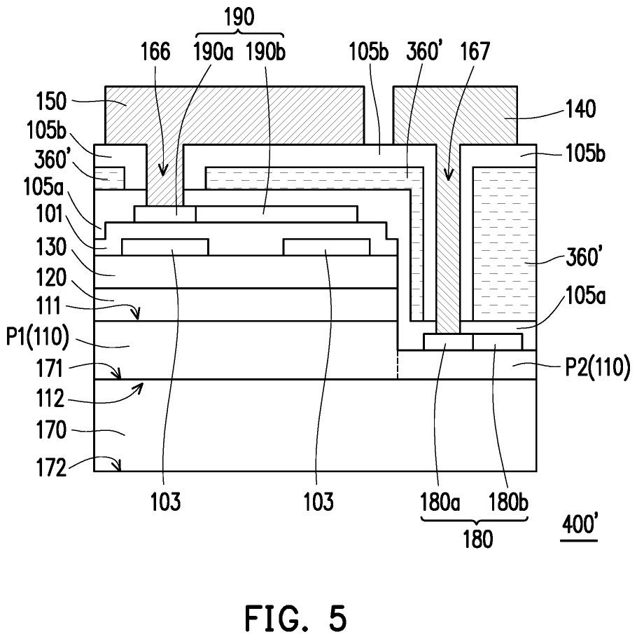

FIG. 5 is a schematic cross-sectional view of an LED according to yet another embodiment of the invention. Referring to FIG. 5, the LED illustrated in FIG. 5 is another LED applicable to flip chip packaging. The LED 400′ in the present embodiment is similar to the LED 300′ in FIG. 4, and a major difference lies in that: the first metal layer 180 includes a welding portion 180a and a finger portion 180b, and the second metal layer 190 includes a welding portion 190a and a finger portion 190b, and the first insulating layer 105a and the second insulating layer 105b may partially overlap with and be in contact with each other. The first insulating layer 105a is disposed on the first-type semiconductor layer 110, the second-type semiconductor layer 130, and sidewalls of the first-type semiconductor layer 110, the light emitting layer 120, and the second-type semiconductor layer 130. In addition, the first insulating layer 105a is disposed on a part of the first metal layer 180, a part of the second metal layer 190, and the conductive layer 101, and the first insulating layer 105 is disposed on a part of the welding portion 180a of the first metal layer 180 and the finger portion 180b of first metal layer 180. A part of the distributed Bragg reflector structure 360′ is located between the first insulating layer 105a and the second insulating layer 105b. Furthermore, the second insulating layer 105b may be disposed on the distributed Bragg reflector structure 360′, the first insulating layer 105a, a part of the first metal layer 180, and a part of the second metal layer 190. The second insulating layer 105b may further cover the distributed Bragg reflector structure 360′, and the second insulating layer 105b is disposed on a part of the welding portion 180a of the first metal layer 180 and the finger portion 180b of the first metal layer 180. In other words, the first-type semiconductor layer 110, the light emitting layer 120, the second-type semiconductor layer 130, and the distributed Bragg reflector structure 360′ in the present embodiment are sequentially stacked on the first surface 171 of the growth substrate 170. The through holes 166 penetrate through the second insulating layer 105b and the first insulating layer 105a, so as to allow the second current conducting layer 150 to be filled into the through holes 166 and be electrically connected to the welding portion 190a of the second metal layer 190 and the second-type semiconductor layer 130. The through holes 167 penetrate through the second insulating layer 105b and the first insulating layer 105a, so as to allow the first current conducting layer 140 to be filled into the through holes 167 and be electrically connected to the welding portion 180a of the first metal layer 180 and the first-type semiconductor layer 110. A material of the first insulating layer 105a and the second insulating layer 105b includes, for example, silicon dioxide (SiO₂), or the material thereof may be the same material or the same refractive material. Moreover, the material of the first insulating layer 105a or the second insulating layer 105b may further include a material contained in the distributed Bragg reflector structure 360′.

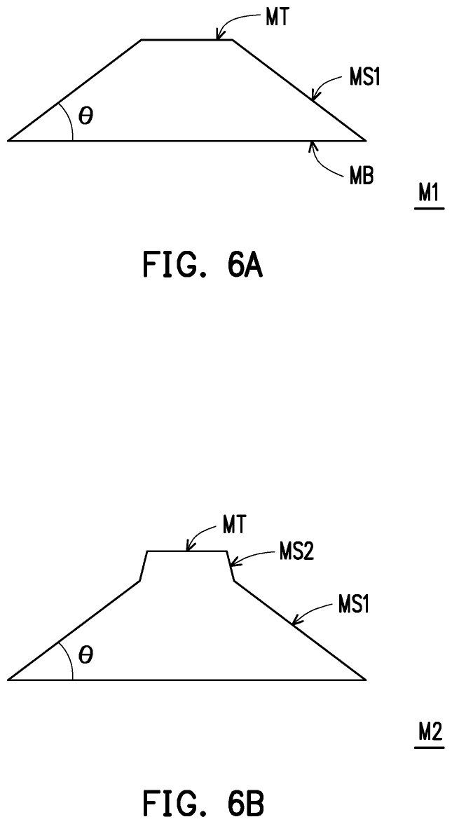

FIG. 6A is a schematic cross-sectional view of a metal layer according to an embodiment of the invention. FIG. 6B is a schematic cross-sectional view of a metal layer according to another embodiment of the invention. Referring to FIG. 6A, the metal layer M includes a top surface MT, a bottom surface MB, and side surfaces MS. The side surfaces MS and the bottom surface MB form an included angle θ, and the included angle θ may be less than or equal to 60 degrees, or less than or equal to 45 degrees. For example, the included angle θ may be 30 degrees to 45 degrees. The metal layer M can be used in at least one of the first metal layer 180 and the second metal layer 190 in the previous embodiments.

Specifically, when the metal layer M is applied to the first metal layer 180 in FIG. 3, an area of the through holes 166 can be set to fall on an area of the top surface MT, and the side surfaces MS may be at least partially covered by the first insulating layer 105a. At this time, since the included angle θ formed by the side surfaces MS and the bottom surface MB may be less than or equal to 60 degrees, the first insulating layer 105a can reliably cover the side surfaces MS. In other words, the first insulating layer 105a has an excellent coverage effect for covering a part of the metal layer M. Similarly, when the metal layer M is applied to the second metal layer 190 in FIG. 3 or at least one of the first metal layer 180 and the second metal layer 190 in FIG. 4 and FIG. 5, similar effects may be provided.

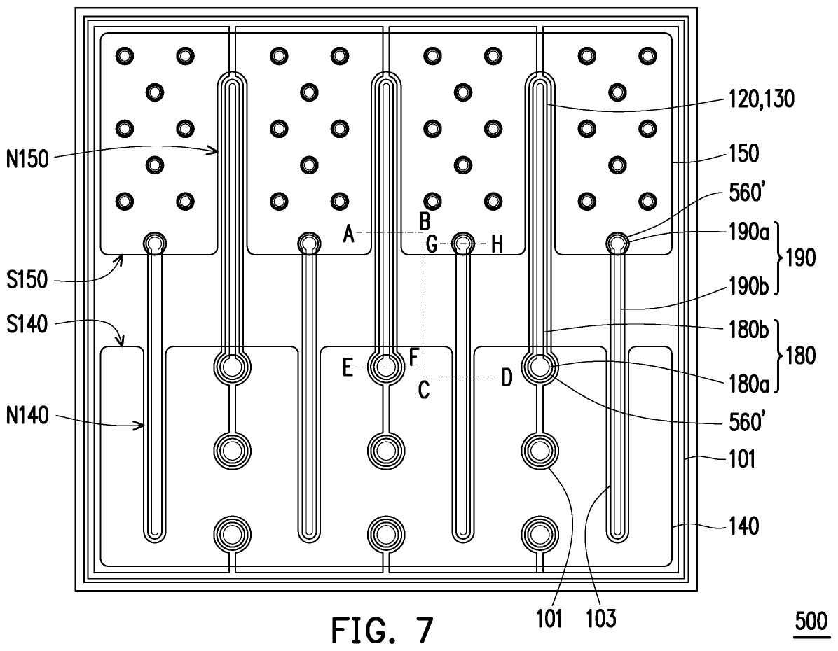

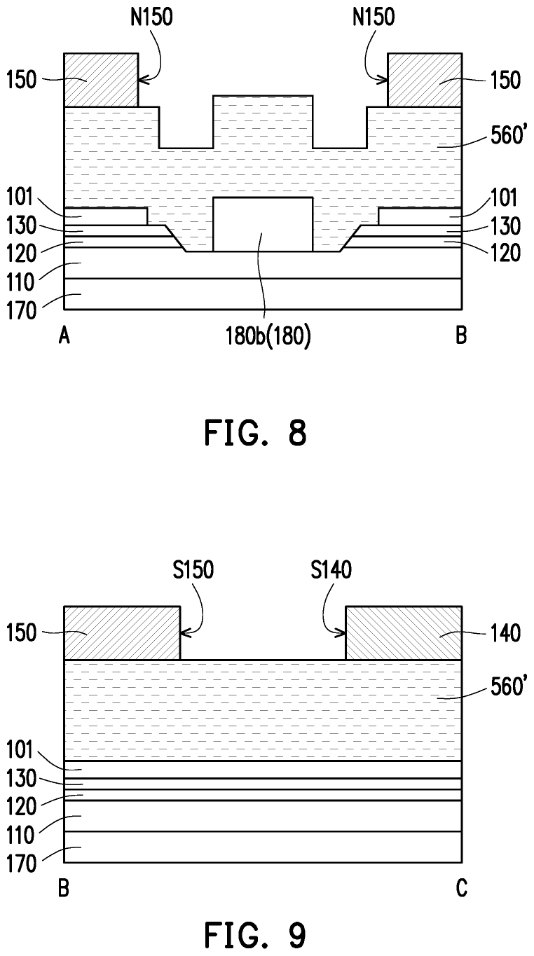

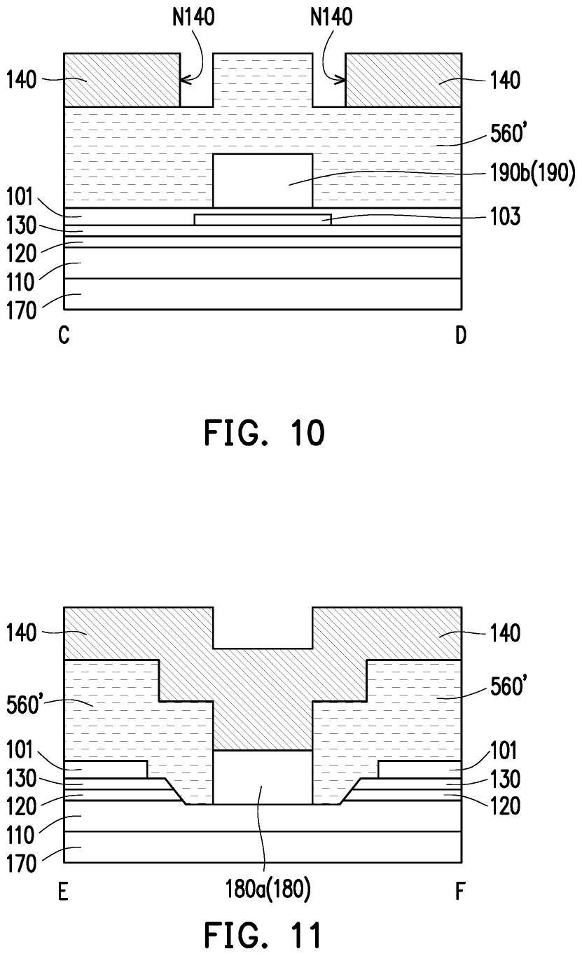

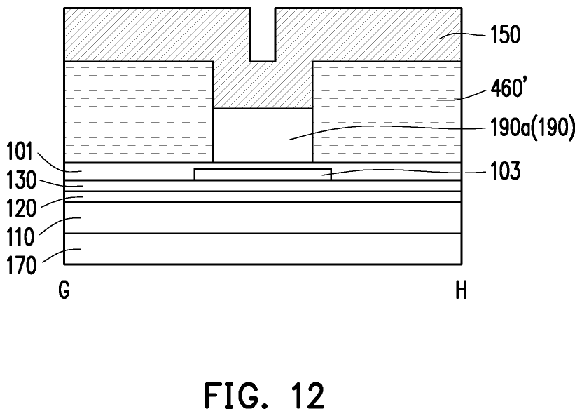

FIG. 7 is a schematic top view of an LED according to an embodiment of the invention. FIG. 8 is a schematic cross-sectional view along a line A-B of FIG. 7. FIG. 9 is a schematic cross-sectional view along a line B-C of FIG. 7. FIG. 10 is a schematic cross-sectional view along a line C-D of FIG. 7. FIG. 11 is a schematic cross-sectional view along a line E-F of FIG. 7. FIG. 12 is a schematic cross-sectional view along a line G-H of FIG. 7. In the present embodiment, the LED 500 generally includes a conductive layer 110, insulating patterns 103, a first-type semiconductor layer 110, a light emitting layer 120, a second-type semiconductor layer 130, a first current conducting layer 140, a second current conducting layer 150, a distributed Bragg reflector structure 560′, a growth substrate 170, a first metal layer 180, and a second metal layer 190. Some of the elements are not illustrated in FIG. 7 but are presented in the cross-sectional view corresponding to line A-B, B-C, C-D, E-F, or G-H.

As illustrated in FIG. 7, the first current conducting layer 140 and the second current conducting layer 150 of the LED 500 are disposed opposite to each other and are separated from each other. The first current conducting layer 140 is substantially rectangular and a sidewall S140 of the first current conducting layer 140 facing the second current conducting layer 150 has a plurality of recesses N140. The recesses N140 extend from the sidewall S140 toward an interior of the first current conducting layer 140 but do not penetrate through the first current conducting layer 140. The second current conducting layer 150 is also substantially rectangular and a sidewall S150 of the second current conducting layer 150 facing the first current conducting layer 140 has a plurality of recesses N150. The recesses N150 extend from the sidewall S150 toward an interior of the second current conducting layer 150 but do not penetrate through the second current conducting layer 150. A material of the first current conducting layer 140 and the second current conducting layer 150 is, for example, gold (Au), gold/tin (Au/Sn) alloy, or other conductive materials applicable in eutectic bonding. In other embodiments, the first current conducting layer 140 and the second current conducting layer 150 may be formed by the same material, and an additional bonding layer which is used for eutectic bonding can be disposed above the first current conducting layer 140 and the second current conducting layer 150.

In the present embodiment, the welding portion 180a of the first metal layer 180 overlaps with the first current conducting layer 140. The finger portion 180b of the first metal layer 180 extends from the welding portion 180a toward the second current conducting layer 190, and in particular, extends into the recesses N150 of the second current conducting layer 150. As illustrated in FIG. 7, the finger portion 180b and the second current conducting layer 150 do not overlap with each other on the layout area. The welding portion 190a of the second metal layer 190 overlaps with the second current conducting layer 150. The finger portion 190b of the second metal layer 190 extends from the welding portion 190a toward the first current conducting layer 180, and in particular, extends into the recesses N140 of the first current conducting layer 140.

As illustrated in FIG. 7, the finger portion 190b and the first current conducting layer 140 do not overlap with each other on the layout area. A profile of the conductive layer 101 surrounds the first metal layer 180 and does not overlap with the first metal layer 180. The insulating patterns 103 are disposed corresponding to the second metal layer 190, and profiles of the insulating patterns 103 are substantially similar to the profile of the second metal layer 190. Moreover, a profile of the distributed Bragg reflector structure 560′ correspondingly exposes the welding portion 180a of the first metal layer 180 and the welding portion 190a of the second metal layer 190. That is, the welding portion 180a of the first metal layer 180 and the welding portion 190a of the second metal layer 190 do not overlap with the distributed Bragg reflector structure 560′, so as to allow the welding portion 180a of the first metal layer 180 to be physically and electrically connected to the first current conducting layer 140 and allow the welding portion 190a of the second metal layer 190 to be physically and electrically connected to the second current conducting layer 150. However, the finger portion 180b of the first metal layer 180 and the finger portion 190b of the second metal layer 190 may overlap with the Bragg reflector structure 560′.

As illustrated in FIG. 7 and FIG. 8, in the LED 500, the first-type semiconductor layer 110, the light emitting layer 120, the second-type semiconductor layer 130, the conductive layer 101, the Bragg reflector structure 560′, and the second current conducting layer 150 are sequentially stacked on the growth substrate 170. In the stacked structure of the first-type semiconductor layer 110, the light emitting layer 120, and the second-type semiconductor layer 130, the light emitting layer 120 and the second-type semiconductor layer 130 are partially removed and the conductive layer 110 is correspondingly disconnected in this region to expose the first-type semiconductor layer 110. The first metal layer 180 is disposed on the exposed first-type semiconductor layer 110. The first metal layer 180 illustrated in FIG. 8 is the finger portion 180b, and the finger portion 180b is correspondingly located within the recesses N150 of the second current conducting layer 150 and thus does not overlap with the second current conducting layer 150. Moreover, the Bragg reflector structure 560′ overlaps with the finger portion 180b.

As illustrated in FIG. 7 and FIG. 9, between the sidewall S140 of the first current conducting layer 140 and the sidewall S150 of the second current conducting layer 150, the first-type semiconductor layer 110, the light emitting layer 120, the second-type semiconductor layer 130, the conductive layer 101, and the Bragg reflector structure 560′ are distributed continuously, and these elements are sequentially stacked on the growth substrate 170.

As illustrated in FIG. 7 and FIG. 10, at the recesses N140 of the first current conducting layer 140, the first-type semiconductor layer 110, the light emitting layer 120, the second-type semiconductor layer 130, the insulating patterns 103, the conductive layer 101, the second metal layer 190, and the distributed Bragg reflector structure 560′ are sequentially stacked on the growth substrate 170. The profiles of the insulating patterns 103 correspond to the profile of the second metal layer 190 and the two overlap with each other. Specifically, the second metal layer 190 illustrated in FIG. 10 is the finger portion 190b of the second metal layer 190, the finger portion 190b is correspondingly located within the recesses N140 of the first current conducting layer 140 and does not overlap with the first current conducting layer 140. Moreover, the distributed Bragg reflector structure 560′ overlaps with the finger portion 190b.

As illustrated in FIG. 7 and FIG. 11, in the LED 500, the first-type semiconductor layer 110, the light emitting layer 120, the second-type semiconductor layer 130, the conductive layer 101, the distributed Bragg reflector structure 560′, and the second current conducting layer 150 are sequentially stacked on the growth substrate 170. In the stacked structure of the first-type semiconductor layer 110, the light emitting layer 120, and the second-type semiconductor layer 130, the light emitting layer 120 and the second-type semiconductor layer 130 are partially removed and the conductive layer 101 and the distributed Bragg reflector structure 560′ are correspondingly disconnected in this region to expose the first-type semiconductor layer 110. The first metal layer 180 is disposed on the exposed first-type semiconductor layer 110, and the first current conducting layer 140 is filled into the disconnected location of the conductive layer 101 and the distributed Bragg reflector structure 560′ to be physically and electrically connected to the first metal layer 180. In FIG. 11, the welding portion 180a of the first metal layer 180 is illustrated. Therefore, as illustrated in FIG. 8 and FIG. 11, the welding portion 180a of the first metal layer 180 is directly in contact with and is electrically connected to the first current conducting layer, and the finger portion 180b of the first metal layer 180 overlaps with the distributed Bragg reflector structure 560′ and does not overlap with any current conducting layer.

As illustrated in FIG. 7 and FIG. 12, in an area occupied by the second current conducting layer 150, the first-type semiconductor layer 110, the light emitting layer 120, the second-type semiconductor layer 130, the insulating patterns 103, the conductive layer 101, the second metal layer 190, and the distributed Bragg reflector structure 560′ are sequentially stacked on the growth substrate 170. The profiles of the insulating patterns 103 correspond to the profile of the second metal layer 190 and the two overlap with each other. Specifically, in FIG. 12, the welding portion 190a of the second metal layer 190 overlaps with the second current conducting layer 150 and the distributed Bragg reflector structure 560′ is disconnected in a region corresponding to the welding portion 190a, so as to allow the welding portion 190a of the second metal layer 190 to be physically and electrically connected to the second current conducting layer 150. In other words, the welding portion 190a of the second metal layer 190 does not overlap with the distributed Bragg reflector structure 560′. Comparatively, in FIG. 10, the finger portion 190b of the second metal layer 190 overlaps with the distributed Bragg reflector structure 560′, but does not overlap with any current conducting layer.

As illustrated in FIG. 7 to FIG. 12, both the first metal layer 180 and the second metal layer 190 include a part overlapping with the distributed Bragg reflector structure 560′ and another part not overlapping with the distributed Bragg reflector structure 560′. The part of the metal layer (180 or 190) overlapping with the distributed Bragg reflector structure 560′ does not overlap with the current conducting layer. In this way, the thickness of the LED 500 may be more uniform, which helps to improve the yield when bonding the LED 500 to other components. In addition, in FIG. 7 to FIG. 12, the first insulating layer 105a and the second insulating layer 105b illustrated in FIG. 4 or FIG. 5 may be disposed on top and bottom sides of the distributed Bragg reflector structure 560′ additionally, and the limitation where the distributed Bragg reflector structure 560′ is directly in contact with the conductive layer 101, the first current conducting layer 140, the second current conducting layer 150, the first metal layer 180 (finger portion 180a) and the second metal layer 190 (finger portion 190a) is not required. Additionally, the cross-sectional structure of the first metal layer 180 and the second metal layer 190 may include inclined sidewalls MS as illustrated in FIG. 6.

FIG. 13 is a schematic cross-sectional view of a distributed Bragg reflector structure according to an embodiment of the invention. Referring to FIG. 13, a distributed Bragg reflector structure DBR1 is disposed between a first insulating layer I1 and a second insulating layer 12. The distributed Bragg reflector structure DBR1 includes a plurality of first refractive layers 12 and a plurality of second refractive layers 14, and the first refractive layers 12 and the second refractive layers 14 are stacked alternately. A refractive index of each of the first refractive layers 12 is different from a refractive index of each of the second refractive layers 14. In the present embodiment, thicknesses of the first refractive layers 12 and the second refractive layers 14 decrease as they come closer to the second insulating layer 12. That is, the stacking density of the first refractive layers 12 and the second refractive layers 14 increases as they come closer to the second insulating layer 12 and decreases as they come closer to the first insulating layer I1. As a result, the distributed Bragg reflector structure DBR1 is a structure having a refractive layer density that gradually increases from the first insulating layer I1 to the second insulating layer 12.

A material of the first refractive layers 12 in the present embodiment includes tantalum pentoxide (Ta₂O₅), zirconium dioxide (ZrO₂), niobium pentoxide (Nb₂O₅), hafnium oxide (HfO₂), titanium dioxide (TiO₂), or combinations thereof. On the other hand, a material of the second refractive layers 14 includes silicon dioxide (SiO₂). In the present embodiment, the material of the first insulating layer I1 and the second insulating layer 12 may also be silicon dioxide (SiO₂). However, when the material of the second refractive layers 14, the first insulating layer I1, and the second insulating layer 12 are all silicon dioxide (SiO₂), a crystallinity and a compactness of the second refractive layers 14 are smaller than the first insulating layer I1 and the second insulating layer I2. The materials and thicknesses of the first refractive layers 12 and the second refractive layers 14 may adjust the reflective wavelength range of the distributed Bragg reflector structure DBR1. Therefore, by adapting the first refractive layers 12 and the second refractive layers 14 having thicknesses gradient in the distributed Bragg reflector structure DBR1 of the present embodiment, the distributed Bragg reflector structure DBR1 may have a broader reflective wavelength range to be suitable in end products requiring light emitting effects in broad wavelength range.

For example, when titanium dioxide (TiO₂) is used to fabricate the first refractive layers 12 and silicon dioxide (SiO₂) is used to fabricate the second refractive layers 14, the distributed Bragg reflector structure DBR1 with the thickness gradient exhibited in the refractive layers may be applicable to visible light emitting devices. When tantalum pentoxide (Ta₂O₅) is used to fabricate the first refractive layers 12 and silicon dioxide (SiO₂) is used to fabricate the second refractive layers 14, the distributed Bragg reflector structure DBR1 with the thickness gradient exhibited in the refractive layers may be applicable to ultraviolet light emitting devices. However, the material and the applications on the light emitting devices described above are merely used as examples, and in actuality, when the distributed Bragg reflector structure DBR1 is fabricated by other materials, the application thereof may be adjusted based on the reflective wavelength range exhibited.

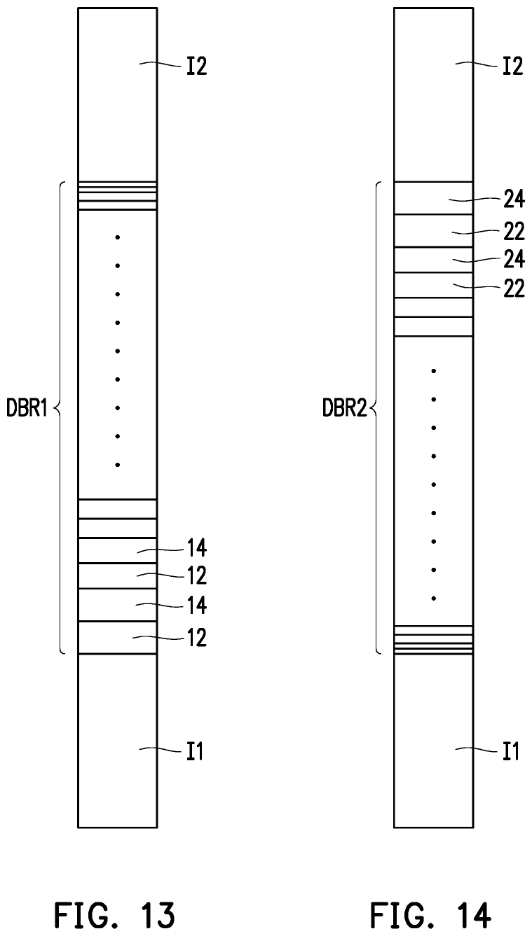

FIG. 14 is a schematic cross-sectional view of a distributed Bragg reflector structure according to another embodiment of the invention. Referring to FIG. 14, a distributed Bragg reflector structure DBR2 is disposed between a first insulating layer I1 and a second insulating layer 12. The distributed Bragg reflector structure DBR1 includes a plurality of first refractive layers 22 and a plurality of second refractive layers 24, and the first refractive layers 22 and the second refractive layers 24 are stacked alternately. A refractive index of each of the first refractive layers 22 is different from a refractive index of each of the second refractive layers 24. In the present embodiment, the thicknesses of the first refractive layers 22 and the second refractive layers 24 increase as they come closer to the second insulating layer 12. That is, the stacking density of the first refractive layers 22 and the second refractive layers 24 decreases as they come closer to the second insulating layer 12 and increases as they come closer to the first insulating layer I1. As a result, the distributed Bragg reflector structure DBR2 is a structure having a refractive layer density that gradually decreases from the first insulating layer I1 to the second insulating layer 12.

The materials and thicknesses of the first refractive layers 22 and the second refractive layers 24 may adjust the reflective wavelength range of the distributed Bragg reflector structure DBR2. A material of the first refractive layers 22 includes tantalum pentoxide (Ta₂O₅), zirconium dioxide (ZrO₂), niobium pentoxide (Nb₂O₅), hafnium oxide (HfO₂), titanium dioxide (TiO₂), or combinations thereof. On the other hand, a material of the second refractive layers 24 includes silicon dioxide (SiO₂).

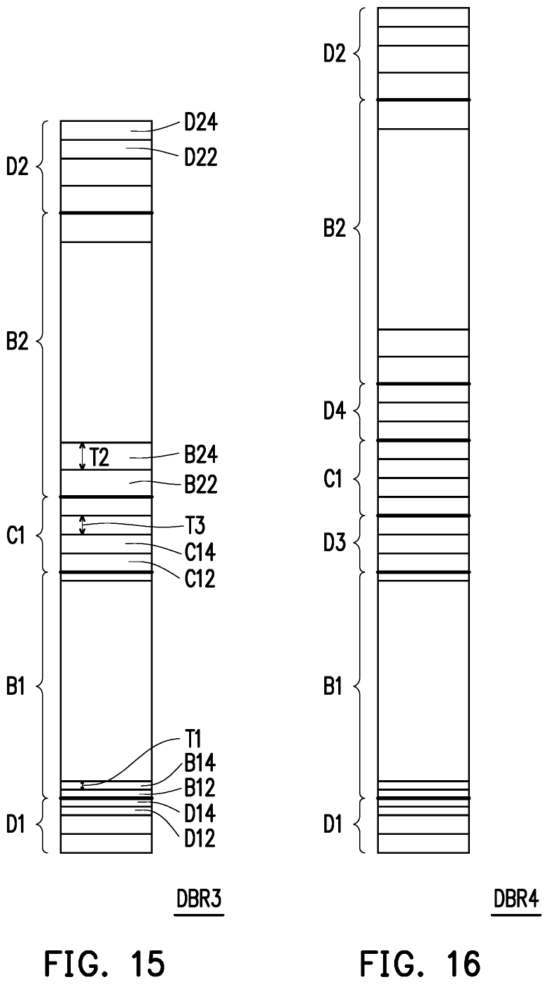

FIG. 15 is a schematic cross-sectional view of a distributed Bragg reflector structure according to yet another embodiment of the invention. Referring to FIG. 15, a distributed Bragg reflector structure DBR3 includes primary stacked layers B1 and B2, a buffer stacked layer C1, and repair stacked layers D1 and D2. The primary stacked layer B1 is formed by alternately stacking first refractive layers B12 and second refractive layers B14 having a refractive index different from the first refractive layers B12 in a repeating manner. The primary stacked layer B2 is formed by alternately stacking first refractive layers B22 and second refractive layers B24 having a refractive index different from the first refractive layers B22 in a repeating manner. The buffer stacked layer C1 is formed by alternately stacking third refractive layers C12 and fourth refractive layers C14 having a refractive index different from the third refractive layers C12 in a repeating manner. The repair stacked layer D1 is formed by alternately stacking fifth refractive layers D12 and sixth refractive layers D14 having a refractive index different from the fifth refractive layers D12 in a repeating manner. The repair stacked layer D2 is formed by alternately stacking fifth refractive layers D22 and sixth refractive layers D24 having a refractive index different from the fifth refractive layers D22 in a repeating manner.

In the present embodiment, the first refractive layers B12 and B22, the third refractive layers C12, and the fifth refractive layers D12 and D22 in the same distributed Bragg reflector structure DBR3 may have the same material or different materials. The material thereof includes tantalum pentoxide (Ta₂O₅), zirconium dioxide (ZrO₂), niobium pentoxide (Nb₂O₅), hafnium oxide (HfO₂), titanium dioxide (TiO₂), or combinations thereof. The second refractive layers B14 and B24, the fourth refractive layers C14, and the sixth refractive layers D14 and D24 in the same distributed Bragg reflector structure DBR3 may have the same material or different materials, and the material thereof includes silicon dioxide (SiO₂).

In addition, in the primary stacked layer B1, each of the first refractive layers B12 has an equal first thickness T1 and the second refractive layer B14 has the equal first thickness T1. In the primary stacked layer B2, each of the first refractive layers B22 has an equal second thickness T2 and the second refractive layer B24 has the equal second thickness T2. Moreover, the first thickness T1 is different from the second thickness T2. In other words, a single primary stacked layer B1 or B2 has periodically stacked refractive layers, but the stacked period of the refractive layers in different primary stacked layers are different. As a result, by stacking multiple primary stacked layers B1 and B2, the distributed Bragg reflector structure DBR3 is able to provide a broad reflective wavelength range.

In the buffer stacked layer C1 between the primary stacked layer B1 and the primary stacked layer B2, the third refractive layers C12 and the fourth refractive layers C14 have a third thickness T3. The third thickness T3 may be an average value of the first thickness T1 and the second thickness T2. In other words, T3=1/2(T1+T2). However, the thicknesses of the third refractive layers C12 and the fourth refractive layers C14 may be respectively between the first thickness T1 and the second thickness T2.

Moreover, the thicknesses of the fifth refractive layers D12 and the sixth refractive layers D14 in the repair stacked layer D1 may approach the first thickness T1 as they come closer to the primary stacked layer B1. The thicknesses of the fifth refractive layers D22 and the sixth refractive layers D24 in the repair stacked layer D2 may approach the second thickness T2 as they come closer to the primary stacked layer B2. That is, the repair stacked layer D1 and the repair stacked layer D2 are stacked structures having thickness gradient in the refractive layers. Moreover, the material composition of the repair stacked layer D1 can be related to the primary stacked layer B1, and the material composition of the repair stacked layer D2 can be related to the primary stacked layer B2.

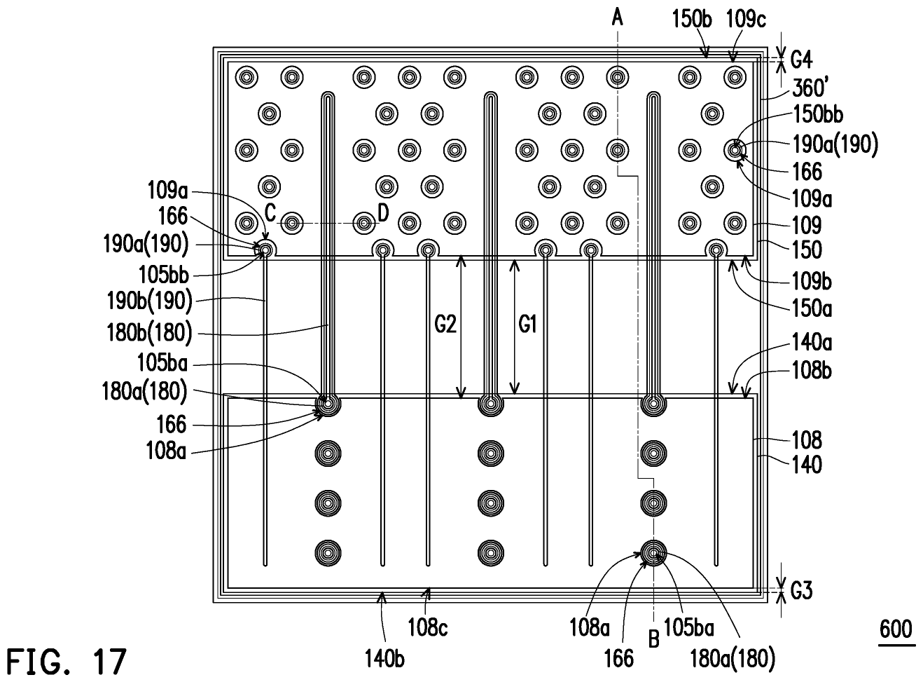

FIG. 16 is a schematic cross-sectional view of a distributed Bragg reflector structure according to yet another embodiment of the invention. Referring to FIG. 16, a distributed Bragg reflector structure DBR4 is similar to the foregoing distributed Bragg reflector structure DBR3, but the distributed Bragg reflector structure DBR4 further includes a repair stacked layer D3 and a repair stacked layer D4. The repair stacked layer D3 is located between the buffer stacked layer C1 and the primary stacked layer B1, and the repair stacked layer D4 is located between the buffer stacked layer C1 and the primary stacked layer B2. The thicknesses of the refractive layers of the repair stacked layer D3 may approach the first thickness T1 as they come closer to the primary stacked layer B1. The thicknesses of the refractive layers of the repair stacked layer D4 may approach the second thickness T2 as they come closer to the primary stacked layer B2. Moreover, the material composition of the repair stacked layer D3 can be related to the primary stacked layer B1, and the material composition of the repair stacked layer D4 can be related to the primary stacked layer B2.

The distributed Bragg reflector structures DBR1-DBR4 in FIG. 13 to FIG. 16 may be applicable to any one of the LEDs in FIGS. 1, 2, 3, 4, 5, and 7. That is, any one of the distributed Bragg reflector structures presented in the foregoing embodiments can be achieved by adopting any of the distributed Bragg reflector structures DBR1-DBR4 in FIG. 13 to FIG. 16. Under the condition where the distributed Bragg reflector structure has a stacked structure with thickness gradient in refractive layers or has a stacked structure by multiple refractive layers having different thicknesses, the distributed Bragg reflector structure is able to provide a broader reflective wavelength range.

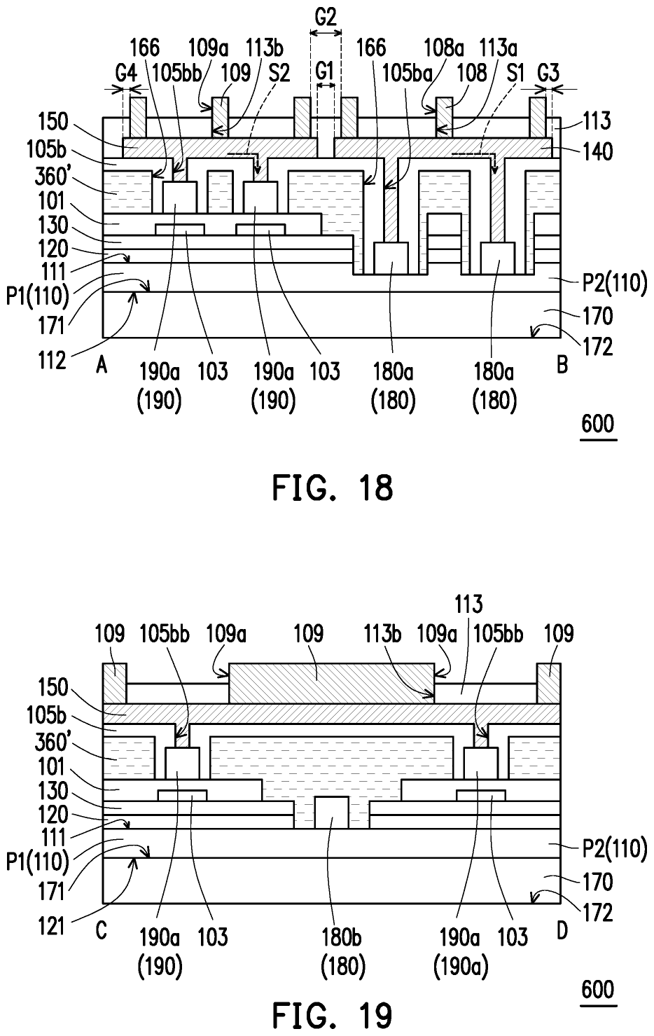

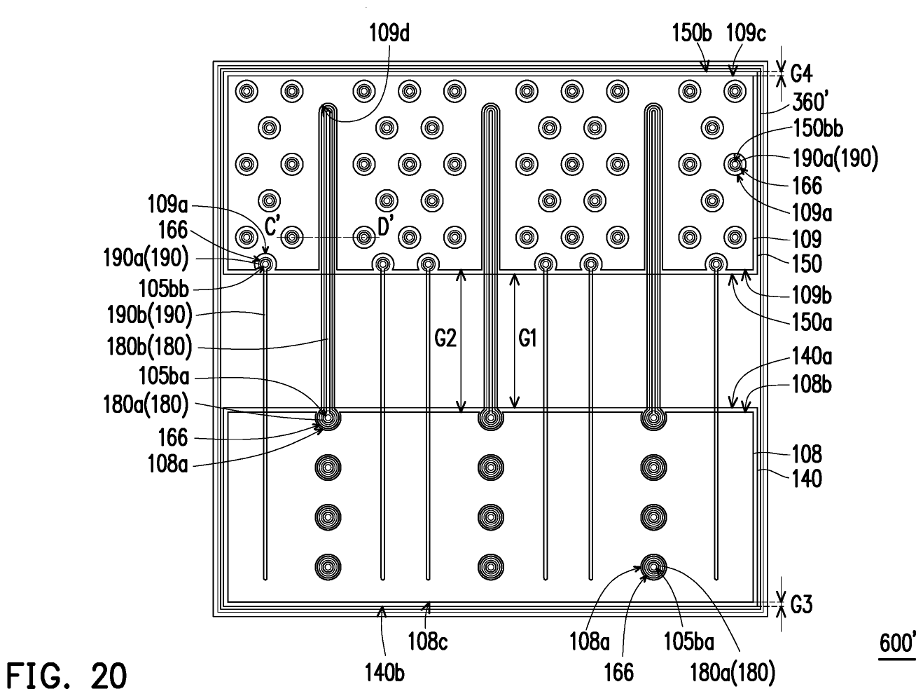

FIG. 17 is a schematic top view of an LED according to an embodiment of the invention. FIG. 18 is a schematic cross-sectional view along a line A-B of FIG. 17. FIG. 19 is a schematic cross-sectional view along a line C-D of FIG. 17. Referring to FIG. 17, FIG. 18, and FIG. 19, an LED 600 of flip chip packaging is illustrated. Referring to FIG. 17, FIG. 18, and FIG. 19, the LED 600 includes a first-type semiconductor layer 110, a light emitting layer 120, a second-type semiconductor layer 130, a first metal layer 180, a second metal layer 190, a first current conducting layer 140, a second current conducting layer 150, a first bonding layer 108, and a second bonding layer 109. The light emitting layer 120 is located between the first-type semiconductor layer 110 and the second-type semiconductor layer 130. The first metal layer 180 is located on the first-type semiconductor layer 110 and electrically connected to the first-type semiconductor layer 110. The first metal layer 180 is located between the first current conducting layer 140 and the first-type semiconductor layer 110. The first current conducting layer 140 is electrically connected to the first-type semiconductor layer 110 via the first metal layer 180. The first current conducting layer 140 is located between the first bonding layer 108 and the first metal layer 180. The first bonding layer 108 is electrically connected to the first-type semiconductor layer 110 via the first current conducting layer 140 and the first metal layer 180. The second metal layer 190 is located on the second-type semiconductor layer 130 and electrically connected to the second-type semiconductor layer 130. The second metal layer 190 is located between the second current conducting layer 150 and the second-type semiconductor layer 130. The second current conducting layer 150 is electrically connected to the second-type semiconductor layer 130 via the second metal layer 190. The second current conducting layer 150 is located between the second bonding layer 109 and the second metal layer 190. The second bonding layer 109 is electrically connected to the second-type semiconductor layer 130 via the second current conducting layer 150 and the second metal layer 190. Similar to some of the foregoing embodiments, the LED 600 further includes a second insulating layer 105b, a distributed Bragg reflector structure 360′, insulating patterns 103, and an insulating layer 113.

It should be noted that the first bonding layer 108 has a plurality of through holes 108a. In the top view (as illustrated in FIG. 17), the first metal layer 180 overlaps with the first through holes 108a of the first bonding layer 108. In other words, a physical portion of the first metal layer 180 is displaced relative to a physical portion of the first bonding layer 108. An area of the physical portion of the first metal layer 180 and an area of the physical portion of the first bonding layer 108 may selectively not overlap with each other. For example, in the present embodiment, the first metal layer 180 includes a welding portion 180a that overlaps with the first current conducting layer 140, and a finger portion 180b that extends from the welding portion 180a toward the second current conducting layer 150. In the present embodiment, the second insulating layer 105b is disposed between the first current conducting layer 140 and the first metal layer 180, and the second insulating layer 105b has a through hole 105ba that overlaps with the welding portion 180a. The first current conducting layer 140 is filled into the through hole 105ba of the second insulating layer 105b to be electrically connected to the welding portion 180a of the first metal layer 180. More specifically, an area of the through hole 105ba of the second insulating layer 105b is smaller than an area of the welding portion 180a of the first metal layer 180 and located within the area of the welding portion 180a of the first metal layer 180. The area of the welding portion 180a of the first metal layer 180 is smaller than an area of the through hole 166 of the distributed Bragg reflector structure 360′ and located within the area of the through hole 166 of the distributed Bragg reflector structure 360′, and the area of the through hole 166 of the distributed Bragg reflector structure 360′ is smaller than an area of the first through hole 108a of the first bonding layer 108 and located within the area of the first through hole 108a of the first bonding layer 108 (not shown).

Similarly, the second bonding layer 109 has a plurality of second through holes 109a. In the top view (as illustrated in FIG. 17), the second metal layer 190 overlaps with the second through holes 109a of the second bonding layer 109. In other words, a physical portion of the second metal layer 190 is displaced relative to a physical portion of the second bonding layer 109. An area of the physical portion of the second metal layer 190 and an area of the physical portion of the second bonding layer 109 may selectively not overlap with each other. For example, in the present embodiment, the second metal layer 190 includes a welding portion 190a that overlaps with the second current conducting layer 150, and a finger portion 190b that extends from the welding portion 190a toward the first current conducting layer 140. The second insulating layer 105b has a through hole 105bb that overlaps with the welding portion 190a of the second metal layer 190. The second current conducting layer 150 is filled into the through hole 105bb of the second insulating layer 105b to be electrically connected to the welding portion 190a of the second metal layer 190. More specifically, an area of the through hole 105bb of the second insulating layer 105b is smaller than an area of the welding portion 190a of the second metal layer 190 and located within the area of the welding portion 190a of the second metal layer 190. The area of the welding portion 190a of the second metal layer 190 is smaller than an area of the through hole 166 of the distributed Bragg reflector structure 360′ and located within the area of the through hole 166 of the distributed Bragg reflector structure 360′, and the area of the through hole 166 of the distributed Bragg reflector structure 360′ is smaller than an area of the second through hole 109a of the second bonding layer 109 and located within the area of the first through hole 109a of the second bonding layer 109 (not shown).

The first bonding layer 108 and the second bonding layer 109 are used for electrically connecting an external circuit board (not shown) in the flip chip bonding process. Since the physical portion of the first bonding layer 108 and the physical portion of the first metal layer 180 are displaced, and the physical portion of the second bonding layer 109 and the physical portion of the second metal layer 190 are displaced (that is, a current conductive path S1 exists between the first bonding layer 108 and the first metal layer 180, and a current conductive path S2 exists between the second bonding layer 109 and the second metal layer 190), in the flip chip bonding process, the bonding material (e.g., solder paste or gold tin eutectic) does not easily flow through the path S1 and/or the path S2 completely to cause a short circuit problem.

A gap G1 exists between the first current conducting layer 140 and the second current conducting layer 150 to electrically isolate them from each other. In detail, in the present embodiment, the first current conducting layer 140 has an inner edge 140a and an outer edge 140b opposite to each other, and the inner edge 140a is closer to the second current conducting layer 150 than the outer edge 140b; the second current conducting layer 150 has an inner edge 150a and an outer edge 150b opposite to each other, and the inner edge 150a is closer to the first current conducting layer 140 than the outer edge 150b; the gap G1 between the first current conducting layer 140 and the second current conducting layer 150 may refer to a distance between the inner edge 140a of the first current conducting layer 140 and the inner edge 150a of the second current conducting layer 150.

A gap G2 exists between the first bonding layer 108 and the second bonding layer 109 to electrically isolate them from each other. In detail, in the present embodiment, the first bonding layer 108 has an inner edge 108b and an outer edge 108c opposite to each other, and the inner edge 108b is closer to the second bonding layer 109 than the outer edge 108c; the second bonding layer 109 has an inner edge 109b and an outer edge 109c opposite to each other, and the inner edge 109b is closer to the first bonding layer 108 than the outer edge 109c; and the gap G2 between the first bonding layer 108 and the second bonding layer 109 may refer to a distance between the inner edge 108b of the first bonding layer 108 and the inner edge 109b of the second bonding layer 109.

It should be noted that, in the present embodiment, the gap G2 between the first bonding layer 108 and the second bonding layer 109 is larger than the gap G1 between the first current conducting layer 140 and the second current conducting layer 150. In addition, a gap G3 exists between the outer edge 108c of the first bonding layer 108 and the outer edge 140b of the first current conducting layer 140, and a gap G4 exists between the outer edge 109c of the second bonding layer 109 and the outer edge 150b of the second current conducting layer 150. In other words, as illustrated in FIG. 17, in the present embodiment, the area of the first bonding layer 108 is smaller than the area of the first current conducting layer 140, and the first bonding layer 108 is located within the area of the first current conducting layer 140; and the area of the second bonding layer 109 is smaller than the area of the second current conducting layer 150, and the second bonding layer 109 is located within the area of the second current conducting layer 150. Thereby, in the flip chip bonding process, the bonding material (e.g., solder paste) does not easily overflow outside the first current conducting layer 140 from the first bonding layer 108, and does not easily overflow outside the second current conducting layer 150 from the second bonding layer 109, so as to prevent a short circuit problem.

For example, in the present embodiment, at least one of the first metal layer 180, the second metal layer 190, the first current conducting layer 140, and the second current conducting layer 150 may include an ohmic contact layer, a reflective layer, a blocking stacked layer, and a connection layer stacked on one another. The ohmic contact layer includes Cr, Ti, or combinations thereof, for example; the reflective layer includes Al, Alloy Al, Alloy Al/Cu, Ag, Pt, or combinations thereof, for example; the blocking stacked layer includes Ti, Ni, Al, Au, Pt, or combinations thereof, for example; and the connection layer includes Ti, Ni, Al, Au, Pt, or combinations thereof, for example. For example, in the present embodiment, at least one of the first bonding layer 108 and the second bonding layer 109 may include a reflective layer, a blocking stacked layer, and a welding layer stacked on one another. A material of the reflective layer includes Al, Alloy Al, Alloy Al/Cu, Ti, Ni, Pt, or combinations thereof, for example; a material of the blocking stacked layer includes Ti, Ni, Al, Au, Pt, or combinations thereof, for example; and a material of the welding layer includes Au, Sn, Alloy Au/Sn, Alloy Sn, Alloy Sn/Ag/Cu, or combinations thereof, for example.

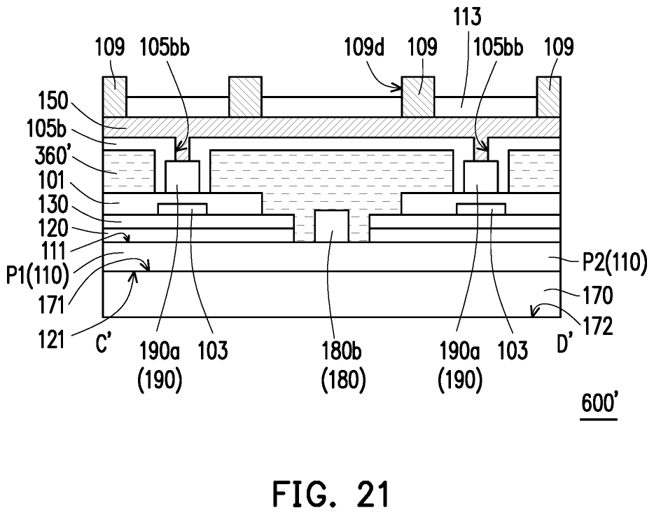

Referring to FIG. 17 and FIG. 19, in the present embodiment, the finger portion 180b of the first metal layer 180 may be covered by the distributed Bragg reflector structure 360′, and extend to be under the second current conducting layer 150 and the second bonding layer 109 to partially overlap with the second current conducting layer 150 and the second bonding layer 109. However, the invention is not limited thereto. In other embodiments, the finger portion 180b of the first metal layer 180 may not overlap with the second bonding layer 109, which is described hereinafter with reference to FIG. 20 and FIG. 21 as an example.

FIG. 20 is a schematic top view of an LED according to another embodiment of the invention. FIG. 21 is a schematic cross-sectional view along a line C′-D′ of FIG. 20. Referring to FIG. 20 and FIG. 21, the LED 600′ as illustrated is applicable to flip chip packaging. The LED 600′ in the present embodiment is similar to the foregoing LED 600, and a major difference lies in that: the inner edge 109b of the second bonding layer 109 of the LED 600′ has a recess 109d that extends from the inner edge 109b toward the interior of the second bonding layer 109 but does not penetrate through the second bonding layer 109, and the finger portion 180b of the first metal layer 180 may extend into the area of the recess 109d without overlapping with the second bonding layer 109. In short, in the present embodiment, the finger portion 180b of the first metal layer 180 and the second bonding layer 109 may be displaced. In the flip chip bonding process, since the physical portion of the second bonding layer 109 and the physical portion of the first metal layer 180 are displaced, when the bonding material (e.g., solder paste or gold tin eutectic) is bonded to the second bonding layer 109, the bonding material does not come into contact with the first metal layer 180 to cause a short circuit problem.

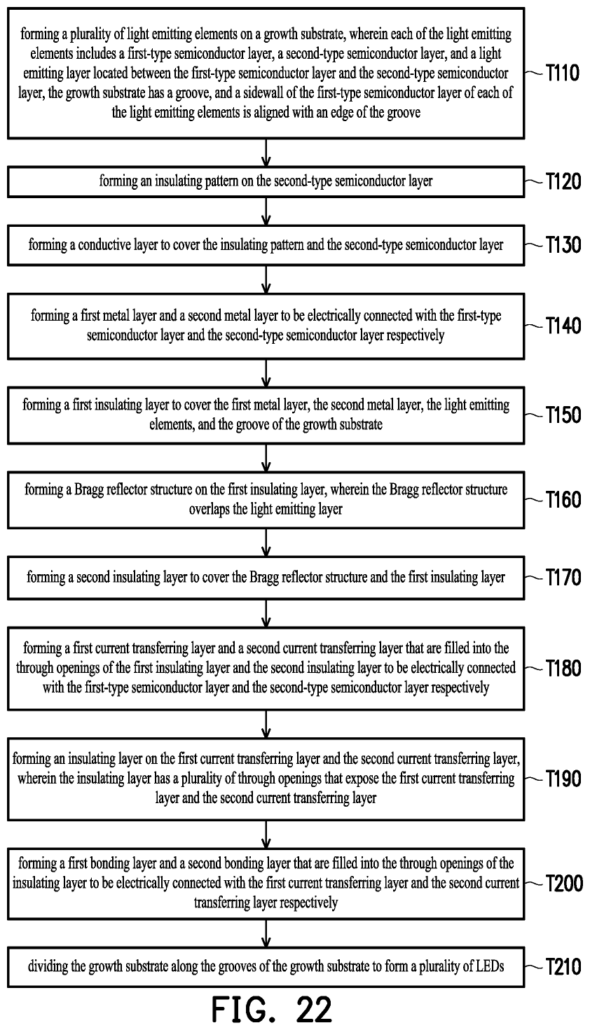

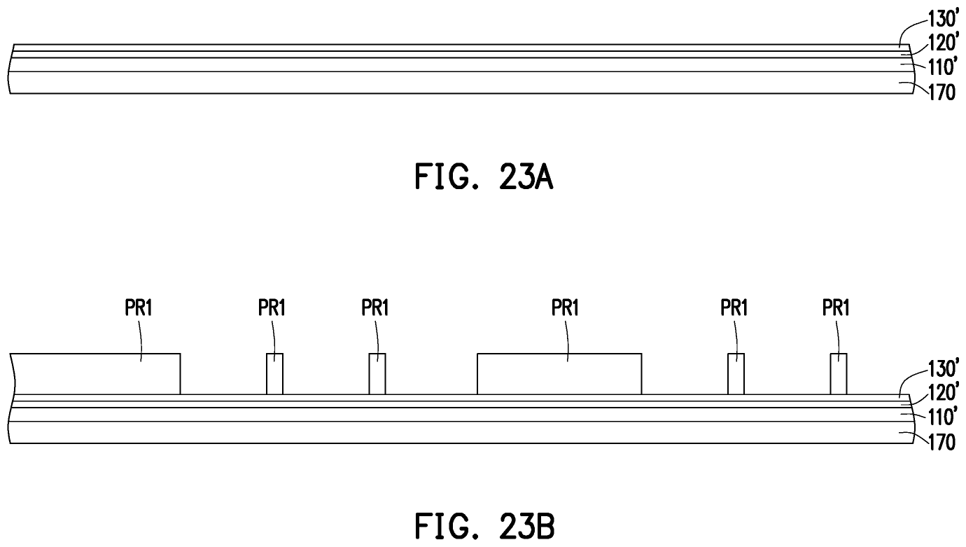

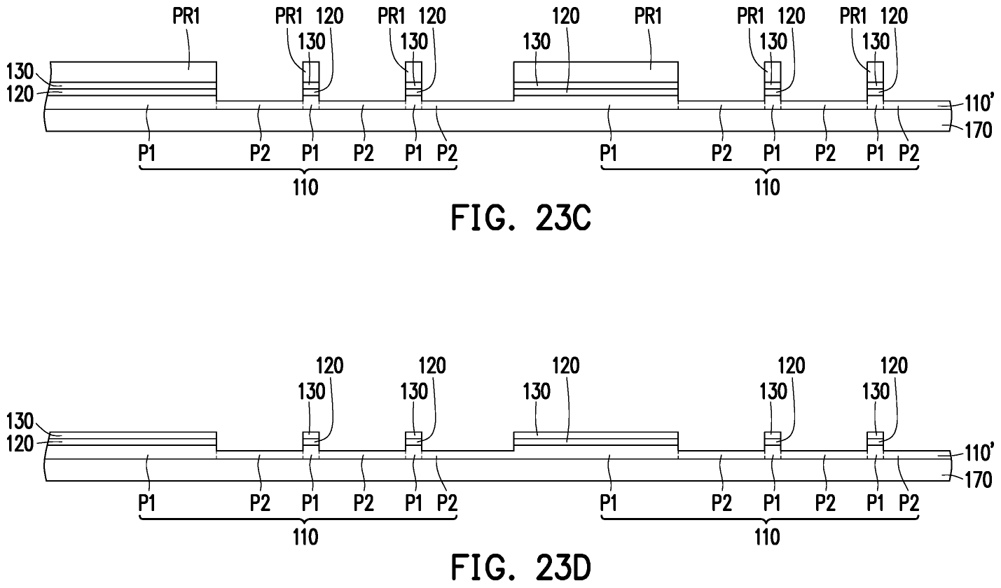

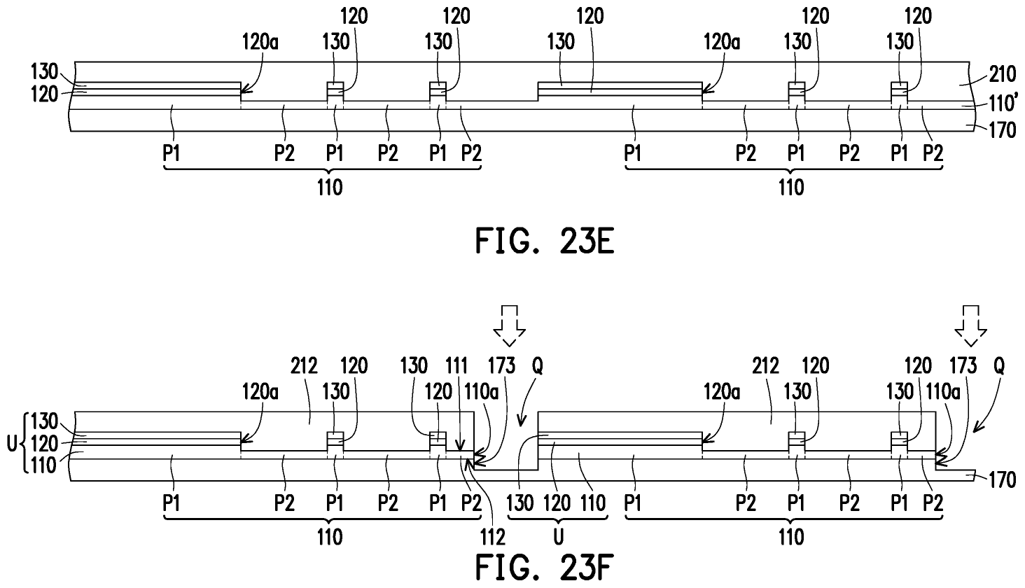

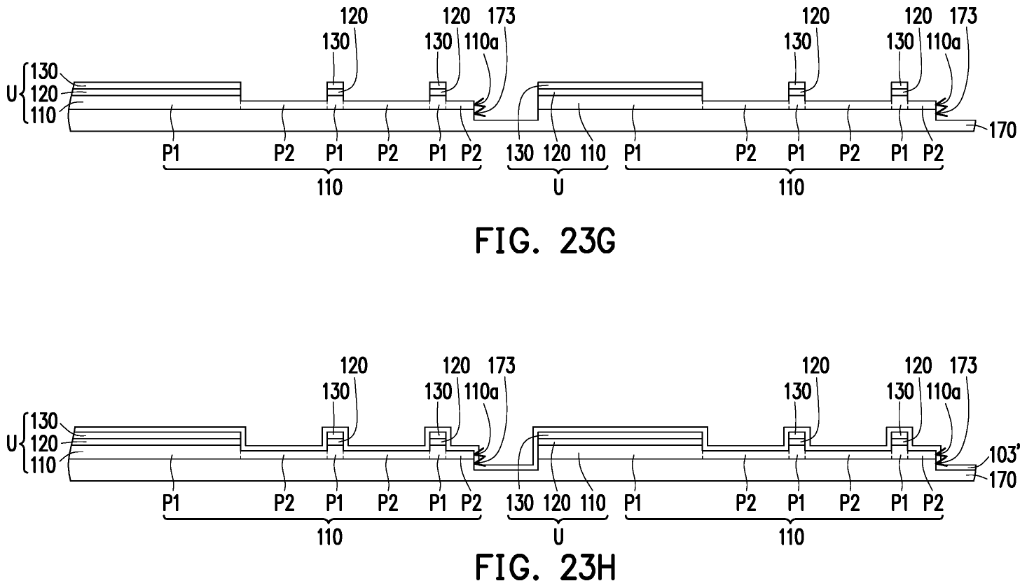

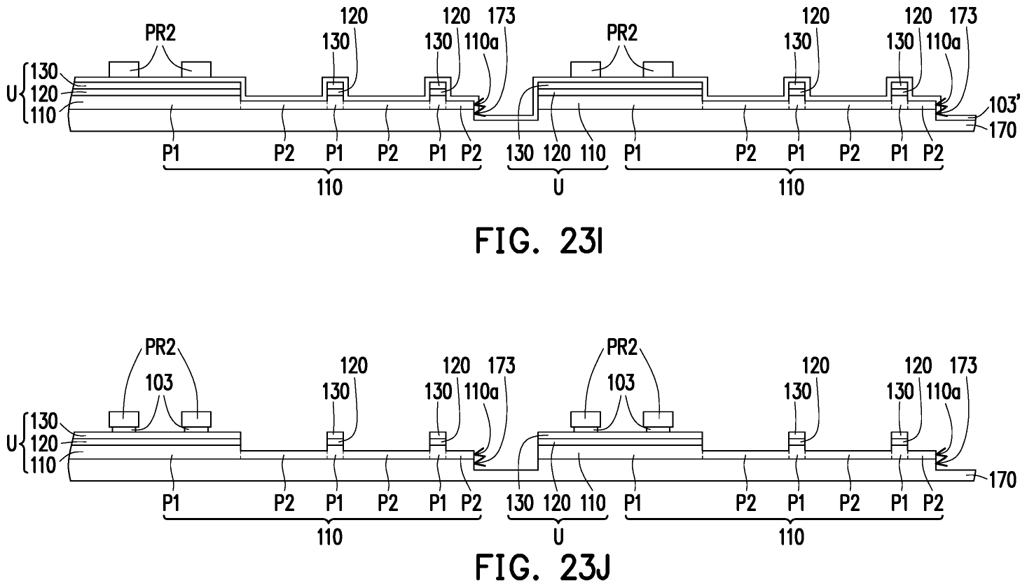

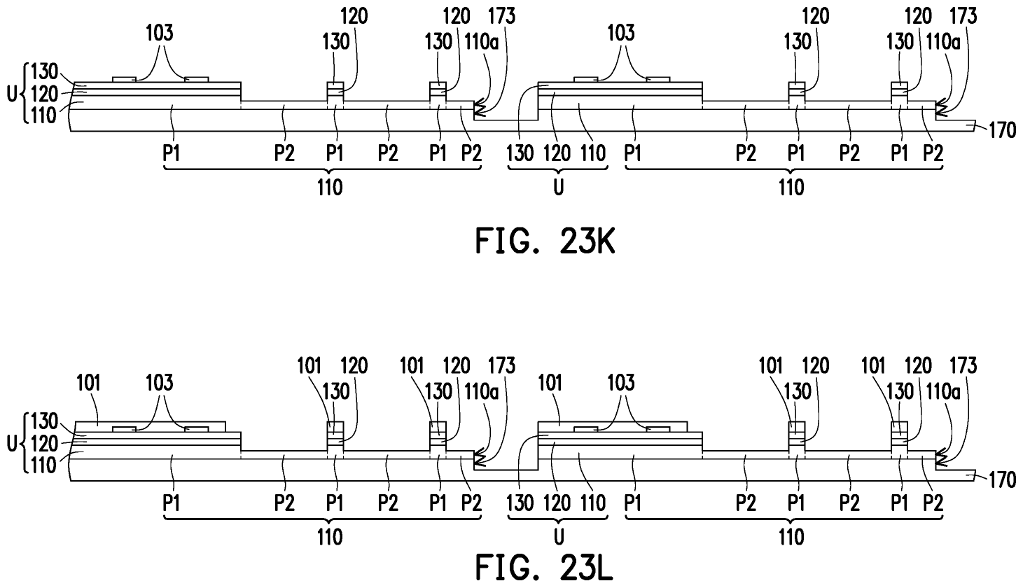

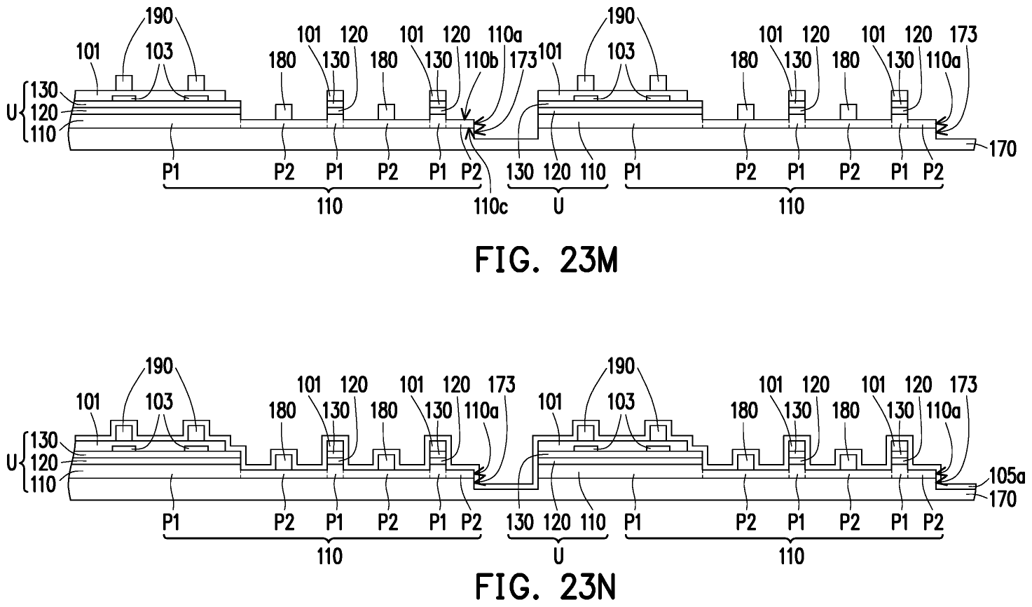

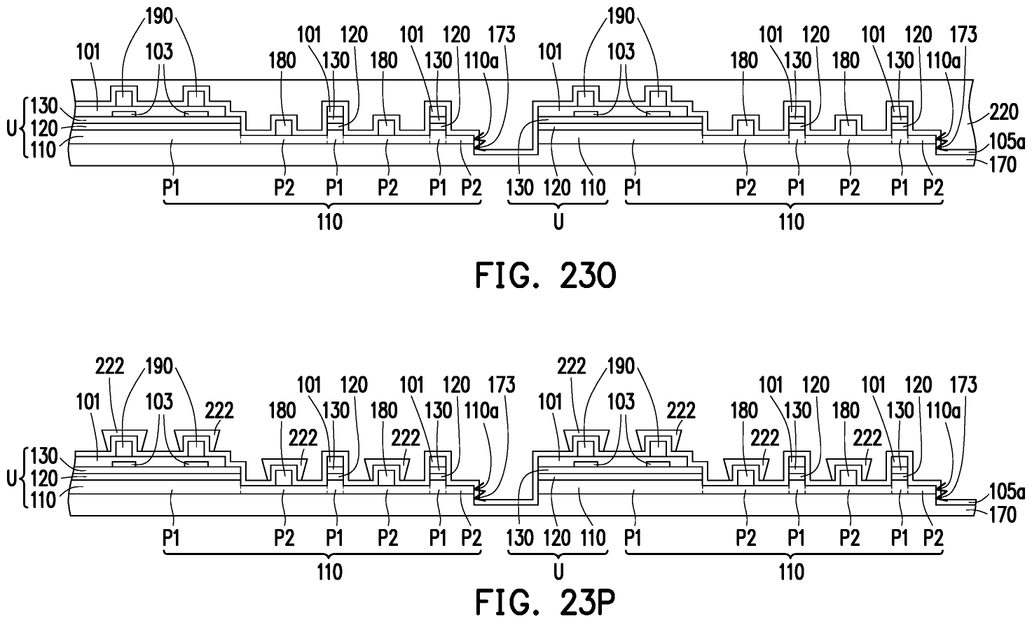

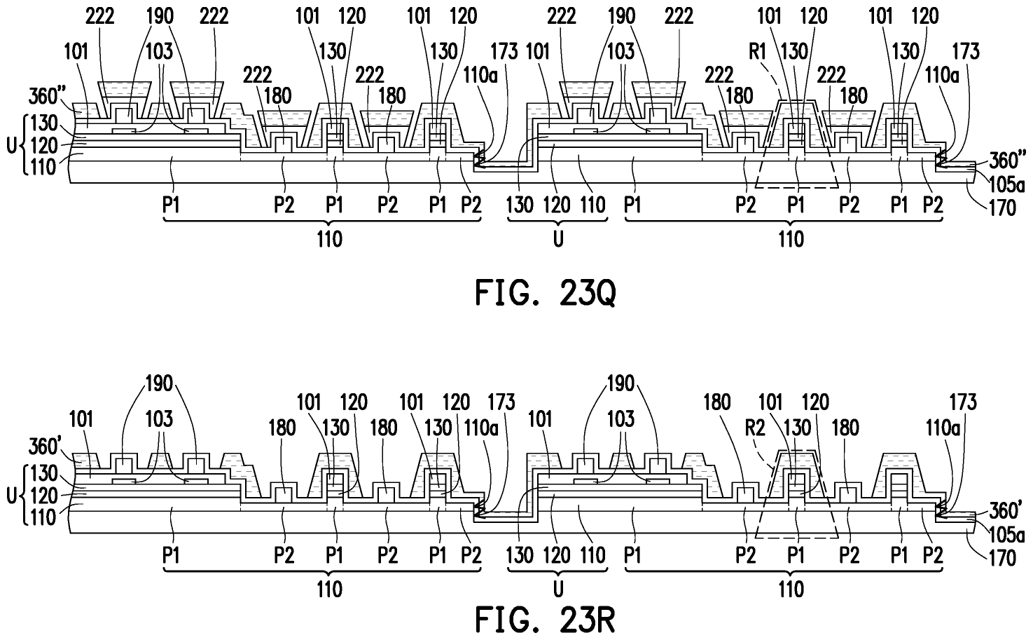

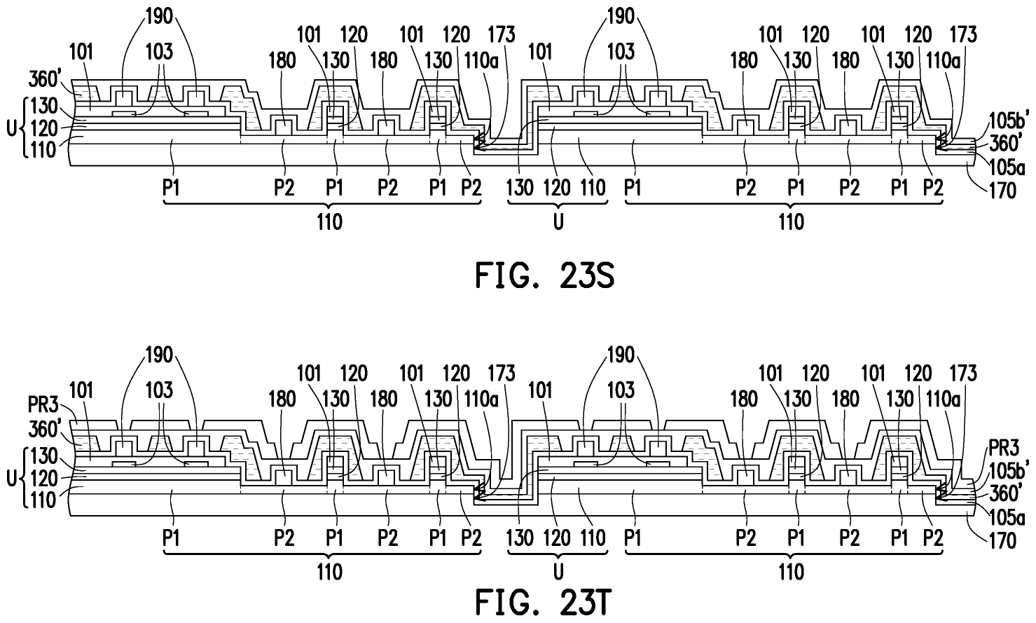

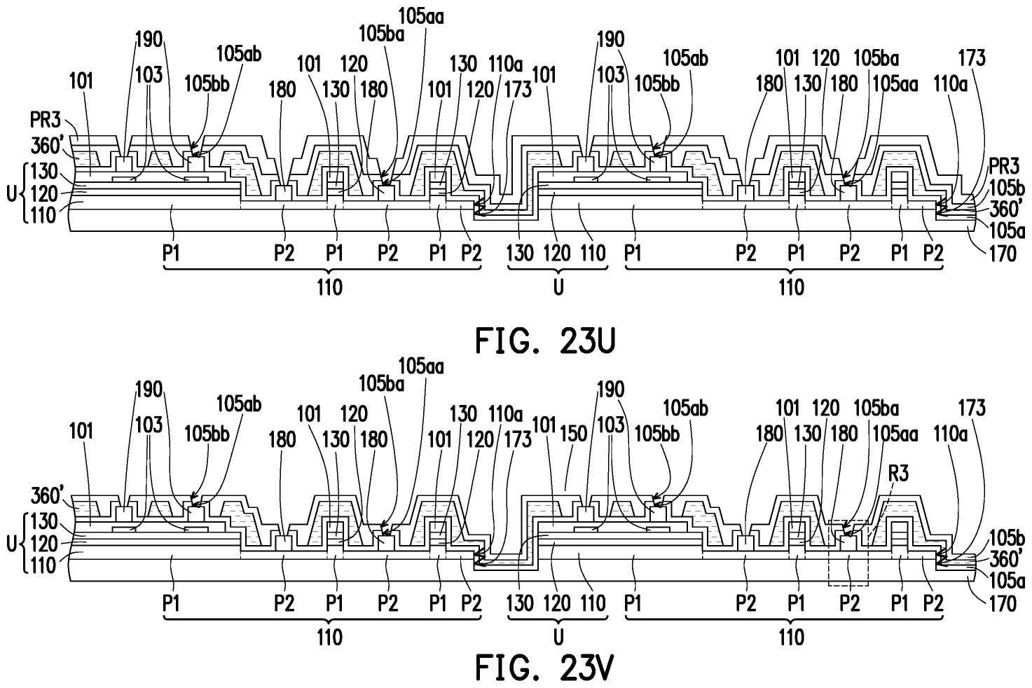

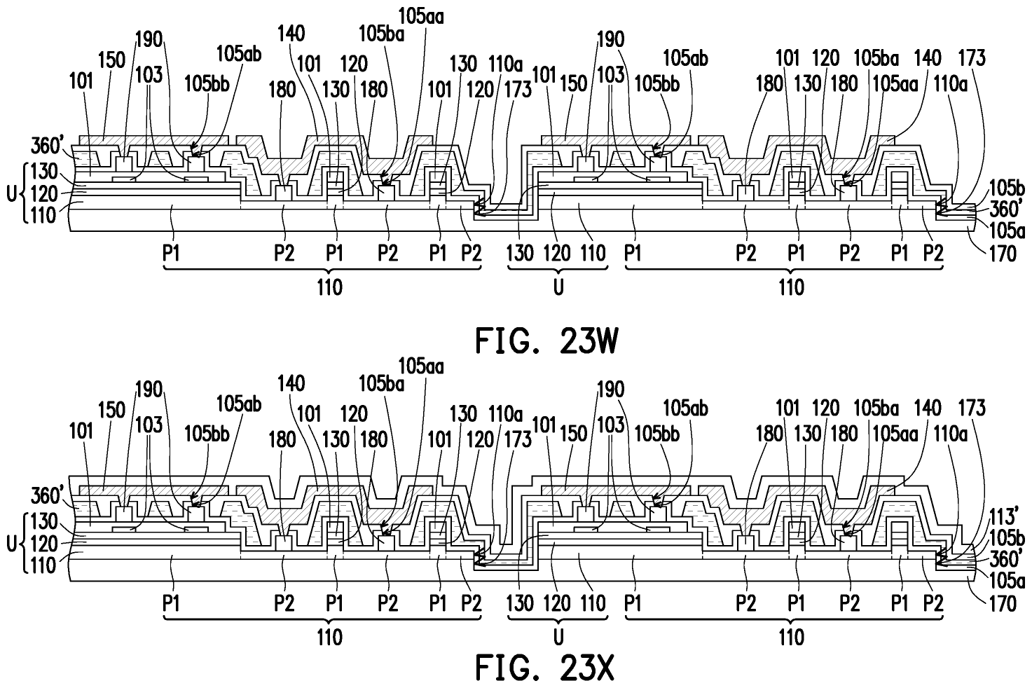

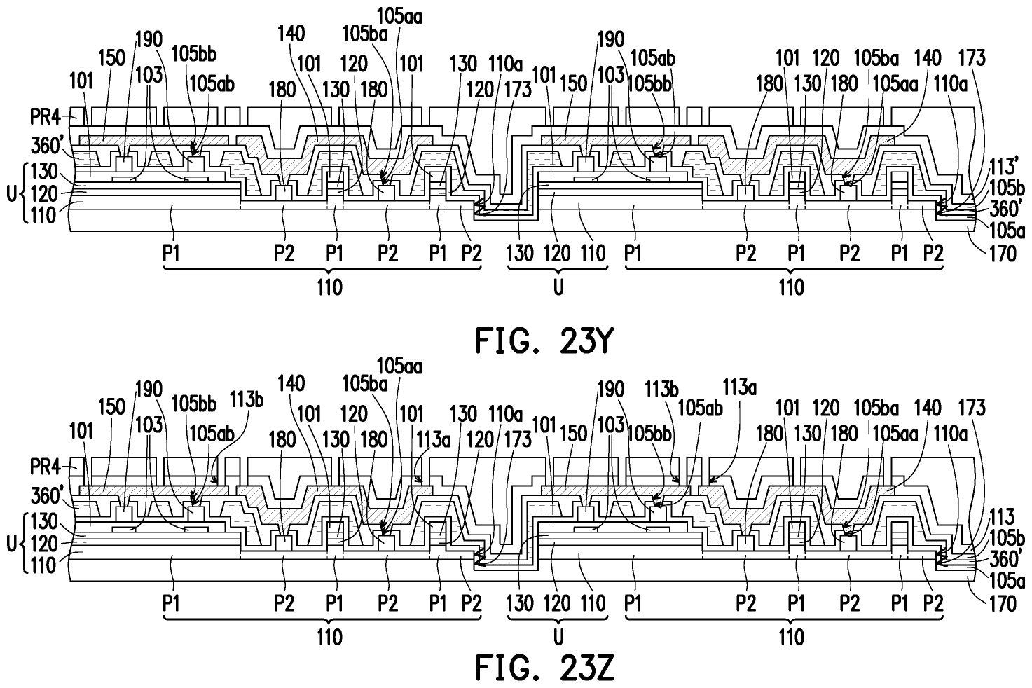

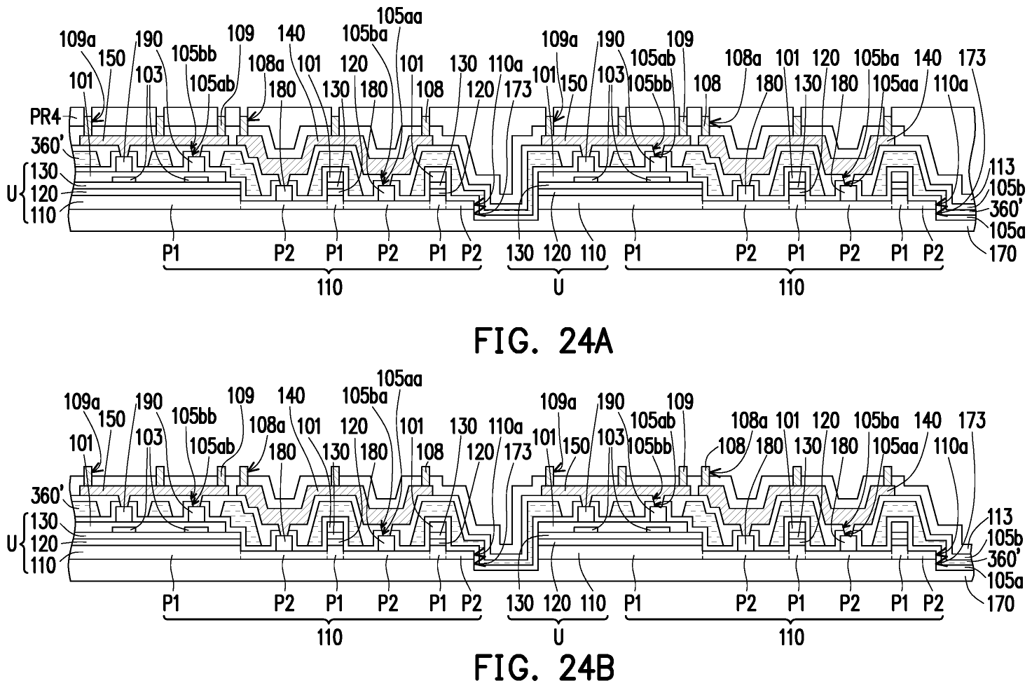

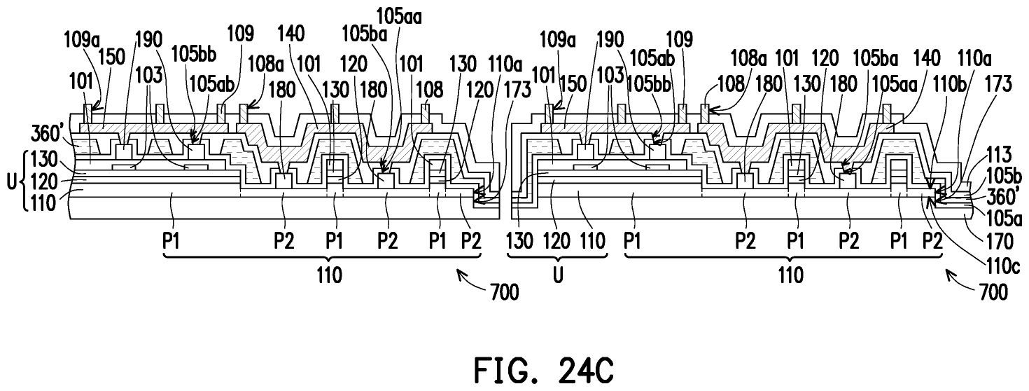

FIG. 22 is a flowchart of manufacturing an LED according to an embodiment of the invention. Referring to FIG. 22, for example, in the present embodiment, a manufacturing method of the LED 700 (illustrated in FIG. 24B) includes: forming a plurality of light emitting elements on a growth substrate, wherein each of the light emitting elements includes a first-type semiconductor layer, a second-type semiconductor layer, and a light emitting layer located between the first-type semiconductor layer and the second-type semiconductor layer, the growth substrate has a groove, and a sidewall of the first-type semiconductor layer of each of the light emitting elements is aligned with an edge of the groove (Step T110); forming an insulating pattern on the second-type semiconductor layer (Step T120); forming a conductive layer to cover the insulating pattern and the second-type semiconductor layer (Step T130); forming a first metal layer and a second metal layer to be electrically connected to the first-type semiconductor layer and the second-type semiconductor layer respectively (Step T140); forming a first insulating layer to cover the first metal layer, the second metal layer, the light emitting elements, and the groove of the growth substrate (Step T150); forming a distributed Bragg reflector structure on the first insulating layer, wherein the distributed Bragg reflector structure overlaps with the light emitting layer (Step T160); forming a second insulating layer to cover the distributed Bragg reflector structure and the first insulating layer, wherein the first insulating layer and the second insulating layer have a plurality of through holes that expose the first metal layer and the second metal layer (Step T170); forming a first current conducting layer and a second current conducting layer that are filled into the through holes of the first insulating layer and the second insulating layer to be electrically connected to the first-type semiconductor layer and the second-type semiconductor layer respectively (Step T180); forming an insulating layer on the first current conducting layer and the second current conducting layer, wherein the insulating layer has a plurality of through holes that expose the first current conducting layer and the second current conducting layer (Step T190); forming a first bonding layer and a second bonding layer that are filled into the through holes of the insulating layer to be electrically connected to the first current conducting layer and the second current conducting layer respectively (Step T200); and dividing the growth substrate along the groove of the growth substrate to form a plurality of LEDs (Step T210). FIG. 23A to FIG. 24C are schematic cross-sectional views showing a manufacturing method of an LED according to an embodiment of the invention, corresponding to the flowchart of manufacturing the LED of FIG. 22. The manufacturing method of the LED 700 (illustrated in FIG. 24C) according to an embodiment of the invention is described hereinafter with reference to FIG. 22 and FIG. 23A to FIG. 24C.

Referring to FIG. 22, first, Step T110 is performed. That is, a plurality of light emitting elements are formed on the growth substrate, wherein each of the light emitting elements includes the first-type semiconductor layer, the second-type semiconductor layer, and the light emitting layer located between the first-type semiconductor layer and the second-type semiconductor layer, and the growth substrate has the groove, and the sidewall of the first-type semiconductor layer of each of the light emitting elements is aligned with the edge of the groove. In the present embodiment, Step T110 of FIG. 22 may correspond to FIG. 23A to FIG. 23G. A possible method of performing Step T110 is described hereinafter with reference to FIG. 23A to FIG. 23G as an example.

Referring to FIG. 23A, in the present embodiment, first, a first-type semiconductor material layer 110′ may be formed on the growth substrate 170, a light emitting material layer 120′ may be formed on the first-type semiconductor material layer 110′, and a second-type semiconductor material layer 130′ may be formed on the light emitting material layer 120′. Referring to FIG. 23B, then, a patterned photoresist PR1 is formed on the stacked structure of the first-type semiconductor material layer 110′, the light emitting material layer 120′, and the second-type semiconductor material layer 130′. For example, in the present embodiment, the patterned photoresist PR1 may be formed by a yellow lithography process, but the invention is not limited thereto. Referring to FIG. 23C, next, the second-type semiconductor material layer 130′, the light emitting material layer 120′, and the first-type semiconductor material layer 110′ are patterned with the patterned photoresist PR1 as a mask to form the second-type semiconductor layer 130, the light emitting layer 120, and the first-type semiconductor material layer 110′ that has a first portion P1 and a second portion P2, wherein the light emitting layer 120 is stacked on the first portion P1 of the first-type semiconductor material layer 110′, and the second portion P2 extends outward from the first portion P1 to protrude outside the area of the light emitting layer 120. A thickness of the second portion P2 may be smaller than a thickness of the first portion P1. For example, in the present embodiment, the second-type semiconductor layer 130, the light emitting layer 120, and the first-type semiconductor material layer 110′ that has the first portion P1 and the second portion P2 may be formed by a dry etching process, but the invention is not limited thereto. Referring to FIG. 23D, then, the patterned photoresist PR1 is removed.

Referring to FIG. 23E, thereafter, a first sacrificial layer 210 is formed to cover the second-type semiconductor layer 120, the light emitting layer 130, and the first-type semiconductor material layer 110′. Referring to FIG. 23E and FIG. 23F, next, as illustrated in FIG. 23F, a scribing process is performed on the growth substrate 170, the second portion P2 of the first-type semiconductor material layer 110′, and the first sacrificial layer 210 located on the second portion P2 to form a scribing mark Q. The scribing mark Q penetrates through a part of the first sacrificial layer 210 and the second portion P2 of the first-type semiconductor material layer 110′ to divide the first sacrificial layer 210 into a plurality of first sacrificial patterns 212 and divide the first-type semiconductor material layer 110′ into a plurality of first-type semiconductor layers 110. The first-type semiconductor layers 110 together with the light emitting layers 120 and the second-type semiconductor layers 130 thereon may form a plurality of light emitting elements U. Each of the light emitting elements U includes the first-type semiconductor layer 110, the second-type semiconductor layer 130, and the light emitting layer 120 located between the first-type semiconductor layer 110 and the second-type semiconductor layer 130. It should be noted that, as the scribing mark Q defines the first-type semiconductor layers 110 of the light emitting elements U, the scribing mark Q further extends to the growth substrate 170 and form the groove 173 that does not penetrate through the growth substrate 170 on the growth substrate 170. Since the growth substrate 170 and the first-type semiconductor material layer 110′ are cut in the same process, the sidewall 110a of the first-type semiconductor layer 110 of each of the light emitting elements U is aligned with the groove 173 of the growth substrate 170. The first-type semiconductor layer 110 has the first surface 111 and the second surface 112 opposite to each other. The light emitting layer 120 and the second-type semiconductor layer 130 are disposed on the first surface 112, and the sidewall 110a is connected between the first surface 111 and the second surface 112.

Referring to FIG. 23G, then, the first sacrificial pattern 212 is removed, by which Step T110 of FIG. 22 is completed. It should be noted that, in the process of forming the first-type semiconductor layers 110 of the light emitting elements U (i.e., in the foregoing scribing process), as illustrated in FIG. 23E, the first sacrificial layer 210 covers the second portion P2 of the first-type semiconductor material layer 110′, the second-type semiconductor layer 130, and the sidewall 120a of the light emitting layer 120. Thus, the light emitting element U does not easily have defects resulting from damage (e.g., particle contamination) in the forming process, which helps to improve the light emission efficiency of the LED formed subsequently.

Referring to FIG. 22, next, Step T120 is performed. That is, the insulating pattern is formed on the second-type semiconductor layer. In the present embodiment, Step T120 of FIG. 22 may correspond to FIG. 23H to FIG. 23K. A possible method of performing Step T120 is described hereinafter with reference to FIG. 23H to FIG. 23K as an example.

Referring to FIG. 23H, in the present embodiment, an insulating material layer 103′ may be formed on the light emitting element U. For example, the insulating material layer 103′ may be formed by vapor deposition, sputtering, or plasma assisted chemical vapor deposition, but the invention is not limited thereto. Referring to FIG. 23I, next, a patterned photoresist PR2 is formed on the insulating material layer 103′ located on the second-type semiconductor layer 130.

Referring to FIG. 23J, then, the insulating material layer 103′ is patterned with the patterned photoresist PR2 as a mask to form the insulating patterns 103. For example, the insulating material layer 103′ may be patterned by wet or dry etching to form the insulating patterns 103, but the invention is not limited thereto. Referring to FIG. 23K, thereafter, the patterned photoresist PR2 is removed, by which Step T120 of FIG. 22 is completed. It should be noted that FIG. 23H to FIG. 23K merely illustrate a possible method of performing Step T120, and the invention is not limited thereto. In other embodiments, other methods may be used, such as a lift-off process. More specifically, after the patterned photoresist PR2 is formed on the light emitting element U as a mask, the insulating material layer 103′ is formed by vapor deposition, sputtering, or plasma assisted chemical vapor deposition to conformally cover the patterned photoresist PR2. Then, the lift-off process is performed, referring to FIG. 23K, to remove the patterned photoresist PR2, so as to remove the insulating material layer 103′ on the patterned photoresist PR2 while removing the patterned photoresist PR2 to complete Step T120. The repetitive descriptions are omitted.

Referring to FIG. 22 and FIG. 23L, next, Step T130 is performed. That is, the conductive layer 101 is formed on the second-type semiconductor layer 130 to cover the insulating pattern 103. In the present embodiment, the conductive layer 101 further covers a part of the second-type semiconductor layer 130 not covered by the insulating pattern 130 to be electrically connected to the second-type semiconductor layer 130. Referring to FIG. 22 and FIG. 23M, thereafter, Step T140 is performed. That is, the first metal layer 180 and the second metal layer 190 are formed to be electrically connected to the first-type semiconductor layer 110 and the second-type semiconductor layer 130 respectively. In detail, in the present embodiment, the first metal layer 180 may be formed on the first portion P1 of the first-type semiconductor layer 110 to be electrically connected to the first-type semiconductor layer 110 directly; and the second metal layer 190 may be formed on the conductive layer 101 located on the second-type semiconductor layer 130 to be electrically connected to the second-type semiconductor layer 130 via the conductive layer 101.

Referring to FIG. 22 and FIG. 23N, then, Step T150 is performed. That is, the first insulating layer 105a is formed to cover the first metal layer 180, the second metal layer 190, the light emitting element U, and the groove 173 of the growth substrate 170. For example, in the present embodiment, the first insulating layer 105a may be formed by vapor deposition, sputtering, or plasma assisted chemical vapor deposition, but the invention is not limited thereto. In the present embodiment, the first insulating layer 105a may comprehensively cover the growth substrate 170 and the components thereon. It should be noted that, because of the design of the groove 173 of the growth substrate 170, the first insulating layer 105a may also cover the sidewall 110a of the first-type semiconductor layer 110. Thus, in the subsequent manufacturing processes of the LED and/or the eutectic bonding process, the sidewall 110a of the first-type semiconductor layer 110 is not easily electrically connected to improper components to cause a short circuit problem.

Referring to FIG. 22, next, Step T160 is performed. That is, the distributed Bragg reflector structure is formed on the first insulating layer, wherein the distributed Bragg reflector structure overlaps with the light emitting layer. In the present embodiment, Step T160 of FIG. 22 may correspond to FIG. 23O to FIG. 23R. A possible method of performing Step T160 is described hereinafter with reference to FIG. 23O to FIG. 23R as an example.

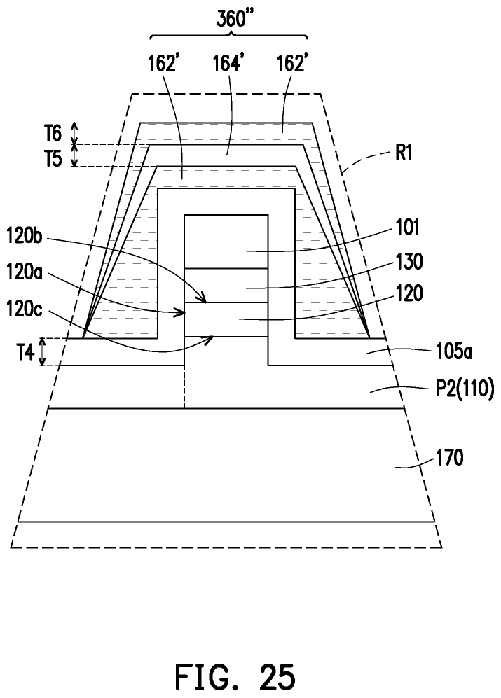

Referring to FIG. 23O, a sacrificial layer 220 is formed on the first insulating layer 105a. In the present embodiment, the sacrificial layer 220 is a photoresist layer, for example, but the invention is not limited thereto. Referring to FIG. 23O and FIG. 23P, then, the sacrificial layer 220 is patterned to form a sacrificial pattern 222. In the present embodiment, a process of patterning the sacrificial layer 220 may include lithography and etching processes and the sacrificial pattern 222 may have an inverted trapezoidal structure, but the invention is not limited thereto. FIG. 25 is a schematic partially enlarged view of a part R1 of FIG. 23Q. Referring to FIG. 23Q and FIG. 25, thereafter, a plurality of first refractive material layers 162′ (illustrated in FIG. 25) and a plurality of second refractive material layers 164′ (illustrated in FIG. 25) stacked alternately are formed on the sacrificial pattern 222 and the first insulating layer 105a not covered by the sacrificial pattern 222. The first refractive material layers 162′ and the second refractive material layers 164′ may be regarded as a distributed Bragg reflective material stacked layer 360″ (illustrated in FIG. 25).

FIG. 26 is a schematic partially enlarged view of a part R2 of FIG. 23R. Referring to FIG. 23Q, FIG. 23R, FIG. 25, and FIG. 26, then, the sacrificial pattern 222 is removed. When the sacrificial pattern 222 is removed, a part of the first refractive material layers 162′ and a part of the second refractive material layers 164′ on the sacrificial pattern 222 are removed as well, and a part of the first refractive material layers 162′ and a part of the second refractive material layers 164′ on the first insulating layer 105a are retained. Thus, the first refractive material layers 162′ and the second refractive material layers 164′ may be patterned to form a patterned structure (i.e., the distributed Bragg reflector structure 360′) formed by stacking the first refractive layers 162 and the second refractive layers 164.

A thickness T4 of the first insulating layer 105b is much larger than a thickness T5 of one first refractive layer 162 or a thickness T6 of one second refractive layer 164 of the distributed Bragg reflector structure 360′. For example, 30×T5≤T4 and 30×T6≤T4, but the invention is not limited thereto. In short, in the present embodiment, the stacked structure of the first refractive material layers 162′ and the second refractive material layers 164′ is patterned by a lift-off process to form the distributed Bragg reflector structure 360′. However, the invention is not limited thereto. In other embodiments, the distributed Bragg reflector structure 360′ may be formed by other suitable methods (e.g., lithography and etching processes).

Referring to FIG. 26, in the present embodiment, since the distributed Bragg reflector structure 360′ is formed by the lift-off process, each refractive layer covers the next refractive layer. For example, the first refractive layer 162 covers the first insulating layer 105a, the second-type semiconductor layer 130, and the light emitting layer 120; the first second refractive layer 164 covers the first refractive layer 162; the second first refractive layer 162 covers the first second refractive layer 164; and so on. Additionally, since the distributed Bragg reflector structure 360′ is formed by the lift-off process, in a normal direction z perpendicular to the first surface 171 of the growth substrate 170, the refractive layer stacking density of an edge region 360′-1 of the distributed Bragg reflector structure 360′ is higher than the refractive layer stacking density of an internal region 360′-2 of the distributed Bragg reflector structure 360′.

The light emitting layer 120 has the sidewall 120a, the first surface 120b, and the second surface 120c. The second-type semiconductor layer 130 is disposed on the first surface 120b of the light emitting layer 120. The second surface 120c is opposite to the first surface 120b. The sidewall 120a is connected between the first surface 120b and the second surface 120c. Since each refractive layer of the distributed Bragg reflector structure 360′ is covered by the next refractive layer, a stacked structure formed by a plurality of first refractive layers 162 and a plurality of second refractive layers 164 exists above the first surface 120b of the light emitting layer 120, and furthermore, a stacked structure formed by a plurality of first refractive layers 162 and a plurality of second refractive layers 164 also exists in a side direction of the sidewall 120a of the light emitting layer 120. Thus, the distributed Bragg reflector structure 360′ not only reflects a light beam L3 emitted from the light emitting layer 120 in a positive direction (e.g., a direction parallel to the direction z), but also reflects a light beam L4 emitted from the light emitting layer 120 in a lateral direction (e.g., a direction oblique to the direction z), so as to improve the light extraction efficiency of the LED formed subsequently.

Moreover, as illustrated in FIG. 23R, the distributed Bragg reflector structure 360′ may be selectively filled into the groove 173 of the growth substrate 170. In this way, the sidewall 110a of the first-type semiconductor layer 110 is covered not only by the first insulating layer 105a but also by the insulated distributed Bragg reflector structure 360′, so as to further reduce the probability of the sidewall 110a of the first-type semiconductor layer 110 being electrically connected to improper components in the subsequent manufacturing processes of the LED and/or the eutectic bonding process to cause a short circuit problem.

Referring to FIG. 22, next, Step T170 is performed. That is, the second insulating layer is formed to cover the distributed Bragg reflector structure and the first insulating layer, wherein the first insulating layer and the second insulating layer have a plurality of through holes that expose the first metal layer and the second metal layer. In the present embodiment, Step T170 of FIG. 22 may correspond to FIG. 23S to FIG. 23V. A possible method of performing Step T170 is described hereinafter with reference to FIG. 23S to FIG. 23V as an example.

Referring to FIG. 23S, an insulating material layer 105b′ is formed on the first insulating layer 105a and the distributed Bragg reflector structure 360′. Referring to FIG. 23T, then, a patterned photoresist PR3 is formed on the insulating material layer 105b′. Referring to FIG. 23T and FIG. 23U, next, the insulating material layer 105b′ is patterned by dry etching or wet etching with the patterned photoresist PR3 as a mask to form the second insulating layer 105b. The second insulating layer 105b has a plurality of through holes 105ba and 105bb that expose the first metal layer 180 and the second metal layer 190 respectively. When the insulating material layer 105b′ is patterned to form the second insulating layer 105b, the first insulating layer 105a may also be patterned with the patterned photoresist PR3 as a mask, such that the first insulating layer 105a has a plurality of through holes 105aa and 105ab that expose the first metal layer 180 and the second metal layer 190 respectively. Referring to FIG. 23V, thereafter, the patterned photoresist PR3 is removed, by which Step T170 is completed.

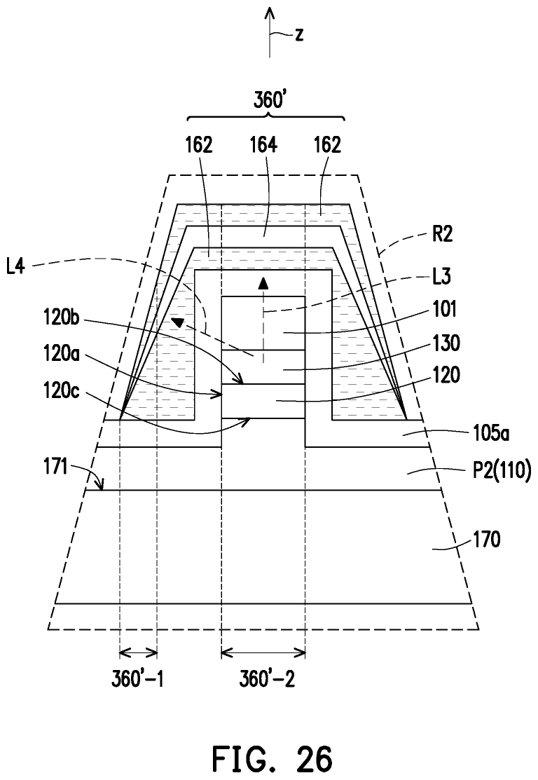

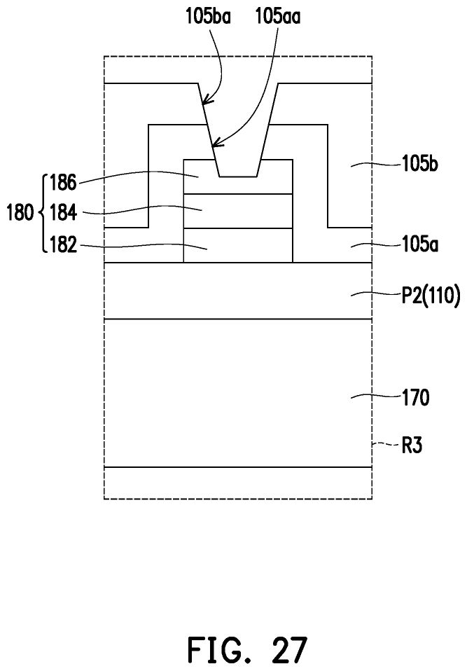

FIG. 27 is a schematic partially enlarged view of a part R3 of FIG. 23V. Referring to FIG. 27, in the present embodiment, the first metal layer 180 may include an ohmic contact layer 182, a reflective layer 184, and a connection layer 186 stacked on one another, wherein the ohmic contact layer 182 is electrically connected to the first-type semiconductor layer 110, and the reflective layer 184 is located between the ohmic contact layer 182 and the connection layer 186. Although not illustrated in the figure, the second metal layer 190 may also include an ohmic contact layer, a reflective layer, and a connection layer stacked on one another, and the ohmic contact layer of the second metal layer 190 is electrically connected to the second-type semiconductor layer 130. In the step of FIG. 23U, when the through holes 105aa and 105ba (and the through holes 105ab and 105bb) are formed in the first insulating layer 105a and the second insulating layer 105b by etching, since the reflective layer 184 is protected by the connection layer 186, the reflective layer 184 is less likely to be damaged. Thus, the first metal layer 180 (and the second metal layer 190) not only disperses current but also achieves a good reflection function, so as to improve the light extraction efficiency of the LED formed subsequently.

Referring to FIG. 22 and FIG. 23W, next, Step T180 is performed. That is, the first current conducting layer 140 and the second current conducting layer 150 are formed, wherein the first current conducting layer 140 and the second current conducting layer 150 are filled into the through holes 105aa, 105ba, 105ab, and 105ba of the first insulating layer 105a and the second insulating layer 105b to be electrically connected to the first-type semiconductor layer 110 and the second-type semiconductor layer 120 respectively. In detail, in the present embodiment, the first current conducting layer 140 may be electrically connected to the first-type semiconductor layer 110 via the first metal layer 180, and the second current conducting layer 150 may be electrically connected to the second-type semiconductor layer 130 via the second metal layer 190 and the conductive layer 101. Similar to the first metal layer 180 of FIG. 27, in the present embodiment, the first current conducting layer 140 and the second current conducting layer 150 may also include an ohmic contact layer, a reflective layer, a blocking stacked layer, and a connection layer (not shown) stacked on one another. The first current conducting layer 140 and the second current conducting layer 150 may achieve a good reflection function and may be called the first reflective layer and the second reflective layer. A thickness range of the ohmic contact layer may be adjusted and set to 0 nm to 50 nm considering the reflectance of the reflective layer.

Referring to FIG. 22, next, Step T190 is performed. That is, an insulating layer is formed on the first current conducting layer and the second current conducting layer, and the insulating layer has a plurality of through holes that expose the first current conducting layer and the second current conducting layer. In the present embodiment, Step T190 of FIG. 22 may correspond to FIG. 23X to FIG. 23Z. A possible method of performing Step T190 is described hereinafter with reference to FIG. 23X to FIG. 23Z as an example.

Referring to FIG. 23X, an insulating material layer 113′ is formed on the first current conducting layer 140, the second current conducting layer 150, and a part of the second insulating layer 105b. Referring to FIG. 23Y, then, a patterned photoresist PR4 is formed on the insulating material layer 113′ by a yellow lithography process. Referring to FIG. 23Z, next, the insulating material layer 113′ is patterned by dry etching or wet etching with the patterned photoresist PR4 as a mask to form the insulating layer 113. The insulating layer 113 has a plurality of through holes 113a and 113b that expose the first current conducting layer 140 and the second current conducting layer 150. In the present embodiment, the insulating layer 113 may be filled into the groove 173 of the growth substrate 170 and cover the sidewall 110a of the first-type semiconductor layer 110. Thereby, Step T190 is completed.

Referring to FIG. 22, thereafter, Step T200 is performed. That is, the first bonding layer and the second bonding layer are formed and filled into the through holes of the insulating layer to be electrically connected to the first current conducting layer and the second current conducting layer respectively. In the present embodiment, Step T200 of FIG. 22 may correspond to FIG. 24A to FIG. 24B. A possible method of performing Step T200 is described hereinafter with reference to FIG. 24A to FIG. 24B as an example.

Referring to FIG. 24A, in the present embodiment, a conductive material may be filled into the through holes 113a and 113b of the insulating layer 113 by vapor deposition or sputtering with the patterned photoresist PR4 as a mask to form the first bonding layer 108 and the second bonding layer 109. The first bonding layer 108 and the second bonding layer 109 are electrically connected to the first current conducting layer 140 and the second current conducting layer 150 respectively. Referring to FIG. 24B, next, the patterned photoresist PR4 is removed, by which Step T200 is completed. After the patterned photoresist PR4 is removed, the location of the patterned photoresist PR4 allows the second bonding layer 109 to have a plurality of second through holes 109a and allows the first bonding layer 108 to have a plurality of through holes 108a.

Referring to FIG. 22 and FIG. 24C, then, Step T210 is performed. That is, the growth substrate 170 is divided along the groove 173 of the growth substrate 170 to form a plurality of LEDs 700 independent of one another. For example, in the present embodiment, the growth substrate 170 and the first insulating layer 105a, the distributed Bragg reflector structure 360′, the second insulating layer 105b, and the insulating layer 113 in the groove 173 of the growth substrate 170 may be cut along the groove 173 of the growth substrate 170, so as to form a plurality of LEDs 700 independent of one another. For example, in the present embodiment, the growth substrate 170 may be cut and divided by laser or a cutter wheel, but the invention is not limited thereto. In other embodiments, the growth substrate 170 may be divided by other suitable methods to form a plurality of LEDs 700 independent of one another. In the present embodiment, the structure of each LED 700 in the top view is similar to that of the LED 600 of FIG. 17, and thus the repetitive descriptions are omitted.

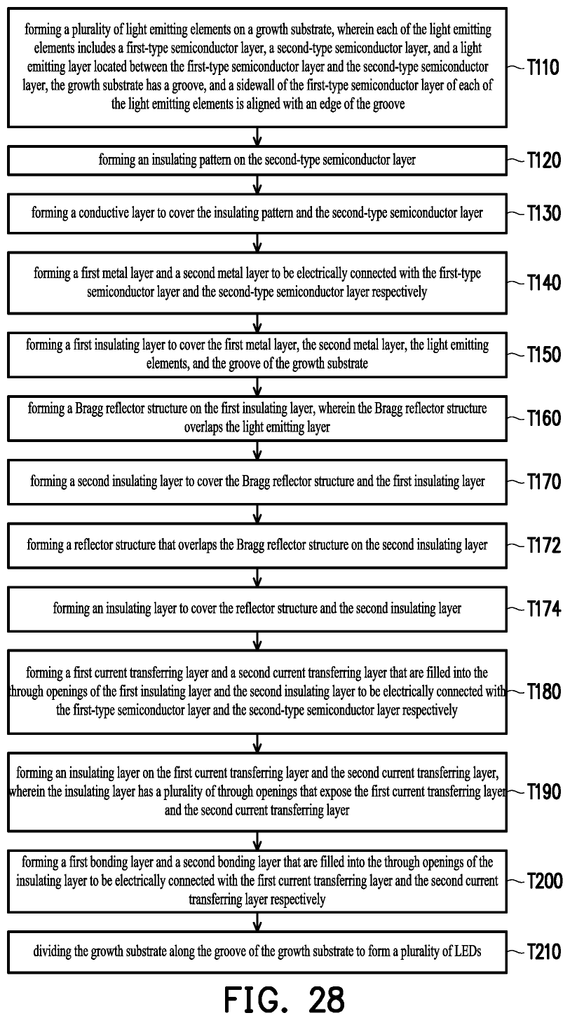

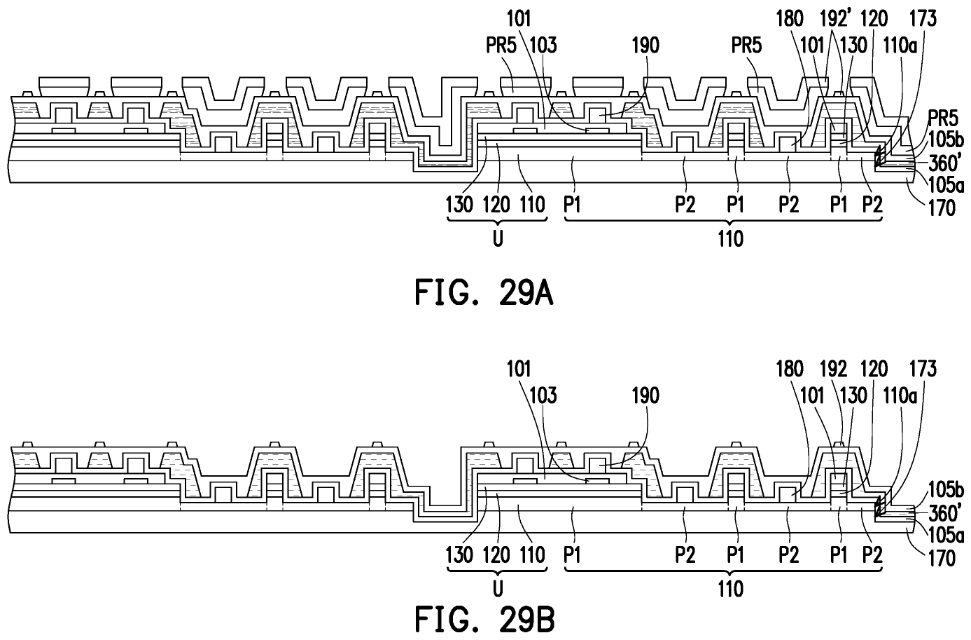

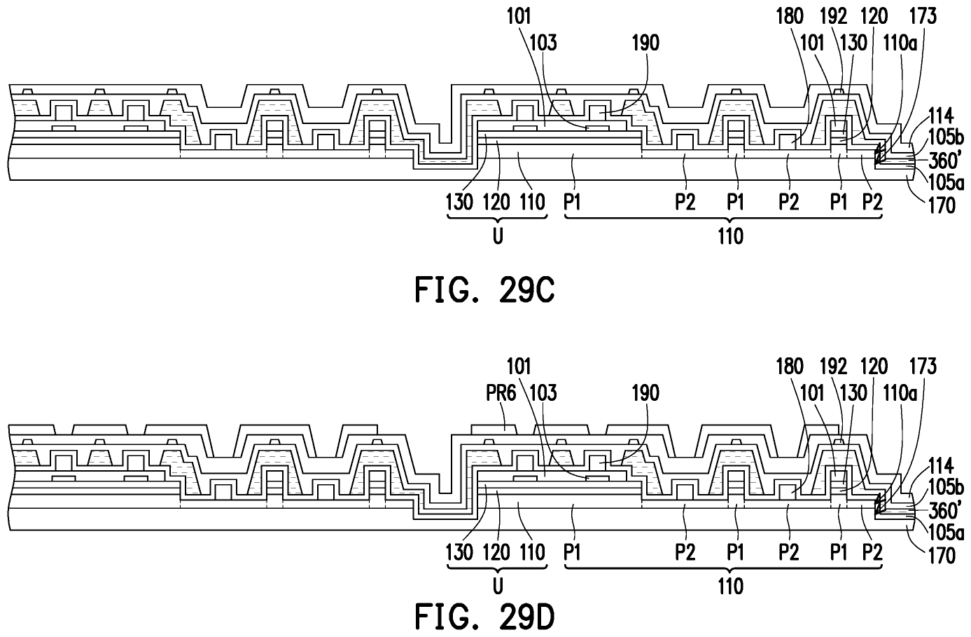

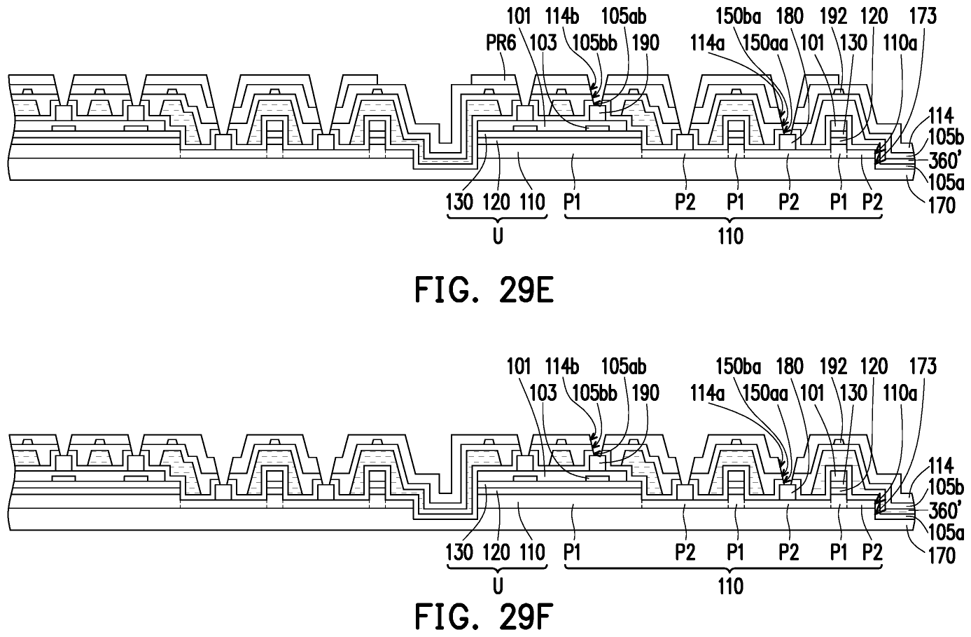

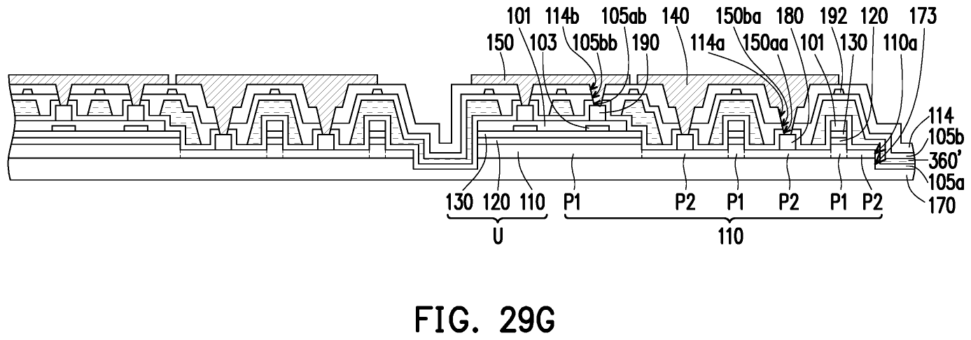

FIG. 28 is a flowchart of manufacturing an LED according to another embodiment of the invention. The manufacturing method of the LED of FIG. 28 is similar to the manufacturing method of the LED of FIG. 22, and a major difference lies in that: the manufacturing method of the LED of FIG. 28 further includes Step T172 and Step T174. FIG. 29A to FIG. 29G are schematic cross-sectional views showing a part of a manufacturing method of an LED according to another embodiment of the invention. FIG. 29A to FIG. 29G correspond to Steps T172, T174, and T180 of FIG. 28. In the present embodiment, Step T110 to Step T170 before Step T172 of FIG. 28 may be understood from FIG. 23A to FIG. 23S and the descriptions thereof, and Step T190 to Step T210 after Step T180 may be understood from FIG. 23X to FIG. 24C and the descriptions thereof. Those skilled in the art can complete the LED manufactured by the manufacturing method of FIG. 28 based on FIG. 28 and FIG. 29A to FIG. 29G and the following descriptions, and thus the same or similar steps are omitted.

Referring to FIG. 28 and FIG. 29A to FIG. 29B, after Step T170 (i.e., forming the second insulating layer 105b) is completed, Step T172 may be performed. That is, a reflector structure that overlaps with the distributed Bragg reflector structure is formed on the second insulating layer. Referring to FIG. 28, for example, in the present embodiment, a patterned photoresist PR5 may be formed on the second insulating layer 105b, and the patterned photoresist PR5 covers the second insulating layer 105b on the first metal layer 180 and the second metal layer 190 and does not cover the second insulating layer 105b on the distributed Bragg reflector structure 360′; and then, a reflective material layer 192′ is formed on the patterned photoresist PR5 and the second insulating layer 105b not covered by the patterned photoresist PR5. Referring to FIG. 29A and FIG. 29B, next, the patterned photoresist PR5 and a part of the reflective material layer 192′ thereon are removed to form a reflector structure 192. In the present embodiment, the reflector structure 192 includes a reflective layer disposed on the second insulating layer 105b and an oxide layer (or referred to as an adhesive layer) disposed on the reflective layer. A material of the reflective layer of the reflector structure includes Al, Alloy Al, Alloy Al/Cu, Ti, Ni, Pt, or combinations thereof, for example. A material of the oxide layer of the reflector structure includes Ti, Ni, Cr, Au, Pt, or combinations thereof, or an insulating material, such as SiO₂ or TiO₂, for example. The reflector structure 192 reflects light by using the material properties of the reflective layer. The reflector structure 192 may reflect the light beam that passes through the distributed Bragg reflector structure 360′, so as to further improve the light extraction efficiency of the LED formed subsequently. It is known from FIG. 29B that an area of the reflector structure 192 projected to the growth substrate 170 is smaller than or equal to an area of the distributed Bragg reflector structure 360′ projected to the growth substrate 170. The reflector structure 192 is disposed on the distributed Bragg reflector structure 360′ and the second insulating layer 105b, wherein the second insulating layer 105b covers the first-type semiconductor layer 110 of the second-type semiconductor layer 130 of the light emitting element and the sidewalls of the first-type semiconductor layer 110, the second-type semiconductor layer 130, and the light emitting layer 120; the distributed Bragg reflector structure 360′ covers the first-type semiconductor layer 110 and the second-type semiconductor layer 130 of the light emitting element and the sidewalls of the first-type semiconductor layer 110, the second-type semiconductor layer 130, and the light emitting layer 120; and the reflector structure 192 covers the first-type semiconductor layer 110 and the second-type semiconductor layer 130 of the light emitting element and the sidewalls (not shown) of the first-type semiconductor layer 110, the second-type semiconductor layer 130, and the light emitting layer 120.

Referring to FIG. 28 and FIG. 29C, thereafter, Step T172 is performed. That is, an insulating layer 114 is formed to cover the reflector structure 192 and the second insulating layer 105b. The insulating layer 114 electrically isolates the reflector structure 192 from other conductive components (e.g., the first current conducting layer 140 and the second current conducting layer 150 formed subsequently) of the LED. In the present embodiment, a main function of the reflector structure 192 is to reflect. Although the reflector structure 192 may include a conductive material, the reflector structure 192 may not serve as a conductive path for conducting an electrical signal that drives the LED.

Referring to FIG. 28 and FIG. 29D to FIG. 29G, next, Step T180 is performed. That is, the first current conducting layer 140 and the second current conducting layer 150 are formed, such that the first current conducting layer 140 and the second current conducting layer 150 are electrically connected to the first-type semiconductor layer 110 and the second-type semiconductor layer 130 respectively. Referring to FIG. 29D, in the present embodiment, a patterned photoresist PR6 may be formed on the insulating layer 114 to at least expose a part of the insulating layer 114 corresponding to the above of the first metal layer 180 and the second metal layer 190. Referring to FIG. 29E, then, the insulating layer 114, the second insulating layer 105b, and the first insulating layer 105a are patterned with the patterned photoresist PR6 as a mask to form a plurality of through holes 114a, 114b, 105ba, 105bb, 105aa, and 105bb that penetrate through the insulating layer 114, the second insulating layer 105b, and the first insulating layer 105a and expose the first metal layer 180 and the second metal layer 190. Referring to FIG. 29F and FIG. 29G, next, the patterned photoresist PR6 is removed and the first current conducting layer 140 and the second current conducting layer 150 are formed on the insulating layer 114. The first current conducting layer 140 and the second current conducting layer 150 are filled into the through holes 114a, 114b, 105ba, 105bb, 105aa, and 105bb to be electrically connected to the first-type semiconductor layer 110 and the second-type semiconductor layer 120 via the first metal layer 180 and the second metal layer 190 respectively.

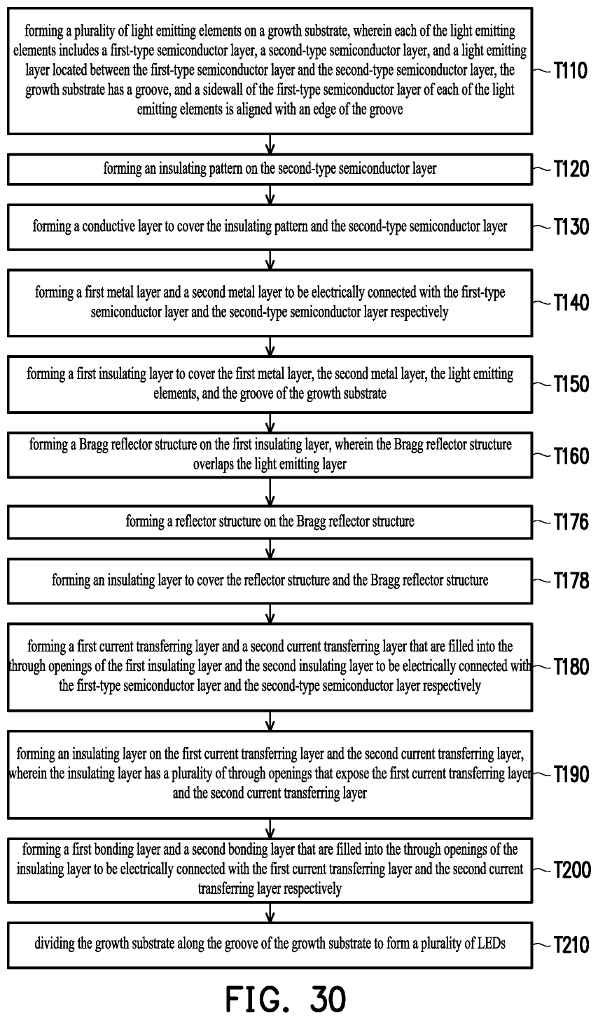

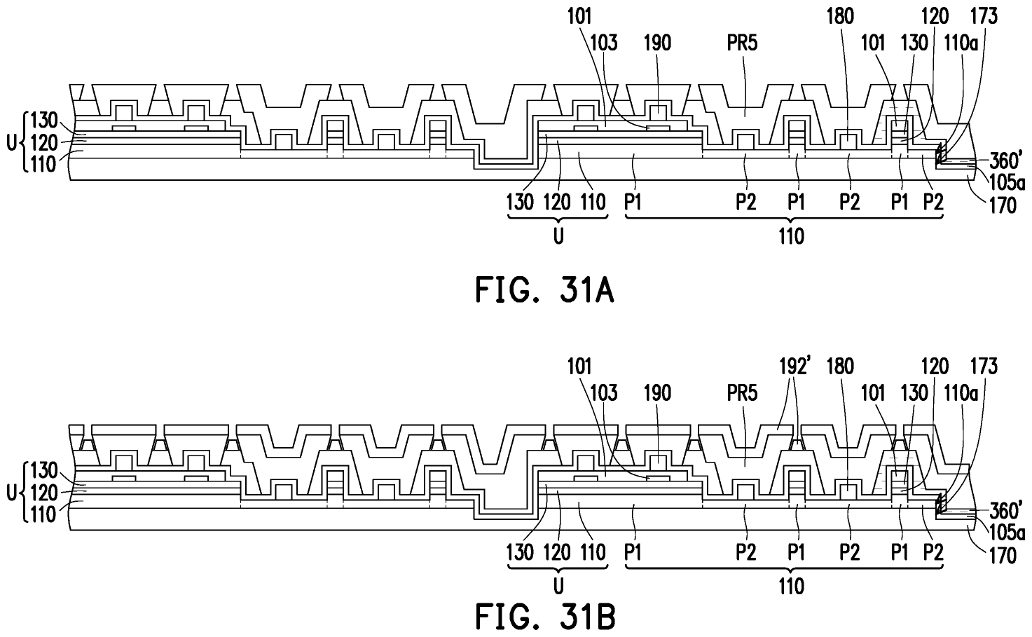

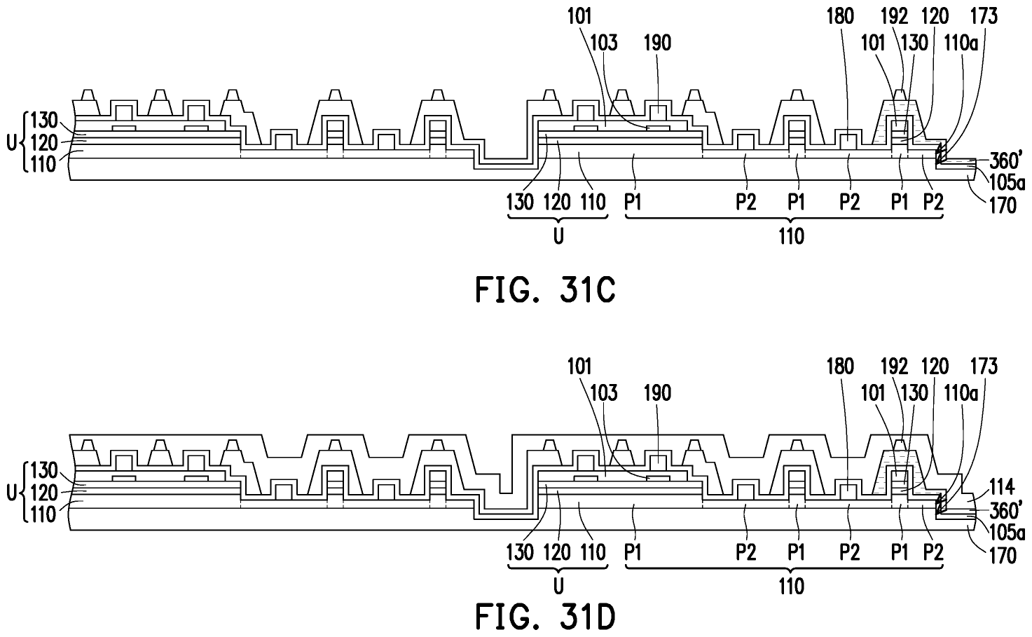

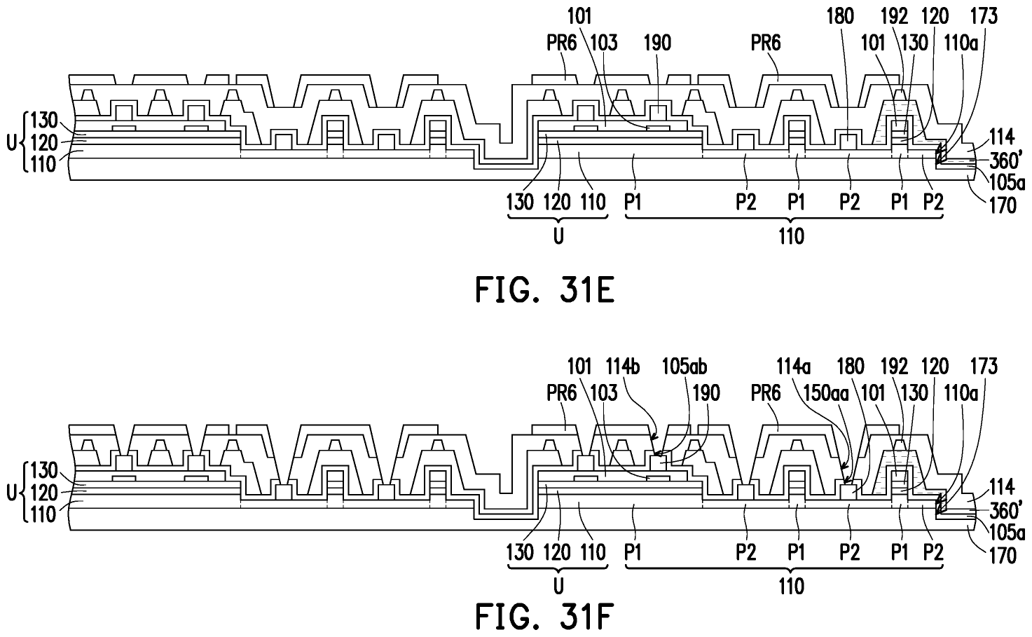

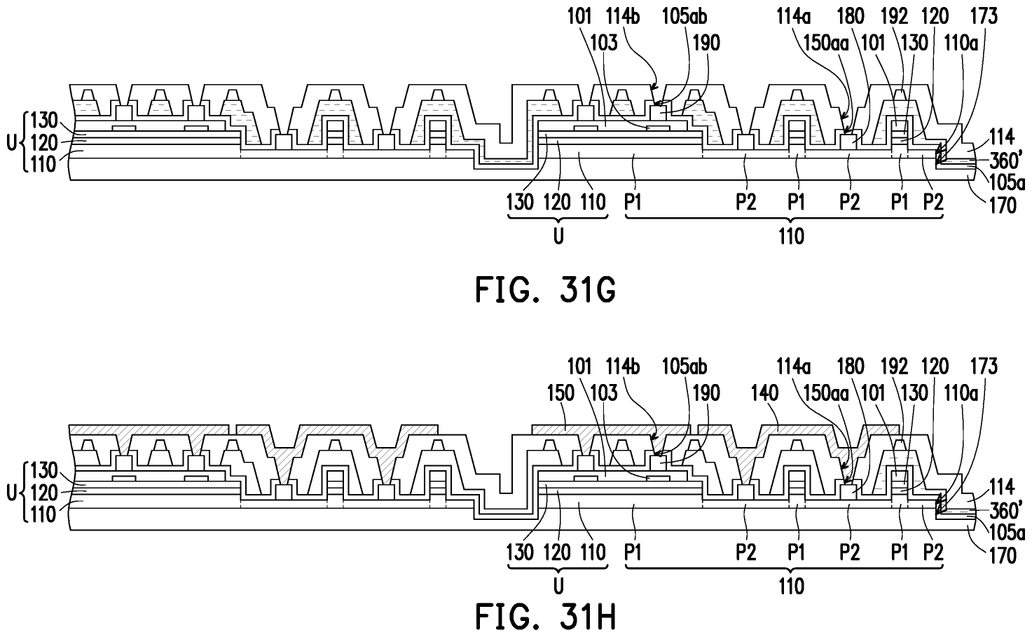

FIG. 30 is a flowchart of manufacturing an LED according to yet another embodiment of the invention. The manufacturing method of the LED of FIG. 30 is similar to the manufacturing method of the LED of FIG. 22, and a major difference lies in that: the manufacturing method of the LED of FIG. 30 does not include Step T170 and further includes Step T176 and Step T178. FIG. 31A to FIG. 31H are schematic cross-sectional views showing a part of a manufacturing method of an LED according to yet another embodiment of the invention. FIG. 31A to FIG. 31H correspond to Steps T176, T178, and T180 of FIG. 30. In the present embodiment, Step T110 to Step T160 before Step T176 of FIG. 30 may be understood from FIG. 23A to FIG. 23R and the descriptions thereof, and Step T190 to Step T210 after Step T180 may be understood from FIG. 23X to FIG. 24C and the descriptions thereof. Those skilled in the art can complete the LED manufactured by the manufacturing method of FIG. 30 based on FIG. 30 and FIG. 31A to FIG. 31H and the following descriptions, and thus the same or similar steps are omitted.

Referring to FIG. 30 and FIG. 31A to FIG. 31C, after Step T160 (i.e., forming the distributed Bragg reflector structure 360′), Step T176 may be performed. That is, the reflector structure 192 is formed on the distributed Bragg reflector structure 360′. Referring to FIG. 31A, for example, a patterned photoresist PR5 may be formed on the first insulating layer 105a. In the present embodiment, the patterned photoresist PR5 may cover a part of the first insulating layer 105a that is not covered by the distributed Bragg reflector structure 360′ and exposes the distributed Bragg reflector structure 360′. Referring to FIG. 31B, then, the reflective material layer 192′ may be formed by vapor deposition, sputtering, or other suitable methods, and the reflective material layer 192′ covers the patterned photoresist PR5 and the distributed Bragg reflector structure 360′. Referring to FIG. 31C, next, the patterned photoresist PR5 is removed. When the patterned photoresist PR5 is removed, a part of the reflective material layer 192′ on the patterned photoresist PR5 is removed as well while a part of the reflective material layer 192′ on the distributed Bragg reflector structure 360′ is retained, so as to form the reflector structure 192. The reflector structure 192 may be disposed on the distributed Bragg reflector structure 360′ directly to be in contact with the distributed Bragg reflector structure 360′.

Referring to FIG. 30 and FIG. 31D, thereafter, Step T178 may be performed. That is, the insulating layer 114 is formed to cover the reflector structure 192 and the distributed Bragg reflector structure 360′. In the present embodiment, the insulating layer 114 further covers a part of the first insulating layer 105a that is not covered by the distributed Bragg reflector structure 360′. Referring to FIG. 30 and FIG. 31E to FIG. 31H, then, Step T180 may be performed. That is, the first current conducting layer 140 and the second current conducting layer 150 are formed, and the first current conducting layer 140 and the second current conducting layer 150 are electrically connected to the first-type semiconductor layer 110 and the second-type semiconductor layer 130 respectively. Referring to FIG. 31E, for example, a patterned photoresist PR6 may be formed on the insulating layer 114. Referring to FIG. 31F, then, the insulating layer 114 and the first insulating layer 105a are patterned with the patterned photoresist PR6 as a mask to form a plurality of through holes 114a, 114b, 105aa, and 105ab that penetrate through the insulating layer 114 and the first insulating layer 105a and expose the first metal layer 180 and the second metal layer 190. Referring to FIG. 31G and FIG. 31H, next, the patterned photoresist PR6 is removed, and the first current conducting layer 140 and the second current conducting layer 150 are formed on the insulating layer 114 and filled into the through holes 114a, 114b, 105aa, and 105ab to be electrically connected to the first-type semiconductor layer 110 and the second-type semiconductor layer 120 respectively.

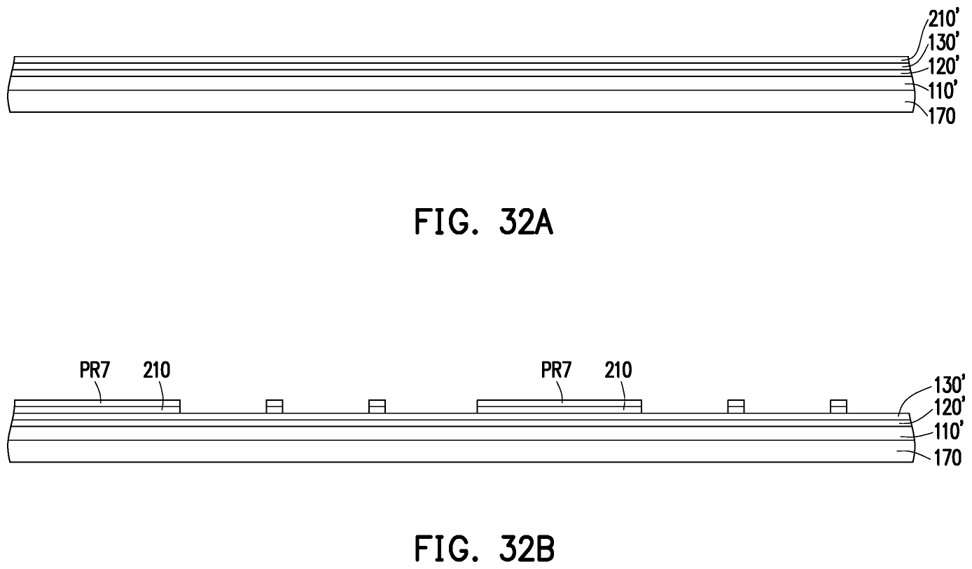

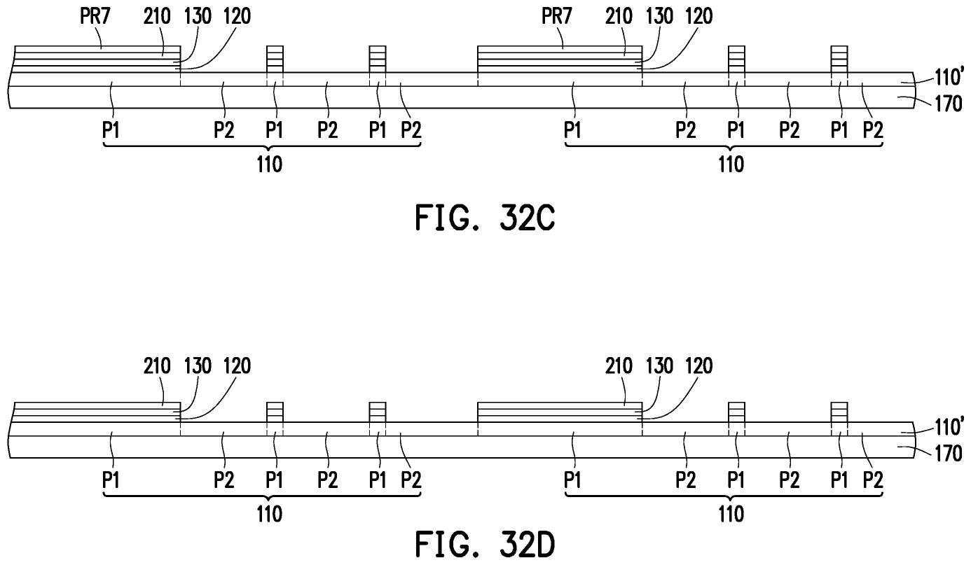

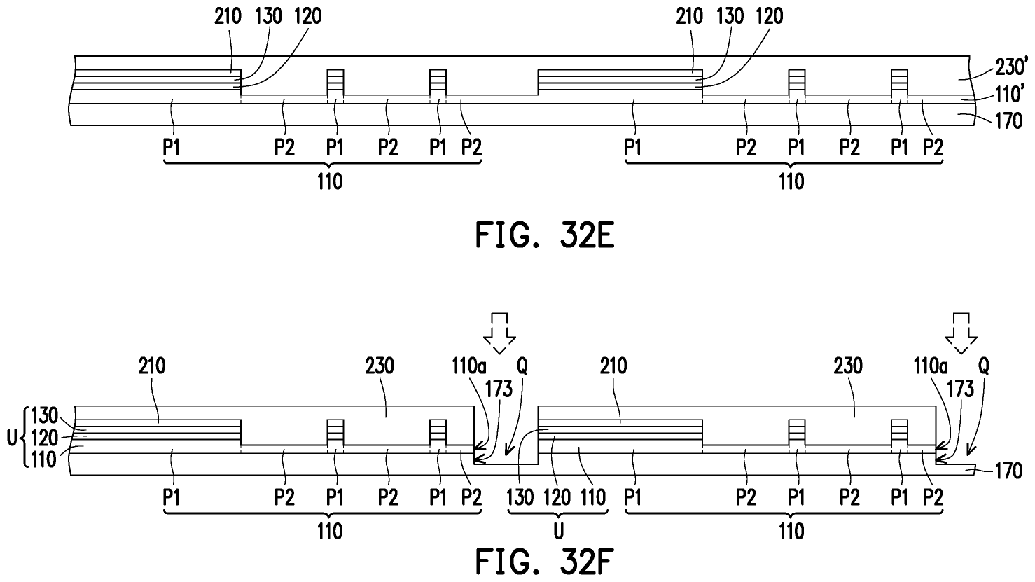

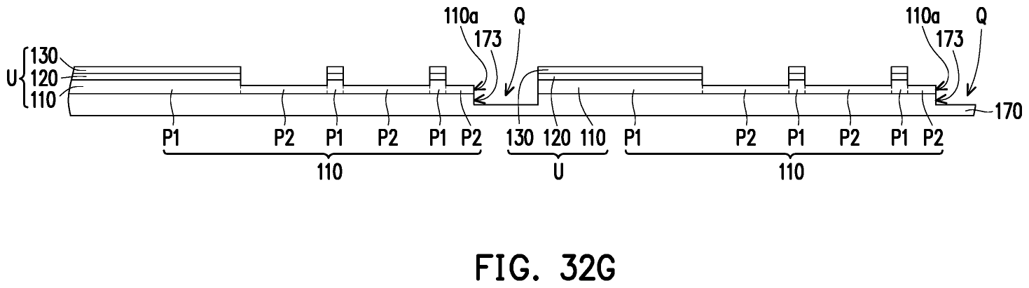

FIG. 32A to FIG. 32G are schematic cross-sectional views showing a part of a manufacturing method of an LED according to yet another embodiment of the invention. FIG. 32A to FIG. 32G illustrate another possible method of completing Step T110 of FIG. 22, FIG. 28, or FIG. 23. The method of completing Step T110 illustrated in FIG. 32A to FIG. 32G is similar to the method of completing Step T110 illustrated in FIG. 23A to FIG. 23G, and a major difference lies in that: the process of completing Step T110 as illustrated in FIG. 23A to FIG. 23G is to form one sacrificial layer, and the process of completing Step T110 as illustrated in FIG. 32A to FIG. 32G is to form two sacrificial layers. An example is described hereinafter with reference to FIG. 32A to FIG. 32G.

Referring to FIG. 32A, the first-type semiconductor material layer 110′ is formed on the growth substrate 170. Then, the light emitting material layer 120′ is formed on the first-type semiconductor material layer 110′. Next, the second-type semiconductor material layer 130′ is formed on the light emitting material layer 120′. Thereafter, a first sacrificial material layer 210′ is formed on the second-type semiconductor material layer 130′. Referring to FIG. 32A and FIG. 32B, then, a patterned photoresist PR7 is formed on the first sacrificial material layer 210′. Then, the first sacrificial material layer 210′ is etched with the patterned photoresist PR7 as a mask to form the first sacrificial pattern layer 210, wherein the first sacrificial pattern layer 210 exposes a part of the second-type semiconductor material layer 130′.

Referring to FIG. 32C, next, the second-type semiconductor material layer 130′, the light emitting material layer 120′, and the first-type semiconductor material layer 110′ are etched by continuing to use the patterned photoresist PR7 as a mask, so as to form the second-type semiconductor layer 130, the light emitting layer 120, and the first-type semiconductor material layer 110′ that has the first portion P1 and the second portion P2. Referring to FIG. 32D, then, the patterned photoresist PR7 is removed and the first sacrificial pattern layer 210 is retained. The first sacrificial pattern layer 210 covers the second-type semiconductor layer 130 but does not cover the second portion P2 of the first-type semiconductor material layer 110′. Referring to FIG. 32E, thereafter, a second sacrificial material layer 230′ is formed to comprehensively cover the first sacrificial pattern layer 210 and the second portion P2 of the first-type semiconductor material layer 110′.

Referring to FIG. 32E and FIG. 32F, then, a scribing process is performed on the second sacrificial material layer 230′, the first-type semiconductor material layer 110′, and the growth substrate 170 to form the scribing mark Q. The scribing mark Q penetrates through the second sacrificial material layer 230′ and the first-type semiconductor material layer 110′ to form a plurality of light emitting elements U and a plurality of second sacrificial pattern layers 230 thereon. Each of the light emitting elements U is a stacked structure of the first-type semiconductor layer 110, the light emitting layer 120, and the second-type semiconductor layer 130. It should be noted that the scribing mark Q further extends to the growth substrate 170 to form the groove 173 that does not penetrate through the growth substrate 170 on the growth substrate 170. That is, the growth substrate 170 is thinner at the groove 173 and thicker at other parts. Since the growth substrate 170 and the first-type semiconductor material layer 110′ are cut in the same process, the sidewall 110a of the first-type semiconductor layer 110 of each light emitting element U is aligned with the edge of the groove 173.

Referring to FIG. 32G, then, the first sacrificial pattern layer 210 and the second sacrificial pattern layer 230 are removed, by which Step T110 is completed. It should be noted that, in the process of forming the first-type semiconductor layers 110 of the light emitting elements U (i.e., in the foregoing scribing process), the first sacrificial pattern layer 210 and the second sacrificial material layer 230′ cover the light emitting elements U. Thus, the light emitting element U is not easily damaged (e.g., particle contamination), which helps to improve the light emission efficiency of the LED formed subsequently.

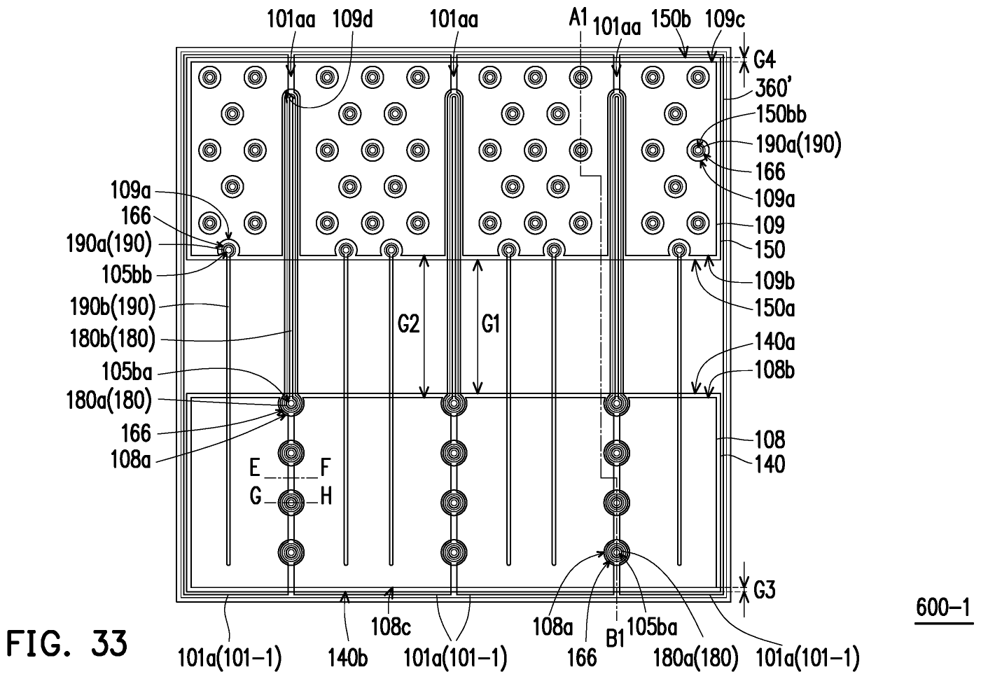

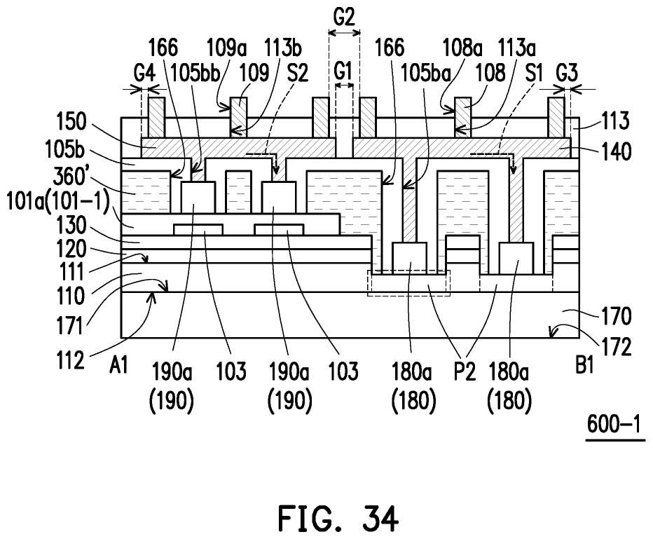

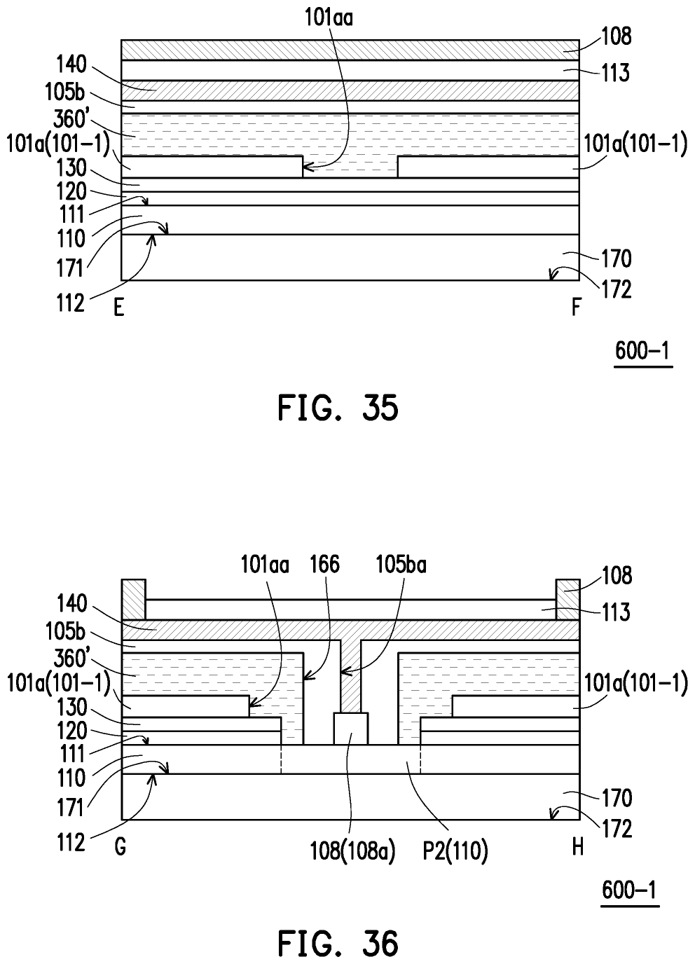

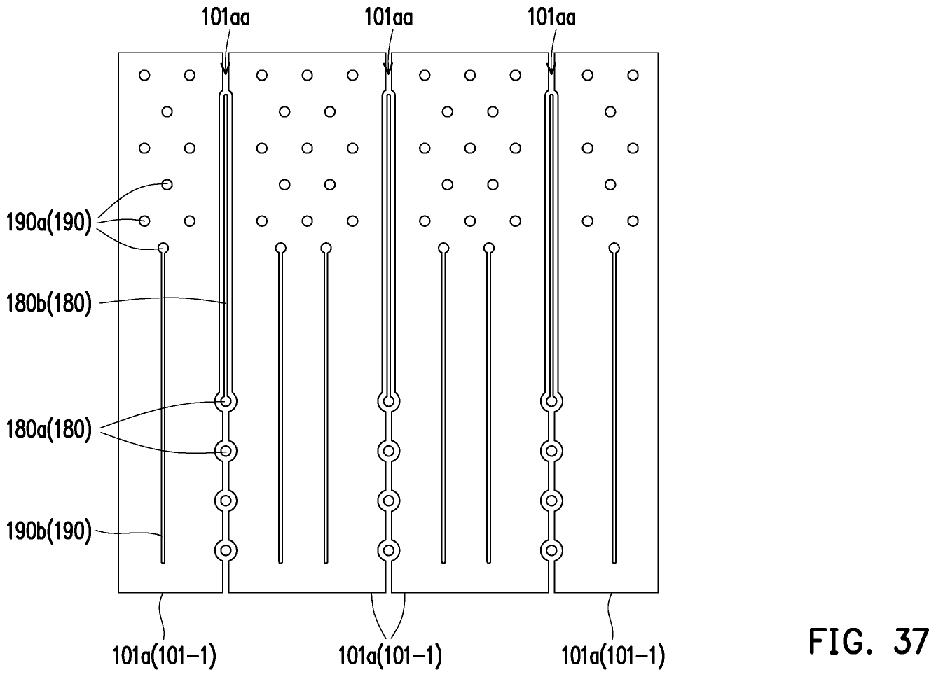

FIG. 33 is a schematic top view of an LED according to an embodiment of the invention. FIG. 34 is a schematic cross-sectional view along a line A1-B1 of FIG. 33. FIG. 35 is a schematic cross-sectional view along a line E-F of FIG. 33. FIG. 36 is a schematic cross-sectional view along a line G-H of FIG. 33. FIG. 37 is a schematic top view of a conductive layer, a first metal layer, and a second metal layer of the LED of FIG. 33. Referring to FIG. 33 to FIG. 36, the LED 600-1 as illustrated is applicable to flip chip packaging. The LED 600-1 in the present embodiment is similar to the foregoing LED 600, and a major difference lies in that: a conductive layer 101-1 of the LED 600-1 and the conductive layer 101 of the LED 600 have different profiles. The following mainly describes this difference. For the same or similar parts, please refer to the foregoing descriptions.

Referring to FIG. 33 to FIG. 36, the conductive layer 101-1 is located on the second-type semiconductor layer 130 and electrically connected to the second-type semiconductor layer 130. The second current conducting layer 150 is electrically connected to the second-type semiconductor layer 130 via the conductive layer 101-1. Referring to FIG. 33 and FIG. 37, unlike the LED 600, the conductive layer 101-1 in the present embodiment includes a plurality of conductive blocks 101a, and the first metal layer 180 is located in a region where the conductive blocks 101a are separated. More specifically, in the present embodiment, the conductive blocks 101a may be separated from one another. That is, the conductive layer 101-1 may be divided into a plurality of conductive blocks 101a, and the conductive blocks 101a are not directly connected to one another.

Referring to FIG. 33 to FIG. 37, for example, in the present embodiment, the second portion P2 of the first-type semiconductor layer 110 and the first metal layer 180 thereon may be disposed in a gap 101aa between adjacent two conductive blocks 101a. More specifically, in the present embodiment, the finger portion 180b and the welding portion 180a of the first metal layer 180 are located in the gap 101aa between adjacent two conductive blocks 101a. In the present embodiment, a plurality of the gaps 101aa may be selectively arranged into a plurality of straight lines to divide the conductive layer 101-1 into a plurality of conductive blocks 101-1 that are approximately rectangular. However, the invention is not limited thereto. In other embodiments, the gaps 101aa may also be arranged in other suitable ways, and the conductive blocks 101-1 of the conductive layer 101-1 may have other suitable shapes.

Referring to FIG. 33 and FIG. 37, in the present embodiment, the same conductive block 101a of the conductive layer 101-1 may overlap with and be electrically connected to a plurality of welding portions 190a and at least one finger portion 190b of the second metal layer 190. The welding portions 190a in the second metal layer 190 are approximately concentrated and distributed on one side while the welding portions 180a in the first metal layer 180 are approximately concentrated on the other side. The finger portion 190b in the second metal layer 190 extends from one of the welding portions 190a toward the side where the welding portions 180a are relatively concentrated, and the finger portion 180b in the first metal layer 180 extends from one of the welding portions 180a toward the side where the welding portions 190a are relatively concentrated. By using the conductive blocks 101a of the conductive layer 101-1 that are separated from one another, the current is more uniformly dispersed in the LED 600-1, so as to improve the light emission efficiency of the LED 600-1.

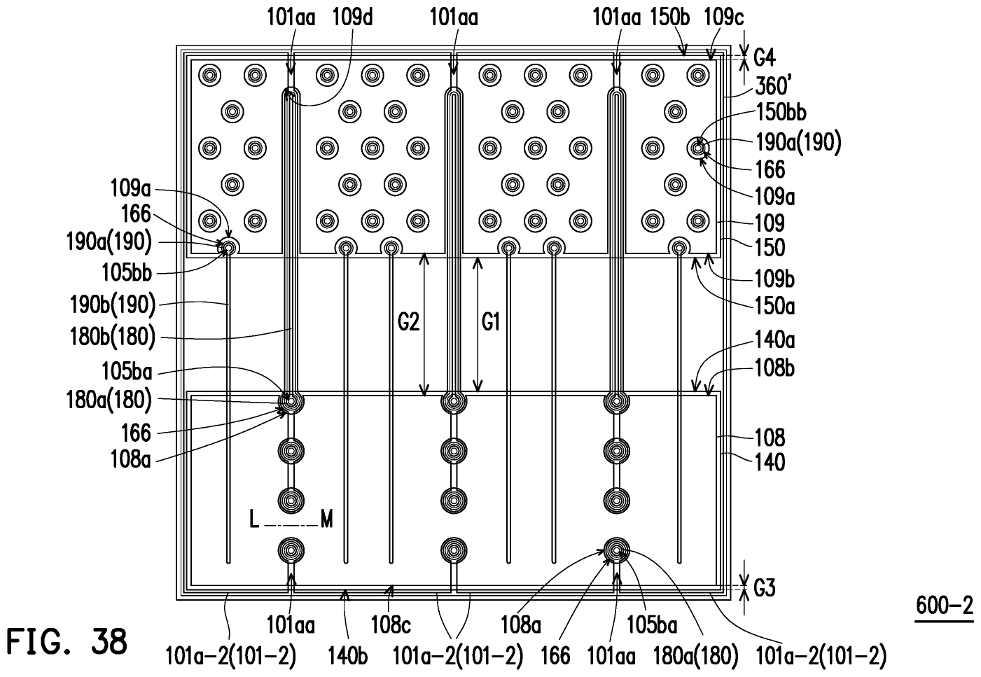

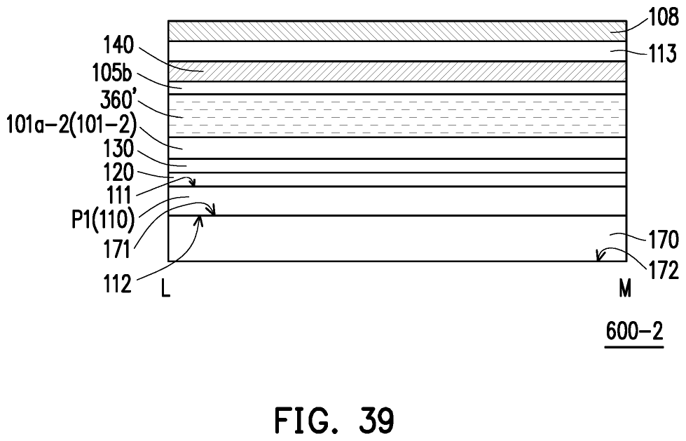

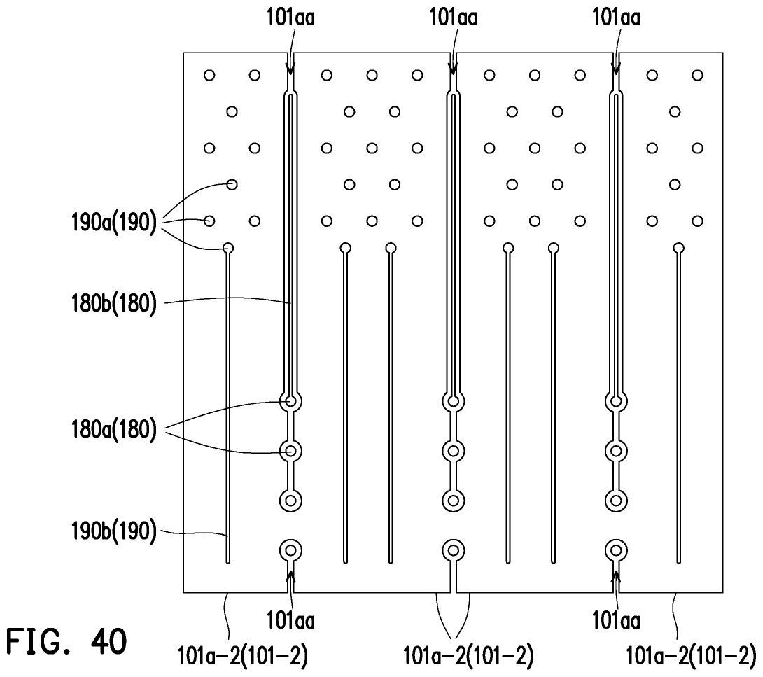

FIG. 38 is a schematic top view of an LED according to an embodiment of the invention. FIG. 39 is a schematic cross-sectional view along a line L-M of FIG. 38. FIG. 40 is a schematic top view of a conductive layer, a first metal layer, and a second metal layer of the LED of FIG. 38.

Referring to FIG. 38 and FIG. 39, the LED 600-2 as illustrated is applicable to flip chip packaging. The LED 600-2 in the present embodiment is similar to the foregoing LED 600-1, and a major difference lies in that: a conductive layer 101-2 of the LED 600-2 is different from the conductive layer 101-1 of the LED 600-1. The following mainly describes this difference. For the same or similar parts, please refer to the foregoing descriptions.

Referring to FIG. 38 to FIG. 40, the conductive layer 101-2 is located on the second-type semiconductor layer 130 and electrically connected to the second-type semiconductor layer 130. The second current conducting layer 150 is electrically connected to the second-type semiconductor layer 130 via the conductive layer 101-2. Referring to FIG. 38 and FIG. 40, the conductive layer 101-2 includes a plurality of conductive blocks 101a-2, but unlike the LED 600-1, the conductive blocks 101a-2 of the conductive layer 101-2 of the LED 600-2 are not completely separated and are partially connected. For example, adjacent two conductive blocks 101a-2 are separated at where they are adjacent to the finger portion 180b of the first metal layer 180, and are connected to each other between adjacent two welding portions 180a of the first metal layer 180 (e.g., where the line L-M of FIG. 38 is located).

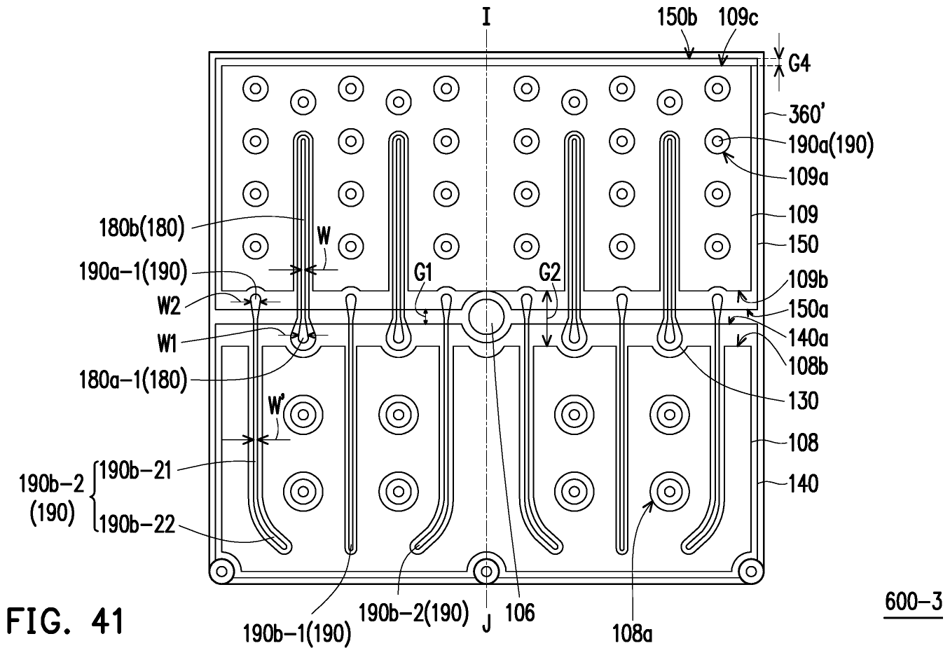

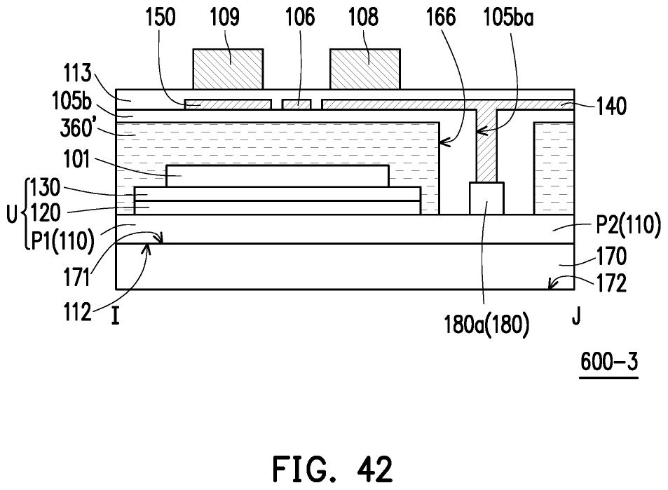

FIG. 41 is a schematic top view of an LED according to an embodiment of the invention. FIG. 42 is a schematic cross-sectional view along a line I-J of FIG. 41. Referring to FIG. 41 and FIG. 42, the LED 600-3 as illustrated is applicable to flip chip packaging. The LED 600-3 in the present embodiment is similar to the foregoing LED 600, and a major difference lies in that: the LED 600-3 further includes a bump 106. The following mainly describes this difference. For the same or similar parts, please refer to the foregoing descriptions.

Referring to FIG. 41 and FIG. 42, in addition to the components of the LED 600 of FIG. 18, the LED 600-3 in the present embodiment further includes the bump 106. The bump 106 is disposed on the second insulating layer 105b. In the present embodiment, the second-type semiconductor layer 130 is farther away from the growth substrate 170 than the first-type semiconductor layer 110, and the bump 106 may be disposed on a part of the second insulating layer 105b above the second-type semiconductor layer 130. More specifically, the distributed Bragg reflector structure 360′ is disposed between the second-type semiconductor layer 130 and the second insulating layer 105b, and the bump 106 may be disposed on the stacked structure of the distributed Bragg reflector structure 360′ and the second insulating layer 105b. For example, in the present embodiment, the bump 106 may be disposed directly on the second insulating layer 105b, and the insulating layer 113 may cover the bump 106. The bump 106 may belong to the same layer as the first current conducting layer 140 and/or the second current conducting layer 150. However, the invention is not limited thereto. In other embodiments, the bump 106 may be directly disposed at other suitable positions and/or belong to other suitable layers, which will be described hereinafter with reference to other figures as examples.

Referring to FIG. 41 and FIG. 42, in the present embodiment, the bump 106 and the first current conducting layer 140, the second current conducting layer 150, the first bonding layer 108, and the second bonding layer 109 are displaced. That is, areas of these components do not overlap with one another. The bump 106 is located within the area of the gap between the first current conducting layer 140 and the second current conducting layer 150, and located within the area of the gap between the first bonding layer 108 and the second bonding layer 109.

Generally, before the LED 600-3 is bonded to an external circuit board by eutectic bonding, the LED 600-3 is disposed on a carrier film (e.g., blue film, not shown) first. When the LED 600-3 is disposed on the carrier film, the first bonding layer 108 and the second bonding layer 109 of the LED 600-3 are located below and the light emitting element U of the LED 600-3 is located above, and the bump 106 is closer to the carrier film than the light emitting element U. When the LED 600-3 on the carrier film is to be bonded to the external circuit board by eutectic bonding, the LED 600-3 needs to be extracted from the carrier film. At this time, usually an extraction mechanism (e.g., a needle, not shown) disposed under the carrier film is placed against the carrier film and the LED 600-3 thereon. In the case where the bump 106 is present, the needle may be against the bump 106 to help the extraction mechanism to extract the LED 600-3. Considering the stability of the extraction mechanism placed against the LED 600-3, the bump 106 may overlap with a mass center line and/or a geometric center line of the LED 600-3, but the invention is not limited thereto. Since the bump 106 has high ductility (higher than the ductility of the insulating layer 113 and/or the second insulating layer 105b, for example), when the extraction mechanism is against the bump 106, the bump 106 does not easily break and is able to protect the components between the bump 106 and the growth substrate 170 (e.g., the second insulating layer 105b, the distributed Bragg reflector structure 360′, the conductive layer 101, the second-type semiconductor layer 130, the light emitting layer 120, the first-type semiconductor layer 110, and so on). Thus, the LED 600-3 is not easily damaged in the extraction process and can maintain a better yield. In addition, since the bump 106 is electrically isolated from other components (e.g., the first current conducting layer 140, the second current conducting layer 150, the first bonding layer 108, and the second bonding layer 109) of the LED 600-3, even if the bump 106 is damaged by the extraction mechanism, the electrical properties of the LED 600-3 are not affected.

Referring to FIG. 41 and FIG. 42, in the present embodiment, a projection area of the second current conducting layer 150 on the growth substrate 170 may be larger than or equal to a projection area of the second bonding layer 109 on the growth substrate 170; and a projection area of the first current conducting layer 140 on the growth substrate 170 may be larger than or equal to a projection area of the first bonding layer 108 on the growth substrate 170, but the invention is not limited thereto. In the present embodiment, a projection of the bump 106 on the growth substrate 170 may be located between a projection of the first current conducting layer 140 on the growth substrate 170 and a projection of the second current conducting layer 150 on the growth substrate 170, and does not overlap with the first current conducting layer 140 and the second current conducting layer 150.

Referring to FIG. 41, another difference between the LED 600-3 and the foregoing LED 600 is that: the first metal layer 180 includes at least one welding portion 180a-1, which is connected to one of the finger portions 180b, and the shape of the welding portion 180a of the LED 600-3 is different from the shape of the welding portion 180a-1 of the LED 600. In detail, in the present embodiment, a width W1 of the welding portion 180a-1 of the first metal layer 180 changes gradually. For example, the width W1 of the welding portion 180a-1 is larger than the width W of the finger portion 180b, and the width W1 of the welding portion 180a-1 may gradually increase and then gradually decrease from a side close to the corresponding finger portion 180b. Similarly, in the present embodiment, the second metal layer 190 includes at least one welding portion 190a-1, which is connected to the finger portion 190b-1 or 190b-2, and the shape of the welding portion 190a-1 of the LED 600-3 is different from the shape of the welding portion 190a-1 of the LED 600. In detail, in the present embodiment, a width W2 of the welding portion 190a-1 of the second metal layer 190 changes gradually. For example, the width W2 of the welding portion 190a-1 is larger than the width W′ of the finger portions 190b-1 and 190b-2, and the width W2 of the welding portion 190a-1 may gradually increase and then gradually decrease from a side close to the corresponding finger portions 190b-1 and 190b-2.

Referring to FIG. 41, another difference between the LED 600-3 and the foregoing LED 600 is that: the shape of at least one finger portion 190b-2 of the second metal layer 190 of the LED 600-3 is different from the shape of the finger portion 190b of the second metal layer 190 of the LED 600. For example, in the present embodiment, the second metal layer 190 includes a plurality of finger portions 190b-1 and a plurality of finger portions 190b-2. The finger portion 190b-1 may have a straight shape. The finger portion 190b-2 includes a straight sub portion 190b-21 and a bent sub portion 190b-22, wherein the straight sub portion 190b-21 of the finger portion 190b-2 is connected between the corresponding welding portion 190a-1 and the bent sub portion 190b-22. The finger portion 190b-1 is disposed between adjacent two finger portions 190b-2, and the bent sub portions 190b-22 of the adjacent two finger portions 190b-2 are bent toward an end of the finger portion 190b-1 that is away from the welding portion 190a-1. The bent sub portions 190b-22 of two finger portions 190b-2 adjacent to the same finger portion 190b-1 are bent in opposite directions. In addition, in the present embodiment, the second-type semiconductor layer 130 may be patterned to surround the first metal layer 180. That is, the first metal layer 180 is located in the region where the second-type semiconductor layer 130 is removed. Since the first metal layer 180 at where the light emitting layer 120 is disposed is removed as well, the area of the first metal layer 180 may be smaller than or equal to the area of the second metal layer 190, so as to obtain a sufficient light emitting area. However, according to different manufacturing needs, the areas of the first metal layer 180 and the second metal layer 190 are not necessarily in the foregoing relationship.

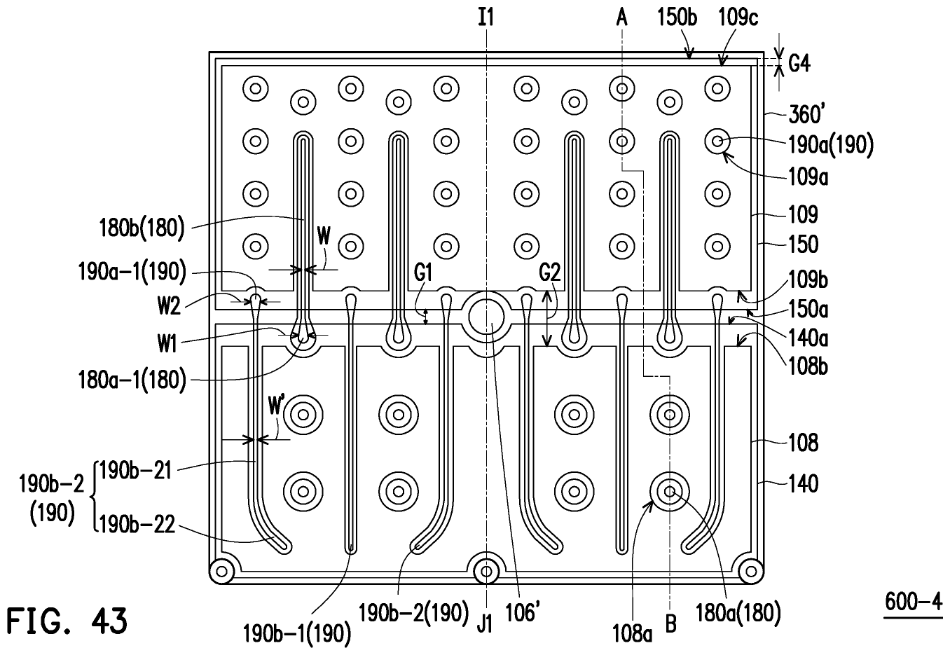

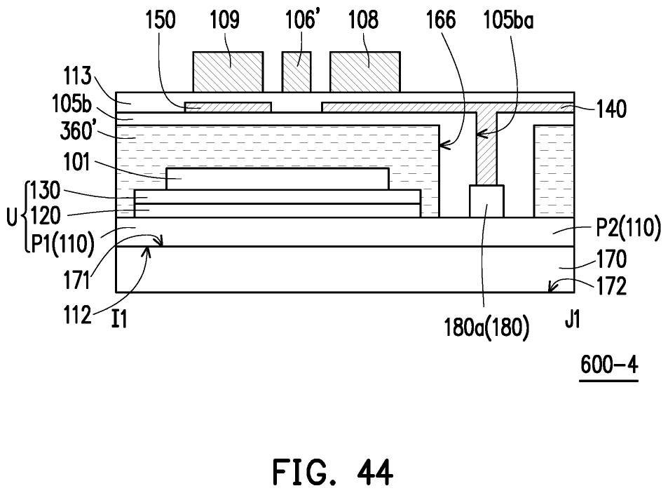

FIG. 43 is a schematic top view of an LED according to an embodiment of the invention. FIG. 44 is a schematic cross-sectional view along a line I1-J1 of FIG. 43. Referring to FIG. 43 and FIG. 44, the LED 600-4 as illustrated is applicable to flip chip packaging. The LED 600-4 in the present embodiment is similar to the foregoing LED 600-3, and a major difference lies in that: the layer to which the bump 106′ of the LED 600-4 belongs is different from the layer to which the bump 106 of the LED 600-3 belongs. In detail, in the present embodiment, the bump 106′, the first bonding layer 108, and the second bonding layer 109 may belong to the same layer. The bump 106′ may be disposed on the second insulating layer 105b that covers the first current conducting layer 140 and the second current conducting layer 150. For the same or similar parts, please refer to the foregoing descriptions.

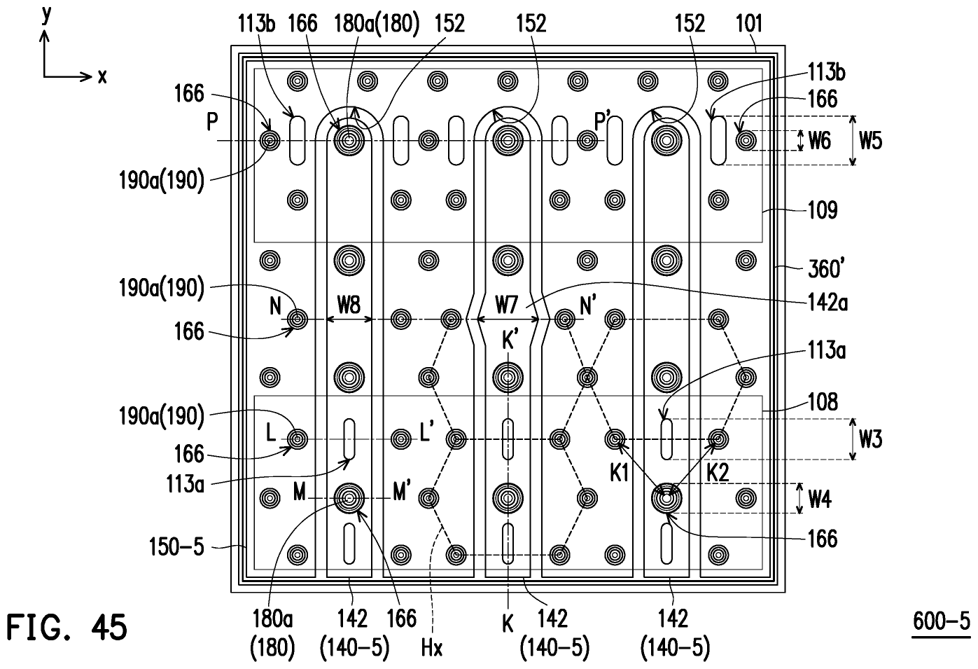

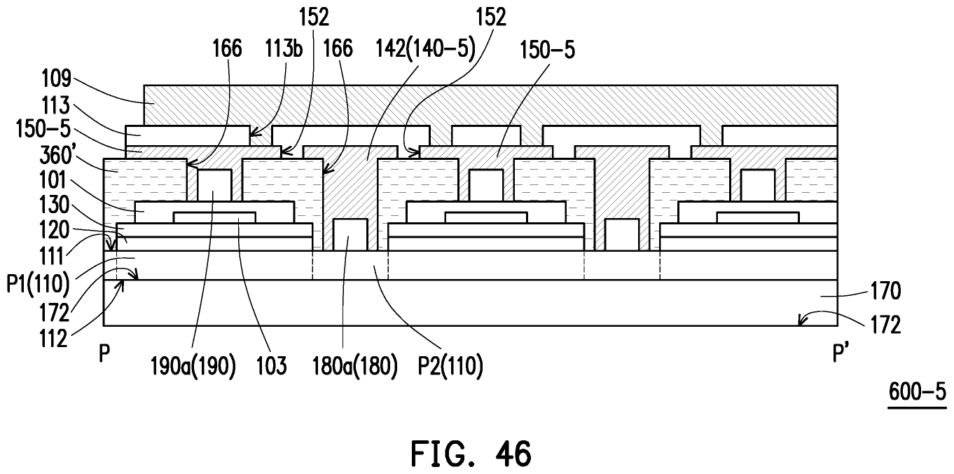

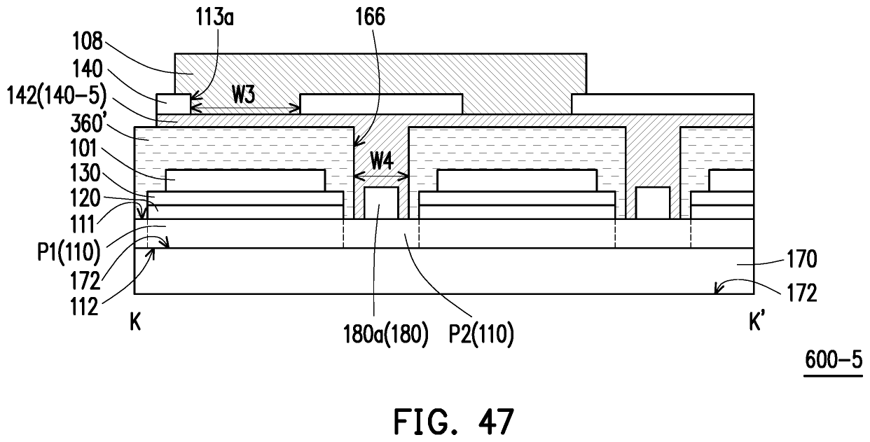

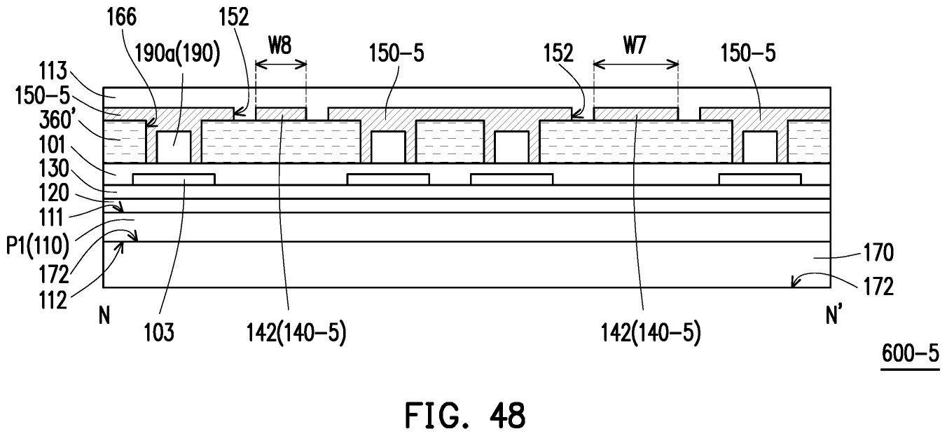

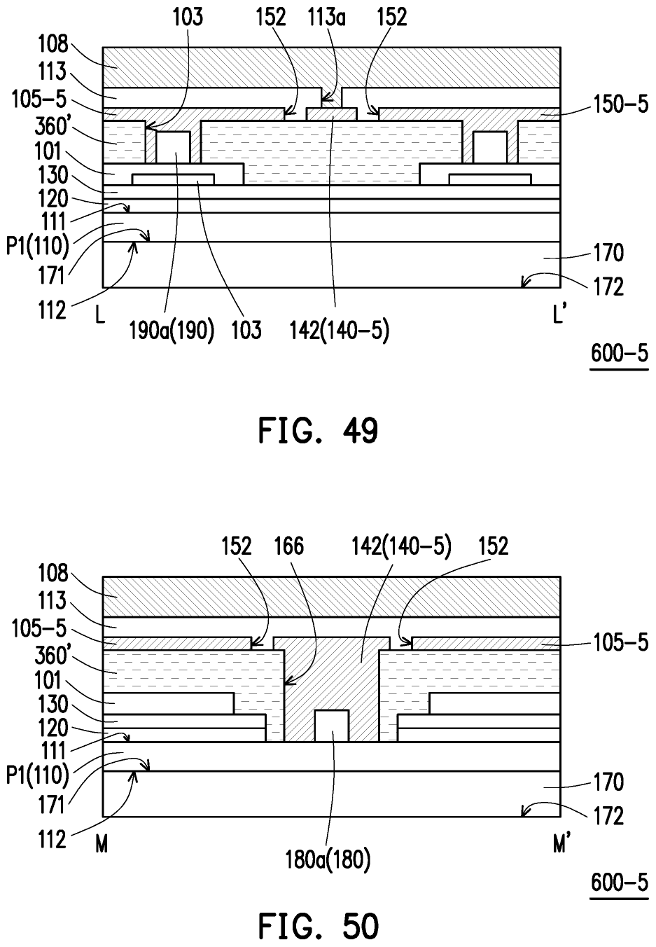

FIG. 45 is a schematic top view of an LED according to an embodiment of the invention. FIG. 46 is a schematic cross-sectional view along a line P-P′ of FIG. 45. FIG. 47 is a schematic cross-sectional view along a line K-K′ of FIG. 45. FIG. 48 is a schematic cross-sectional view along a line N-N′ of FIG. 45. FIG. 49 is a schematic cross-sectional view along a line L-L′ of FIG. 45. FIG. 50 is a schematic cross-sectional view along a line M-M′ of FIG. 45. Referring to FIG. 45 to FIG. 50, the LED 600-5 in the present embodiment is similar to the foregoing LED 600, and a major difference between the LED 600-5 and the LED 600 lies in that: the shapes of a first current conducting layer 140-5 and a second current conducting layer 150-5 of the LED 600-5 are different from the shapes of the first current conducting layer 140 and the second current conducting layer 150 of the LED 600. Referring to FIG. 45, in detail, in the present embodiment, the first current conducting layer 140-5 includes a plurality of conductive portions 142 that are separated from one another, and the second current conducting layer 150-5 has a plurality of recesses 152, and the conductive portions 142 of the first current conducting layer 140-5 are disposed within the areas of the recesses 152 of the second current conducting layer 150-5.

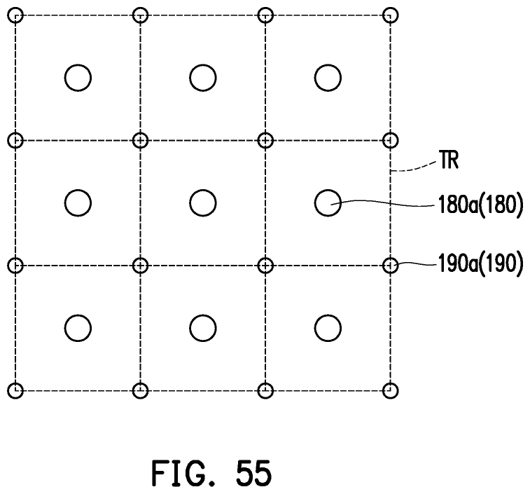

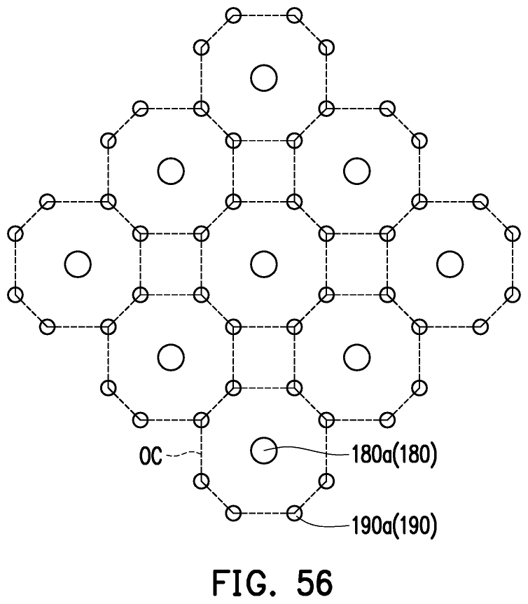

Moreover, in the present embodiment, according to the top view, each welding portion 180a of the first metal layer 180 may be surrounded by a plurality of welding portions 190a of the second metal layer 190. The distances K1 and K2 between one single welding portion 180a and different welding portions 190a of the nearest second metal layer 190 may be equal or not equal. For example, in the present embodiment, one welding portion 180a of the first metal layer 180 may be surrounded by six welding portions 190a of the second metal layer 190, and the six welding portions 190a of the second metal layer 190 may be arranged into a hexagon HX. However, the invention is not limited thereto. In other embodiments, the welding portions 190a of the second metal layer 190 that surround the same welding portion 180a of the first metal layer 180 may also be arranged into other suitable shapes. For example, in another embodiment, as illustrated in FIG. 55, one welding portion 180a of the first metal layer 180 may be surrounded by four welding portions 190a of the second metal layer 190, and the four welding portions 190a of the second metal layer 190 may be arranged into a quadrangle TR; in yet another embodiment, as illustrated in FIG. 56, one welding portion 180a of the first metal layer 180 may be surrounded by eight welding portions 190a of the second metal layer 190, and the eight welding portions 190a of the second metal layer 190 may be arranged into an octagon OC.

Referring to FIG. 45 and FIG. 46, the second bonding layer 109 may have a solid pattern and may not have a through hole in the interior. The second bonding layer 109 may be filled into the through hole 113b of the insulating layer 113 to be electrically connected to the second current conducting layer 150-5, the second current conducting layer 150-5 may be filled into the through hole 166 of the distributed Bragg reflector structure 360′ to be electrically connected to the welding portion 190a of the second metal layer 190 located in the through hole 166, and the welding portion 190a of the second metal layer 190 is disposed on the second-type semiconductor layer 130 and electrically connected to the second-type semiconductor layer 130 via the conductive layer 110. In short, the second bonding layer 109 may be electrically connected to the second-type semiconductor layer 130 via the second current conducting layer 150-5, the welding portion 190a of the second metal layer 190, and the conductive layer 101.

Additionally, in the present embodiment, the through hole 113b of the insulating layer 113 and the through hole 166 of the distributed Bragg reflector structure 360′ may be displaced and may not overlap with each other in the top view. Moreover, the through hole 113b of the insulating layer 113 covered by the second bonding layer 109 has a width W5 in the direction y, and the through hole 166 of the distributed Bragg reflector structure 360′ has a width W6 in the direction y, and W5>W6.

Referring to FIG. 45 and FIG. 47, in the present embodiment, the first bonding layer 108 may have a solid pattern and may not have a through hole in the interior. The conductive portion 142 of the first current conducting layer 140-5 extends in the direction y, and the through hole 113a of the insulating layer 113 covered by the first bonding layer 108 has a width W3 in the direction y. The through hole 166 of the distributed Bragg reflector structure 360′ has a width W4 in the direction y, and W3>W4.

Referring to FIG. 45, FIG. 47, FIG. 49, and FIG. 50, the first bonding layer 108 may be filled into the through hole 113a of the insulating layer 113 to be electrically connected to the conductive portion 142 of the first current conducting layer 140-5, and the conductive portion 142 of the first current conducting layer 140-5 may be filled into the through hole 166 of the distributed Bragg reflector structure 360′ to be electrically connected to the welding portion 180a of the first metal layer 180 located in the through hole 166. The welding portion 180a is disposed on the first-type semiconductor layer 110 and electrically connected to the first-type semiconductor layer 110. In short, the first bonding layer 108 may be electrically connected to the first-type semiconductor layer 110 via the conductive portion 142 of the first current conducting layer 140-5 and the welding portion 180a of the first metal layer 180. Moreover, in the present embodiment, the through hole 113a of the insulating layer 113 and the through hole 166 of the distributed Bragg reflector structure 360′ may be displaced and may not overlap with each other in the top view.

Referring to FIG. 45 and FIG. 48, in the present embodiment, a plurality of conductive portions 142 of the first current conducting layer 140-5 are arranged in the direction x and each have an extending direction parallel to the direction y. Each conductive portion 142 has a middle portion 142a located between the first bonding layer 108 and the second bonding layer 109, which is a part of the each conductive portion 142 that does not overlap with the first bonding layer 108 and the second bonding layer 109, for example. The width of the middle portion 142a (or referred to as a wide sub portion) of at least one conductive portion 142 in the direction x changes. For example, the LED 600-5 of FIG. 45 includes three conductive portions 142, wherein a width W7 of the middle portion 142a of the conductive portion 142 located in the middle may gradually decrease from the center toward the first bonding layer 108 and the second bonding layer 109. The middle portions 142a of the other conductive portions 142 may have a consistent width W8 in the direction x, and the widest part of the width W7>the width W8.

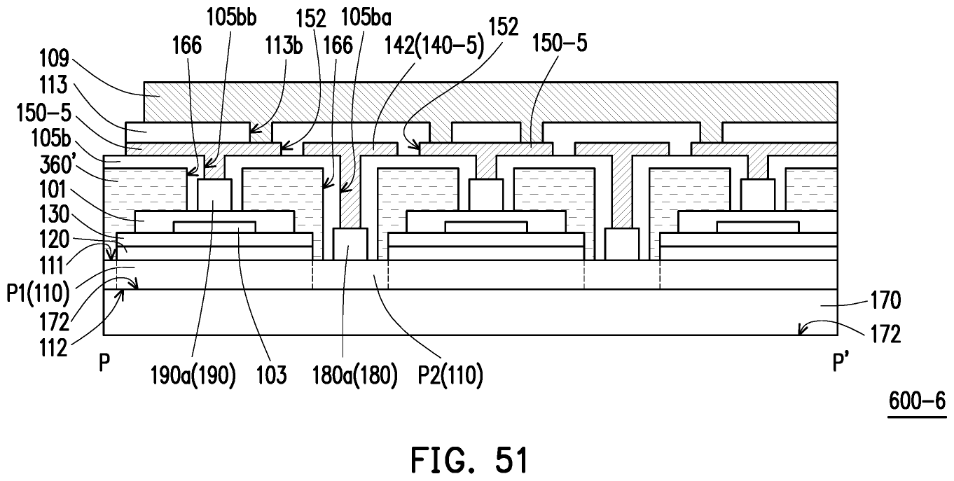

FIG. 51 is a schematic cross-sectional view of an LED according to an embodiment of the invention. FIG. 51 may be another embodiment corresponding to the line P-P′ of FIG. 45. The LED 600-6 of FIG. 51 is similar to the LED 600-5 of FIG. 46, and a major difference lies in that: the LED 600-6 of FIG. 51 further includes the second insulating layer 105b that is located between the first current conducting layer 140-5 and the distributed Bragg reflector structure 360′ and between the second current conducting layer 150-5 and the distributed Bragg reflector structure 360′. The second insulating layer 105b has the through hole 105ba and the through hole 105bb. The second insulating layer 105b may be filled into the through hole 166 of the distributed Bragg reflector structure 360′. The first current conducting layer 140-5 is filled into the through hole 105ba of the second insulating layer 105b in the through hole 166 to be electrically connected to the first metal layer 180. The second current conducting layer 150-5 is filled into the through hole 105bb of the second insulating layer 105b in the through hole 166 to be electrically connected to the second metal layer 190.

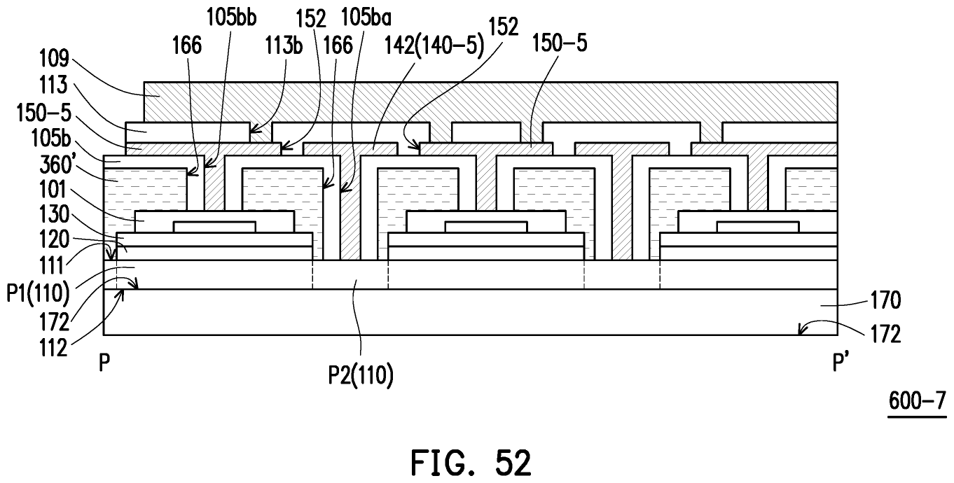

FIG. 52 is a schematic cross-sectional view of an LED according to an embodiment of the invention. FIG. 52 may be yet another embodiment corresponding to the line P-P′ of FIG. 45. The LED 600-7 of FIG. 52 is similar to the LED 600-6 of FIG. 51, and a major difference lies in that: in the LED 600-7 of FIG. 52, the first metal layer 180 and the second meta layer 190 may be omitted. The first current conducting layer 140-5 may be filled into the through hole 105ba of the second insulating layer 105b to be electrically connected to the first-type semiconductor layer 110 directly, and the second current conducting layer 150-5 may be filled into the through hole 105bb of the second insulating layer 105b to be electrically connected to the conductive layer 101 on the second-type semiconductor layer 130 directly.

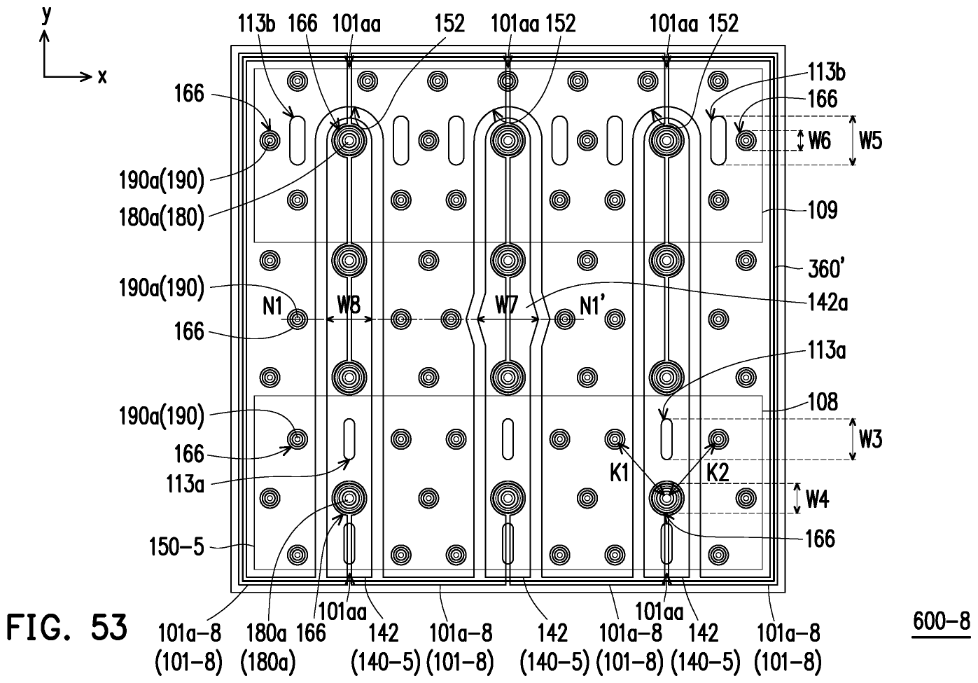

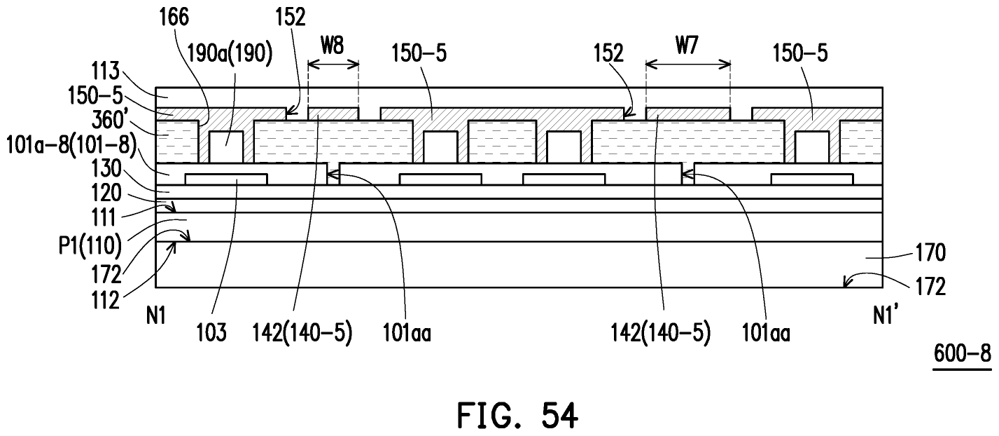

FIG. 53 is a schematic top view of an LED according to an embodiment of the invention. FIG. 54 is a schematic cross-sectional view along a line N1-N1′ of FIG. 53. Referring to FIG. 53 and FIG. 54, the LED 600-8 in the present embodiment is similar to the foregoing LED 600-6, and a major difference lies in that: a conductive layer 101-8 of the LED 600-8 has a plurality of recesses 101aa. A plurality of welding portions 180a of the first metal layer 180 are located within the areas of the recesses 101aa of the conductive layer 101-8. The conductive layer 101-8 includes a plurality of conductive blocks 101a-8, and the first metal layer 180 is located within the areas of the recesses 101aa where the conductive blocks 101a-8 are separated. The conductive blocks 101a-8 of the conductive layer 101-8 of the LED 600-8 may not be completely separated and may be partially connected. In the present embodiment, each recess 101aa of the conductive layer 101-8 is approximately located right under the conductive portion 142 of the first current conducting layer 140-5, but the invention is not limited thereto.

To sum up, the LED according to an embodiment of the invention includes the first-type semiconductor layer, the second-type semiconductor layer, and the light emitting layer located between the first-type semiconductor layer and the second-type semiconductor layer. The LED further includes the metal layer located on the semiconductor layer and electrically connected to the semiconductor layer, the current conducting layer, and the bonding layer. The metal layer is located between the current conducting layer and the semiconductor layer. The current conducting layer is located between the bonding layer and the metal layer. The bonding layer is electrically connected to the semiconductor layer via the current conducting layer and the metal layer. In particular, the pattern of the bonding layer is not solid but has a plurality of through holes that overlap with the metal layer. In other words, the physical area of the bonding layer and the physical area of the metal layer are displaced, and a path exists between the bonding layer and the metal layer. Thereby, in the process of using the bonding layer to bond an external circuit board, the bonding material (e.g., solder paste) does not easily flow through the path completely to cause a short circuit problem.

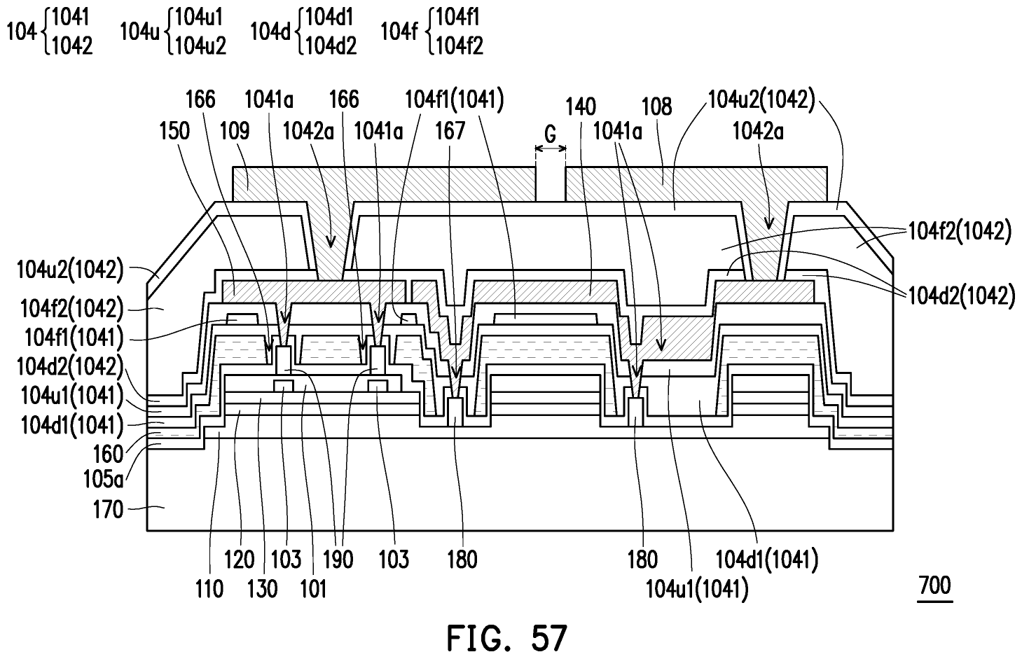

FIG. 57 to FIG. 64 are schematic cross-sectional views of an LED according to different embodiments of the invention.

Referring to FIG. 57, an LED 700 of flip chip packaging is illustrated. A top view layout of the LED 700 is similar to the top view layout of the LED 600′ in FIG. 20 since a major difference therebetween is the layouts of the cross-sectional structures. Thereby, the repetitive descriptions of the top view layout are omitted. The LED 700 includes a first-type semiconductor layer 110, a light emitting layer 120, a second-type semiconductor layer 130 (wherein the first and the second-type semiconductor layers 110 and 130 and the light emitting layer 120 may be treated as a light emitting unit), a first current conducting layer 140, a second current conducting layer 150, a Bragg reflector structure 160, a first insulating layer 105a, a conductive layer 101, an insulating pattern 103, a growth substrate 170, a first metal layer 180, a second metal layer 190, a first bonding layer 108, a second bonding layer 109, and at least one functional stacking layer 104. In the present embodiment, a form of the at least one functional stacking layer 104 is, for example, a sandwich structure, and the at least one functional stacking layer 104 includes an upper insulating layer 104u away from the growth substrate 170, a lower insulating layer 104d close to the growth substrate 170, and a functional layer 104f. Herein, the functional layer 104f is located between the upper insulating layer 104u and the lower insulating layer 104d, and the functional layer 104f includes a reflector structure layer which is electrically floating or a buffer layer. More specifically, in the present embodiment, the number of the at least one functional stacking layer 104 is, for example, two, and the functional stacking layers 104 are respectively called as a first functional stacking layer 1041 and a second functional stacking layer 1042. A functional layer 104f1 in the first functional stacking layer 1041 includes the reflector structure layer which is electrically floating, and a functional layer 104f2 in the second functional stacking layer 1042 includes the buffer layer.

Referring to FIG. 57 again, in the present embodiment, the light emitting layer 120 is located between the first-type semiconductor layer 110 and the second-type semiconductor layer 130. The first metal layer 180 is located on the first-type semiconductor layer 110 and is in contact with and electrically connected to the first-type semiconductor layer 110. The first metal layer 180 is located between the first current conducting layer 140 and the first-type semiconductor layer 110. The first current conducting layer 140 is electrically connected to the first-type semiconductor layer 110 via the first metal layer 180. The first current conducting layer 140 is located between the first bonding layer 108 and the first metal layer 180. The first bonding layer 108 is electrically connected to the first-type semiconductor layer 110 via the first current conducting layer 140 and the first metal layer 180. The insulating pattern 103 is disposed on a surface of the second-type semiconductor layer 130. The conductive layer 101 is disposed on the surface of the second-type semiconductor layer 130 and covers the insulating pattern 103. The second metal layer 190 is located on the second-type semiconductor layer 130 and is electrically connected to second-type semiconductor layer 130 via the conductive layer 101, and the position of the second metal layer 190 corresponds to the insulating pattern 103. The second metal layer 190 is located between the second current conducting layer 150 and the second-type semiconductor layer 130 (or the conductive layer 101). The second current conducting layer 150 is electrically connected to the second-type semiconductor layer 130 via the second metal layer 190. The second current conducting layer 150 is located between the second bonding layer 109 and the second metal layer 190. The second bonding layer 109 is electrically connected to the second-type semiconductor layer 130 via the second current conducting layer 150 and the second metal layer 190. The first functional stacking layer 1041 and the second functional stacking layer 1042 are disposed on the first-type semiconductor layer 110, the light emitting layer 120, and the second-type semiconductor layer 130, and the first functional stacking layer 1041 is closer to the growth substrate 170 compared to the second functional stacking layer 1042. In detail, the first current conducting layer 140 is located between a first upper insulating layer 104u1 of the first functional stacking layer 1041 and a second lower insulating layer 104d2 of the second functional stacking layer 1042, and the second current conducting layer 150 is located between the first upper insulating layer 104u1 of the first functional stacking layer 1041 and the second lower insulating layer 104d2 of the second functional stacking layer 1042. In addition, a second upper insulating layer 104u2 of the second functional stacking layer 1042, the second functional layer 104f2 (the buffer layer), and the second lower insulating layer 104d2 are exposed to the outside.

Referring to FIG. 57 again, in more detail, the first functional stacking layer 1041 has a plurality of through holes 1041a located between the second metal layer 190 and the second current conducting layer 150 and located between the first metal layer 180 and the first current conducting layer 140, and the second functional stacking layer 1042 has a plurality of through holes 1042a located between the second bonding layer 109 and the second current conducting layer 150 and located between the first bonding layer 108 and the first current conducting layer 140. Herein, the first bonding layer 108 and the second bonding layer 109 are respectively filled into some of these through holes 1042a and are electrically connected to first current conducting layer 140 and the second current conducting layer 150 respectively. The first current conducting layer 140 and the second current conducting layer 150 are respectively filled into some of these through holes 1041a and are electrically connected to the first metal layer 180 and the second metal layer 190 respectively. The Bragg reflector structure 160 has a plurality of through holes 166 located between the second current conducting layer 150 and the second-type semiconductor layer 130 and a plurality of through holes 167 located between the first current conducting layer 140 and the first-type semiconductor layer 110. Herein, the first metal layer 180 is filled into these through holes 167 to be electrically connected to the first-type semiconductor layer 110, and the second metal layer 190 is filled into these through holes 166 to be electrically connected to the conductive layer 101 and the second-type semiconductor layer 130. These through holes 1042a, 1041a, 166, and 167 do not overlap with one another (or are displaced). In other words, the first functional layer 104f1 (the reflector structure layer), the first metal layer 180, the second metal layer 190, the first bonding layer 108, and the second bonding layer 109 overlap with the light emitting layer 120.

In addition, a gap G exists between the first bonding layer 108 and the second bonding layer 109, and the orthogonal projection of the gap G overlaps with the first functional layer 104f1 (the reflector structure layer). In this way, in the assembly process of the LED 700 and an external circuit, a short circuit problem or an electricity leakage problem derived from damaged internal structure of the LED 700 caused by the thimble process is prevented from occurring.

In the present embodiment, the material of the reflector structure layer may be Al, Alloy Al, Alloy Al/Cu, Ti, Ni, Pt, or combinations thereof. The material of the buffer layer may be polyimide, a polymer material, an organic adhesive material, an organic insulating material, a photo sensitive material, or an electrically floating metal material. The materials of other devices are described in the foregoing paragraphs, and thus the repetitive descriptions are omitted.

In view of the above, in the LED 700 of the present embodiment, the at least one functional stacking layer 104 is disposed, and the functional layer 104f in the at least one functional stacking layer 104 may be the reflector structure layer which is electrically floating or the buffer layer. When the functional layer 104f is the reflector structure layer, increased light beams from the light emitting layer 120 are emitted from the LED 700, and that light emission efficiency is improved. When the functional layer 104f is the buffer layer, even though the LED 700 may generate heat owing to long-term use and an internal device in the LED 700 may generate thermal stress owing to such heat, an effect generated by such stress may be effectively reduced by the buffer layer. Therefore, the LED 700 exhibits good device reliability. In addition, through the buffer layer, a structure of the LED 700 is prevented from being damaged (including cracking of the insulating layers, the metal layers, the semiconductor layers, or the light emitting layer, for example) when a thimble drawn and fitted to an robot arm is pushed up, and such damage may lead to an electricity leakage problem, a poor light emitting problem, and a quality abnormality problem in the LED 700.

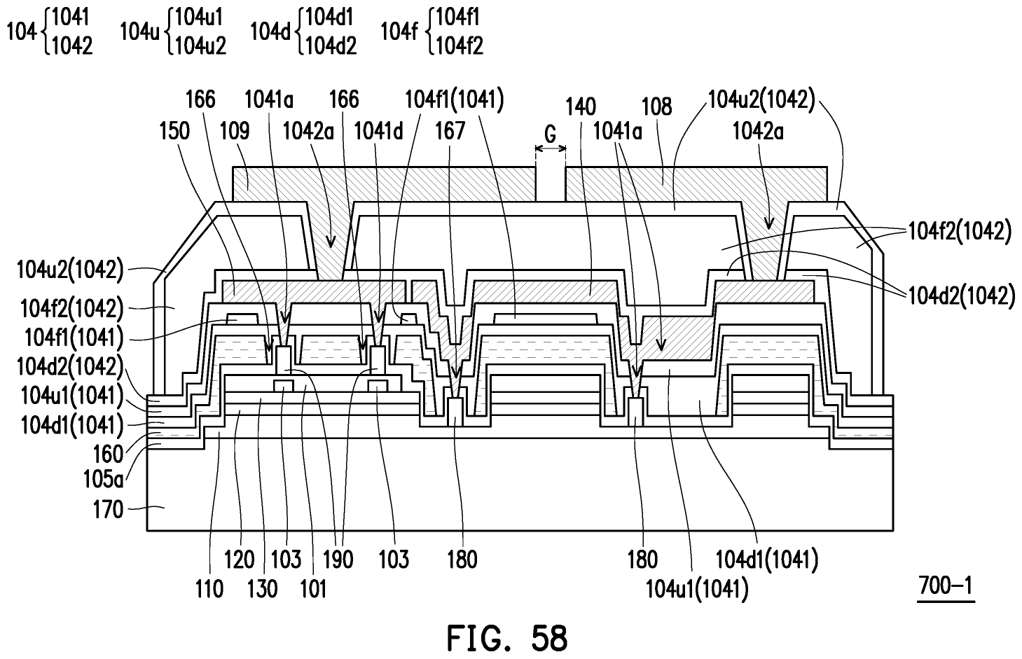

Referring to FIG. 58, an LED 700-1 of FIG. 58 is generally similar to the LED 700 of FIG. 57, and a major difference therebetween lies in that: the second upper insulating layer 104u2 and the second lower insulating layer 104d2 are exposed to the outside and completely cover the second functional layer 104f2 (the buffer layer). Since a material of the buffer layer is generally soft, when being completely covered by the second upper and lower insulating layers 104u2 and 104d2, the buffer layer is not susceptible to be cracked during a singularization process (a cutting process).

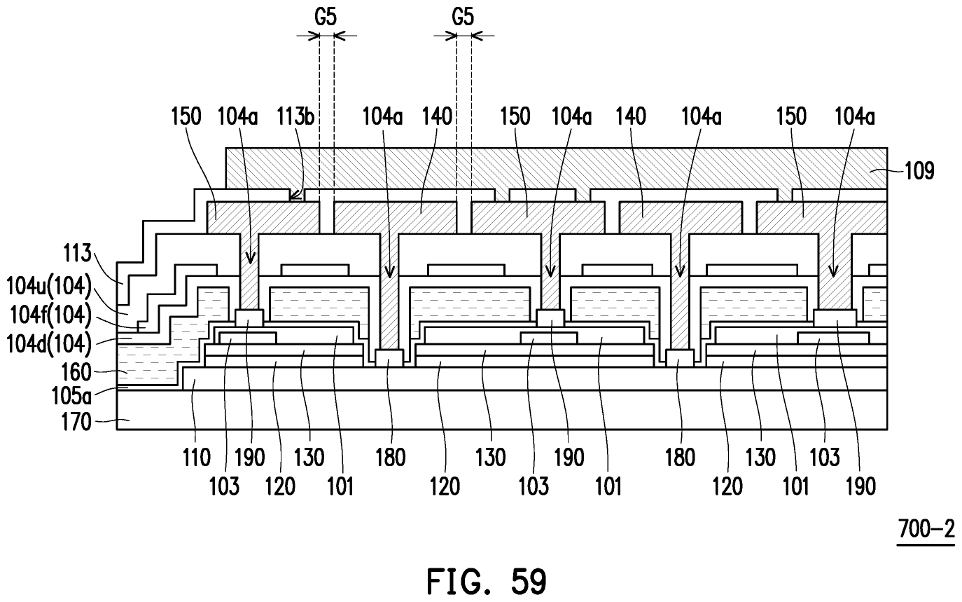

Referring to FIG. 59, a cross-sectional structure layout of an LED 700-2 of FIG. 59 is generally similar to that of the LED 700 of FIG. 57, and a top view layout of the LED 700-2 is generally similar to that of the LED 600-5 of FIG. 45. A major between the LED 700-2 and the LED 700 lies in that: an insulating layer 113 is further included in the LED 700-2. The insulating layer 113 is disposed between the second bonding layer 109 and the first current conducting layer 140 and is disposed between the second bonding layer 109 and the second current conducting layer 150. The insulating layer 113 has a plurality of through holes 113b, and the second bonding layer 109 are filled into the through holes 113b. In addition, the number of the functional stacking layer 104 is one. Moreover, the upper insulating layer 104u of the functional stacking layer 104 and the insulating layer 113 cover the first current conducting layer 140 and the second current conducting layer 150 together. Herein, the functional layer 104f of the functional stacking layer 104 includes the reflector structure layer which is electrically floating. The functional stacking layer 104 has a plurality of through holes 104a. The first current conducting layer 140, the second current conducting layer 150 are filled into the through holes 104a to be electrically connected to the first metal layer 180 and the second metal layer 190 respectively. The functional stacking layer 104 is located between the first current conducting layer 140 and the second-type semiconductor layer 130 and is located between the second current conducting layer 150 and the second-type semiconductor layer 130. In addition, the first-type semiconductor layer 110 exposes a partial surface of the growth substrate 170, and the insulating layer 105a covers the partial surface.

It should be noted that a gap G5 exists between the first and the second current conducting layers 140 and 150, and the gap G5 overlaps with the functional layer 104f. Thereby, if some light beams are emitted from the gap G5 and are transmitted towards a direction of the functional layer 104f, the chance of the light beams being reflected by the functional layer 104f increases, and that light emitting efficiency is improved.

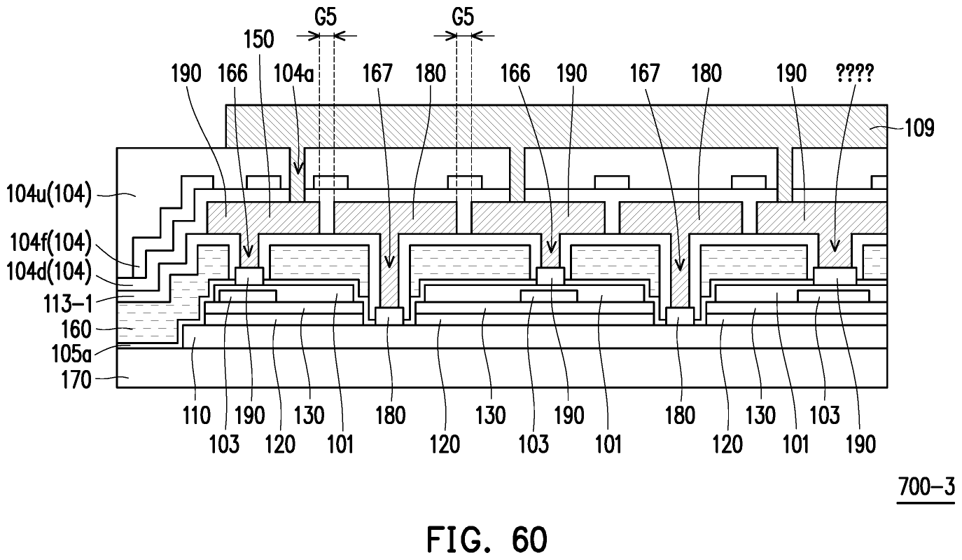

Referring to FIG. 60, a cross-sectional structure layout of an LED 700-3 of FIG. 60 is generally similar to that of the LED 700-2 of FIG. 59, and a top view layout of the LED 700-3 is generally similar to that of the LED 600-5 of FIG. 45. The major difference between the LED 700-3 and the LED 700-2 lies in that: in the LED 700-3, the first current conducting layer 140 is located between the functional stacking layer 104 and the second-type semiconductor layer 130, and the second current conducting layer 150 is located between the functional stacking layer 104 and the second-type semiconductor layer 130. In addition, the LED 700-3 further includes an insulating layer 113-1. The insulating layer 113-1 is disposed between the Bragg reflector structure 160 and the lower insulating layer 104d and covers the Bragg reflector structure 160 together with the insulating layer 105a.

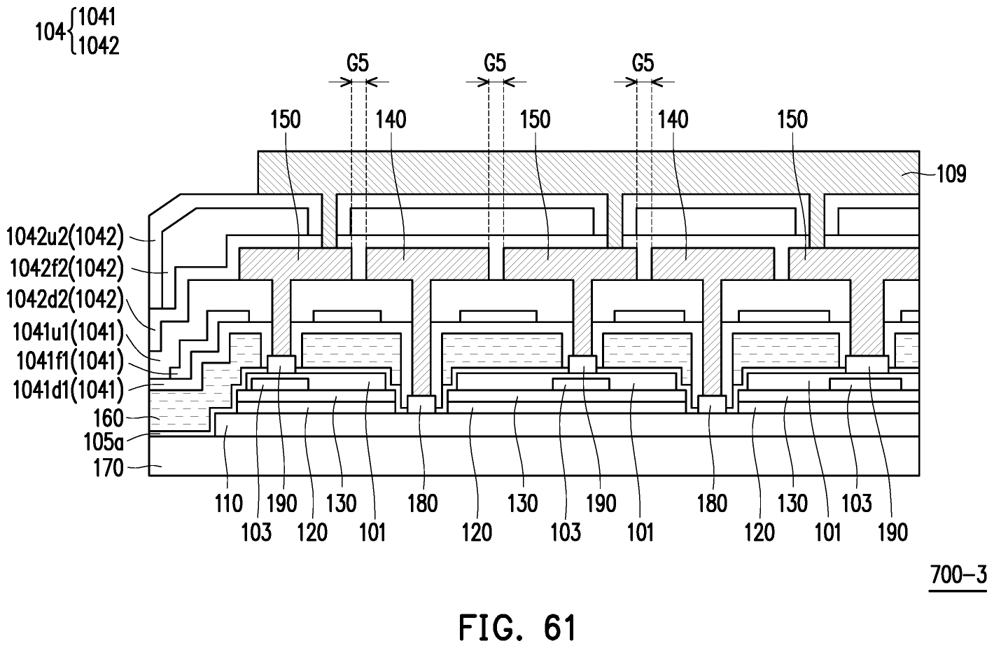

Referring to FIG. 61, a cross-sectional structure layout of an LED 700-3 of FIG. 61 is generally similar to that of the LED 700-2 of FIG. 60, and a top view layout of the LED 700-3 is generally similar to that of the LED 600-5 of FIG. 45. The major difference between the LED 700-3 and the LED 700-2 lies in that: in the LED 700-3, the number of the at least one functional stacking layer 104 is plural, for example, and the number is, for example, two, so the functional stacking layers 104 are respectively called as a first functional stacking layer 1041 and a second functional stacking layer 1042. The first current conducting layer 140 and the second current conducting layer 190 are located between the first functional stacking layer 1041 and the second functional stacking layer 1042. Moreover, the first functional stacking layer 1041 is located between the first current conducting layer 140 and the second-type semiconductor layer 130 and is located between the second current conducting layer 150 and the second-type semiconductor layer 130. In addition, in the second functional stacking layer 1042, the second upper insulating layer 104u2 and the second lower insulating layer 104d2 are exposed to the outside and completely cover the second functional layer 104f2 (the buffer layer).

It should be noted that the gap G5 exists between the first and the second current conducting layers 140 and 150, and the gap G5 overlaps with the second functional layer 104f2. In this way, in the assembly process of the LED 700-3 and an external circuit, a device short circuit problem caused by the first and the second bonding layers 108 and 109, solder paste used by an external circuit for bonding, or other bonding materials due to metal migration or solder overflow may be prevented, and a device damage or leakage problem caused by strengthening the ability to withstand the force of the thimble produced by the die-bonding process may also be prevented.

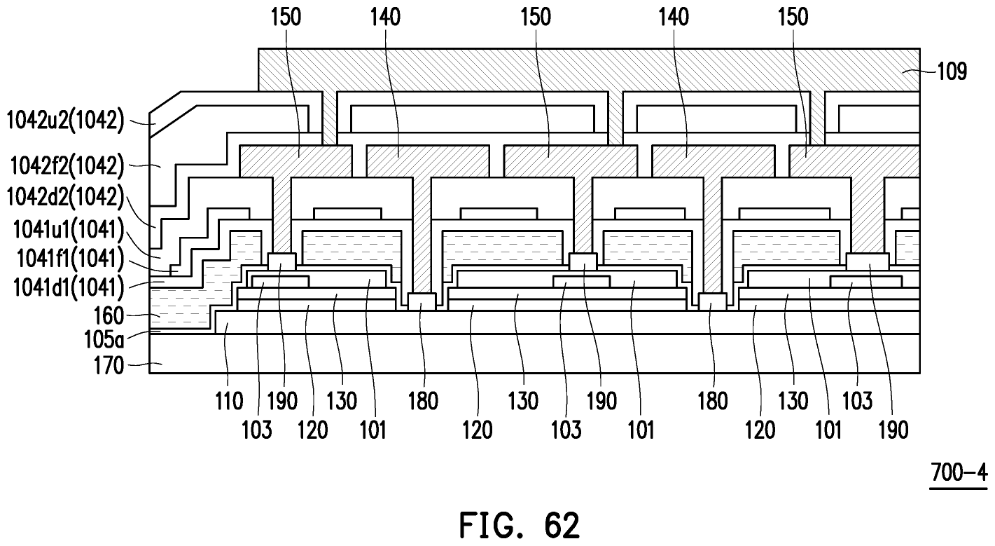

Referring to FIG. 62, a cross-sectional structure layout of an LED 700-4 of FIG. 62 is generally similar to that of the LED 700-3 of FIG. 61, and a top view layout of the LED 700-4 is generally similar to that of the LED 600-5 of FIG. 45. The major difference between the LED 700-4 and the LED 700-3 lies in that: in the LED 700-4, a second upper insulating layer 104u2 of the second functional stacking layer 1042, the second functional layer 104f2 (the buffer layer), and the second lower insulating layer 104d2 are exposed to the outside.

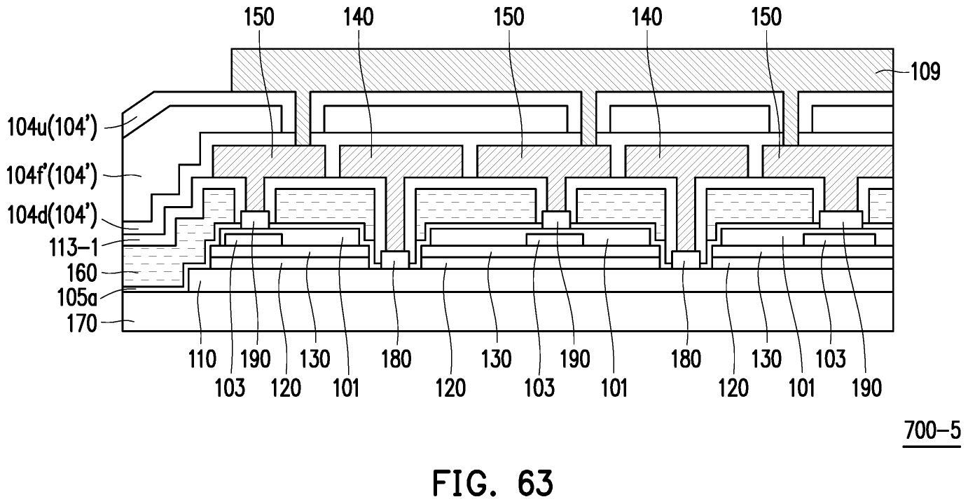

Referring to FIG. 63, a cross-sectional structure layout of an LED 700-5 of FIG. 63 is generally similar to that of the LED 700-4 of FIG. 62, and a top view layout of the LED 700-5 is generally similar to that of the LED 600-5 of FIG. 45. The major difference between the LED 700-5 and the LED 700-4 lies in that: in the LED 700-5, a number of a functional stacking layer 104′ is one, a functional layer 104f′ in the functional stacking layer 104′ includes the buffer layer, and an upper insulating layer 104u, a lower insulating layer 104d, and a functional layer 104f′ of the functional stacking layer 104′ are exposed to the outside. Besides, the LED 700-5 further includes the insulating layer 113-1 located between the functional stacking layer 104′ and the Bragg reflector structure 160.

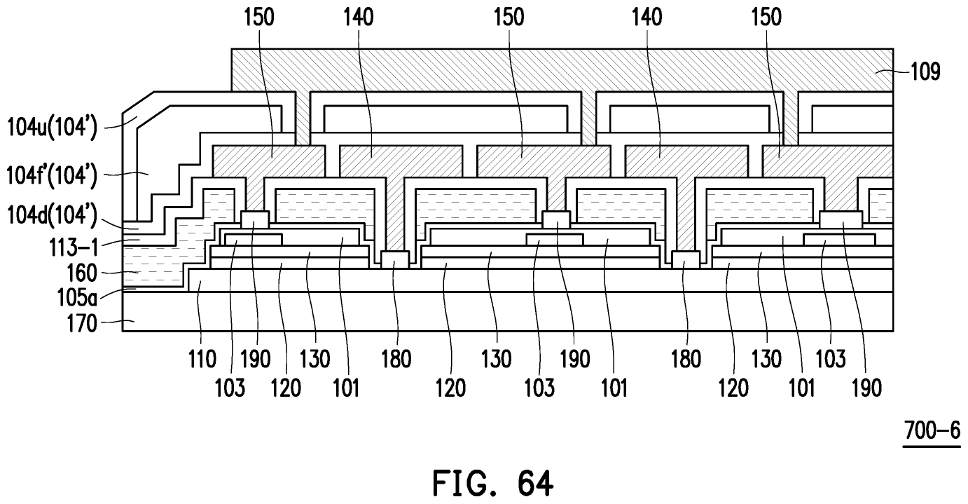

Referring to FIG. 64, a cross-sectional structure layout of an LED 700-6 of FIG. 64 is generally similar to that of the LED 700-4 of FIG. 62, and a top view layout of the LED 700-6 is generally similar to that of the LED 600-5 of FIG. 45. The major difference between the LED 700-6 and the LED 700-4 lies in that: in the LED 700-5, the number of the functional stacking layer 104′ is one, the functional layer 104f′ in the functional stacking layer 104′ includes the buffer layer, and the upper insulating layer 104u and the lower insulating layer 104d of the functional stacking layer 104′ are exposed to the outside. Besides, the LED 700-5 further includes the insulating layer 113-1 located between the functional stacking layer 104′ and the Bragg reflector structure 160.

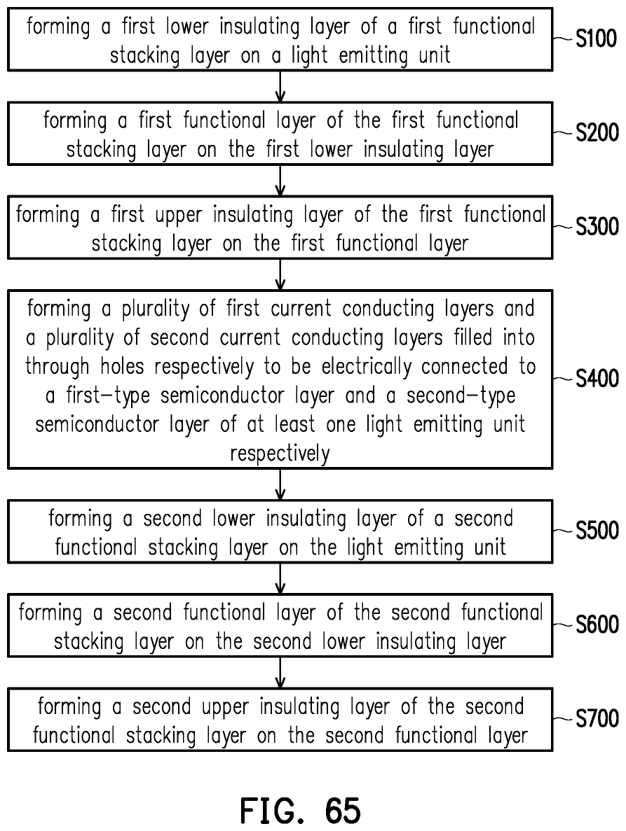

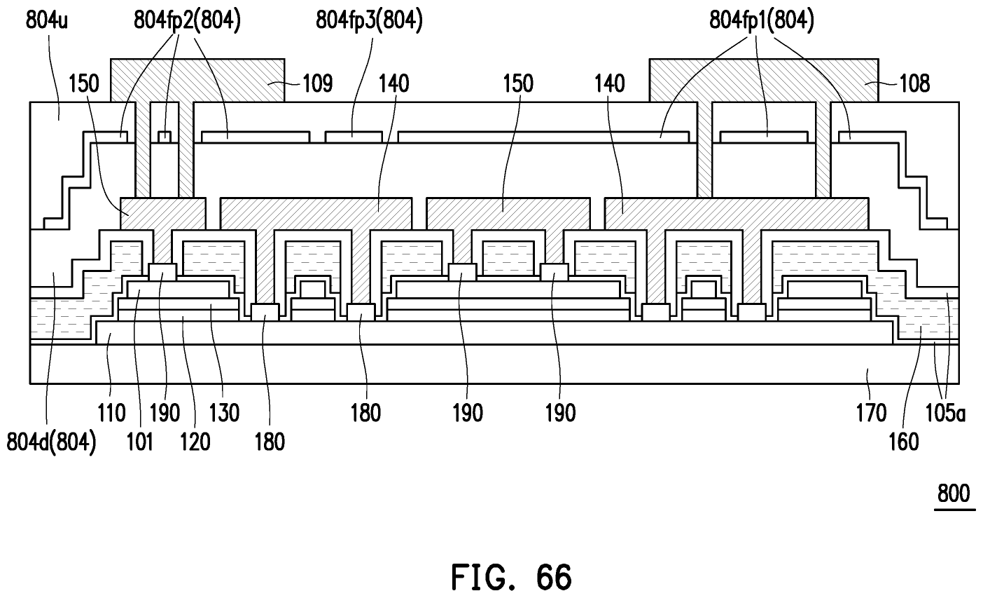

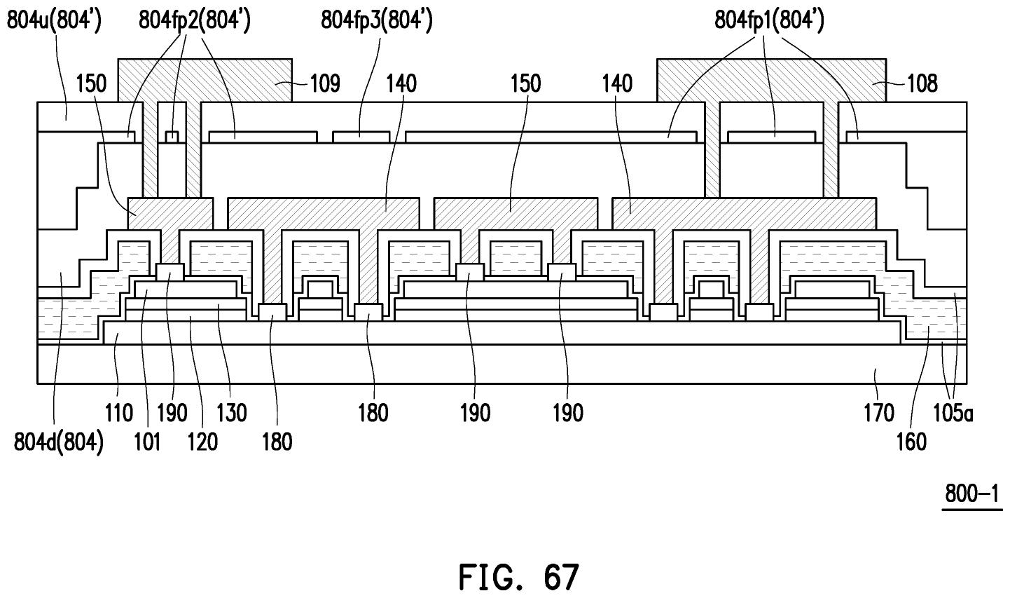

FIG. 65 is a partial flowchart of manufacturing the LED of the embodiment of FIG. 57.

Referring to FIG. 65, a complete manufacturing method of the LED 700 of the embodiment of FIG. 57 is generally similar to the manufacturing method shown in FIG. 28. The major difference therebetween lies in that: step T190 in FIG. 28 is replaced by the following seven steps S100 to S700. Steps S100 to S300 are the major steps for forming a first functional stacking layer 1401, and the steps S500 to S700 are the major steps for forming a second functional stacking layer 1402.

In Step S100: a first lower insulating layer 140d1 of the first functional stacking layer 1401 is formed on a light emitting unit. Herein, the first lower insulating layer 140d1 covers a first electrode (the first metal layer 180), a second electrode (the second metal layer 190), and the light emitting unit.

In Step S200: a first functional layer 140f1 (the reflector structure layer) of the first functional stacking layer 1401 is formed on a first lower insulating layer 140d1.

In Step S300: a first upper insulating layer 140u1 of the first functional stacking layer 1401 is formed on the first functional layer 140f1. Manufacturing of the first functional stacking layer 1401 is generally completed so far.

In Step S400: a plurality of first current conducting layers 140 and a plurality of second current conducting layers 150 are formed and are filled into through holes 1041a respectively, so as to be electrically connected to a first-type semiconductor layer 110 and a second-type semiconductor layer 120 of at least one light emitting unit respectively.

In Step S500: a second lower insulating layer 140d2 of the second functional stacking layer 1402 is formed on the light emitting unit (or on the first functional stacking layer 1041 or the first and the second current conducting layers 140 and 150), and the second lower insulating layer 140d2 covers the first upper insulating layer 140d1 of the first functional stacking layer 1401.

In Step S600: a second functional layer 140f2 (the buffer layer) of the second functional stacking layer 1402 is formed on the second lower insulating layer 140d2. The second upper and lower insulating layers 140d2 and 140u2 of the second functional stacking layer 1402 and the second functional layer 140f2 (the buffer layer) are exposed to the outside.

In Step S700: a second upper insulating layer 140u2 of the second functional stacking layer 1402 is formed on the second functional layer 140f2. Manufacturing of the second functional stacking layer 1402 is generally completed so far.

In other words, the steps of forming the first and the second current conducting layers 140 and 150 are alternately provided in the steps of forming the first and the second functional stacking layers 1401 and 1402.

Referring to FIG. 65 and FIG. 28 together, after the steps of FIG. 65 are completed, the steps of T200 and T210 in FIG. 28 are performed, and manufacturing of the LED 700 is generally completed so far.

The manufacturing method of manufacturing the LEDs 700-1 to 700-6 of FIG. 58 to FIG. 64 is generally similar to the manufacturing method of manufacturing the LED 700 of FIG. 57. The major difference therebetween lies in the numbers of the functional stacking layers, whether or not the functional layer is covered, the manufacturing orders of the first and the second current conducting layers to be manufactured prior to, after, or alternately provided between the manufacturing orders of the layers, or the layouts of the top view structures. A person of ordinary skill in the art may make appropriate adjustments according to the above difference with reference to the manufacturing method of the LED 700 of FIG. 57 to manufacture the LEDs 700-1 to 700-6, and thus the repetitive descriptions are omitted.

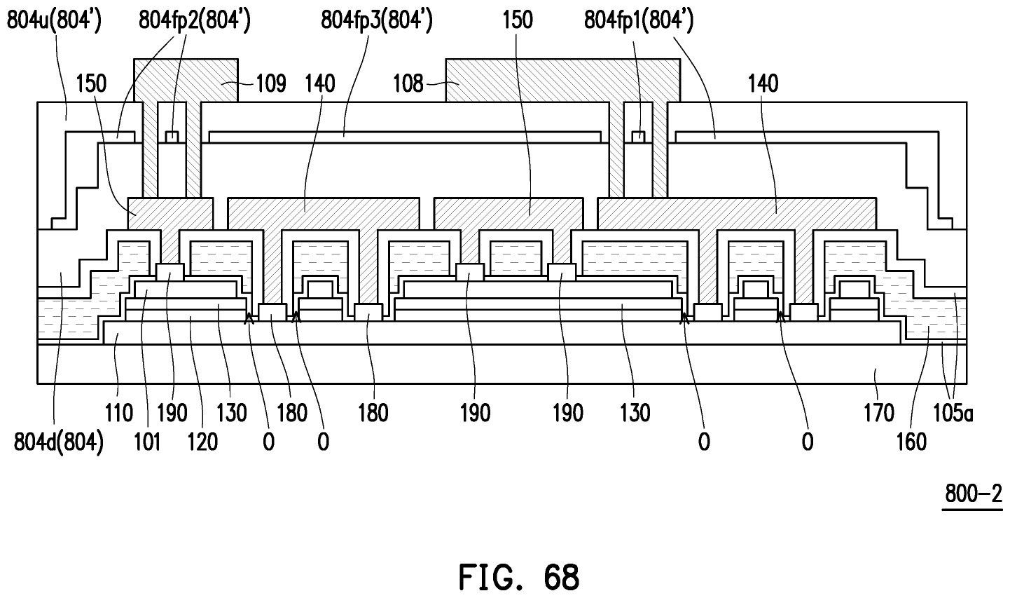

FIG. 66 to FIG. 68 are schematic cross-sectional views of an LED according to different embodiments of the invention.

Referring to FIG. 66, an LED 800 of flip chip packaging is illustrated. A top view layout of the LED 800 is generally similar to the top view layout of the LED 600-5 of FIG. 45 since a major difference therebetween is the layouts of the cross-sectional structures. Thereby, the repetitive descriptions of the top view layout are omitted. The cross-sectional structure layout of the LED 800 is generally similar to the cross-sectional structure layout of the LED 700 of FIG. 57. The major difference therebetween lies in that: a number of a functional stacking layer 804 is one, the first current conducting layer 140 is located between the functional stacking layer 804 and the second-type semiconductor layer 130, and the second current conducting layer 150 is located between the functional stacking layer 804 and the second-type semiconductor layer 130. The functional stacking layer 804 includes an upper and a lower insulating layers 804u and 804d and a functional layer 804f (the reflector structure layer) located between the upper and the lower insulating layers 804u and 804d. Herein, the functional layer 804 includes a first function portion 804fp1, a second function portion 804fp2, and a third function portion 804fp3, and the three portions are separated from one another. Herein, the first function portion 804fp1 and the second function portion 804fp2 are overlap with the first bonding layer 108 and the second boding layer 109, the third function portion 804fp3 is located between the first function portion 804fp1 and the second function portion 804fp2, and the third function portion 804fp3 and the first bonding layer 108 or the second bonding layer 109 are displaced. In more detail, the third function portion 804fp3 generally falls in a middle position of the LED 700. In this embodiment, the functional layer 804 is the reflector structure layer, so that the first to the third function portions 804f1 to 804f3 may also be treated as a first to a third reflector structure portions. In this embodiment, an upper and a lower insulating layers 804u and 804d are exposed to the outside and completely cover the first and the second function portions 804f1 and 804f2. Besides, the LED 800 further includes the insulating layer 113-1 disposed between the Bragg reflector structure 160 and the lower insulating layer 104d. A partial surface of the growth substrate 170 is exposed by the first-type semiconductor layer 110, and the first and the second function portions 804fp1 and 804fp2 (i.e., the first and the second reflector structure portions) overlap with the partial surface. In addition, in other embodiments, the first and the second function portions 804f1 and 804f2 may not overlap with the partial surface.

As described above, in the LED 800 provided by the embodiment, the third function portion 804fp3 (the third reflector structure portion) is disposed between the first and the second function portions 804fp1 and 804fp2 (the first and the second reflector structure portions). In this way, in the assembly process of the LED 800 and an external circuit, a device damage or leakage problem caused by the ability to withstand the force of the thimble produced by the die-bonding process may be prevented.

Referring to FIG. 67, an LED 800-1 of flip chip packaging is illustrated. A cross-sectional structure layout of the LED 800-1 is generally similar to the cross-sectional structure layout of the LED 800 of FIG. 66. The major difference therebetween lies in that: in a functional stacking layer 804′ of the LED 800-1, the upper insulating layer 804u, the first function portion 804fp1 (the first reflector structure portion), the second function portion 804fp2 (the second reflector structure portion), and the lower insulating layer 804d are exposed to the outside.

Referring to FIG. 68, an LED 800-2 of flip chip packaging is illustrated. A cross-sectional structure layout of the LED 800-1 is generally similar to the cross-sectional structure layout of the LED 800 of FIG. 67. The major difference therebetween lies in that: in the LED 800-2, the first bonding layer 108 and the second bonding layer 109 overlap with the second-type semiconductor layer 130 respectively. From another perspective, both the first bonding layer 108 and the second bonding layer 109 and the light emitting layer 120 and through holes O of the second-type semiconductor layer 130 are displaced. Thereby, the surface on which the first bonding layer 108 and the second bonding layer 109 are disposed is flat, so a difference in height may not be easily detected between the first bonding layer 108 and the second bonding layer 109.

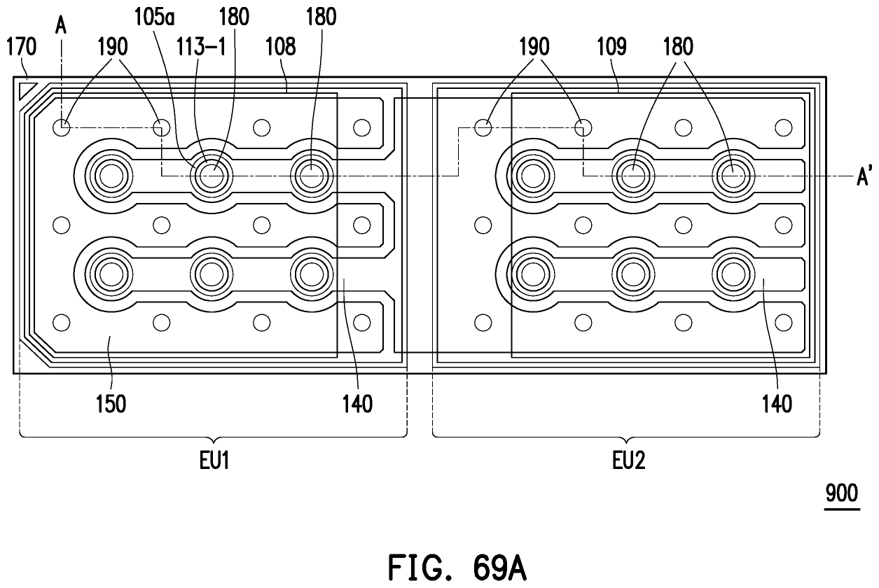

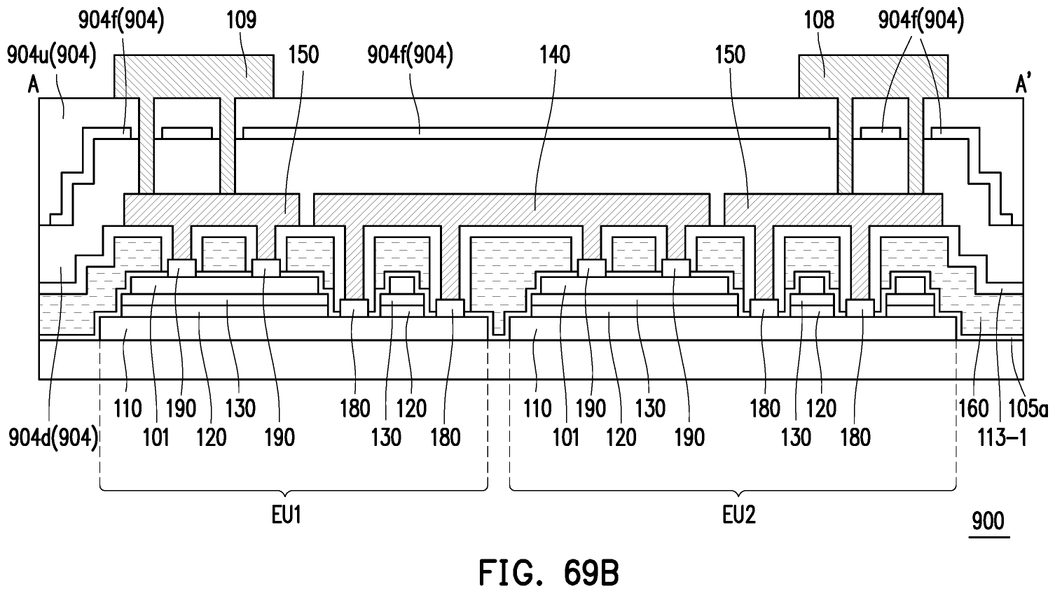

FIG. 69A is a schematic top view of an LED according to an embodiment of the invention. FIG. 69B is a schematic top view of a cross-section A-A′.

Referring to FIG. 69A and FIG. 69B, an LED 900 is generally similar to the LED 700, and a major difference lies in that: in the LED 900, the first-type semiconductor layer 110 includes two separated parts, a partial surface of the growth substrate 170 is exposed between the two separated parts of the first-type semiconductor layer 110. Parts of the light emitting layer 120 and parts of the second-type semiconductor layer 130 are disposed on one part of the first-type semiconductor layer 110 to form a first light emitting unit EU1. Other parts of the light emitting layer 120 and other parts of the second-type semiconductor layer 130 are disposed on the other part of the first-type semiconductor layer 110 to form a second light emitting unit EU2. The first current conducting layer 140 connects the first light emitting unit EU1 and the second light emitting unit EU2 so that the two are connected in series or in parallel. Besides, a functional stacking layer 904 also includes an upper and a lower insulating layers 904u and 904d and a functional layer 904f located therebetween, and the functional layer 904f includes a continuous reflector structure layer. Further, the upper and the lower insulating layers 904u and 904d are exposed to the outside, and the functional layer 904f is completely covered by the upper and the lower insulating layers 904u and 904d.

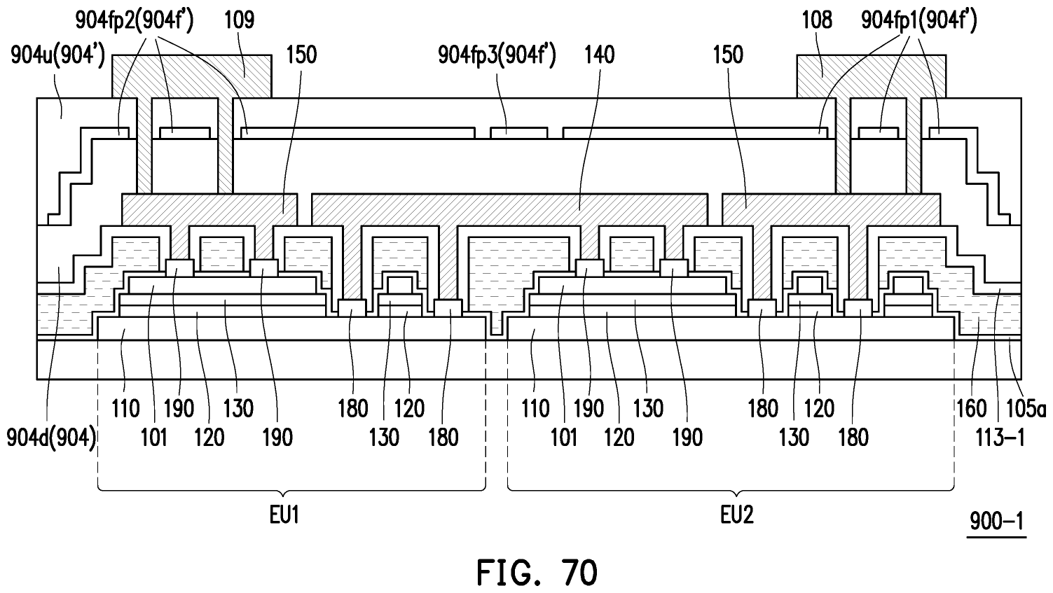

FIG. 70 to FIG. 75 are schematic cross-sectional views of an LED according to different embodiments of the invention.

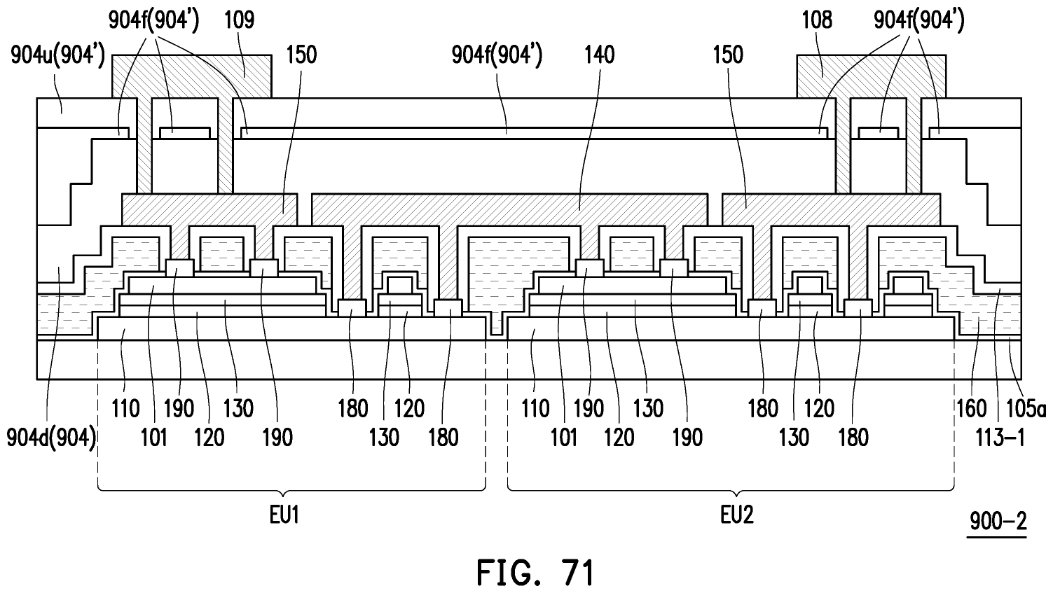

Referring to FIG. 70, a top view layout of an LED 900-1 of FIG. 71 is generally similar to the top view layout of the LED 900 of FIG. 69 since a major difference therebetween is the layouts of the cross-sectional structures. Thereby, the repetitive descriptions of the top view layout are omitted. A cross-sectional structure layout of the LED 900-1 is generally similar to the cross-sectional structure layout of the LED 900. The major difference therebetween lies in that: a functional layer 904f′ in a functional stacking layer 904′ includes a first function portion 904fp1, a second function portion 904fp2, and a third function portion 904fp3 separated from one another. Herein, the first and the second function portions 904fp1 and 904fp2 respectively overlap with the first and the second bonding layers 108 and 109, and the third function portion 904fp3 is located between the first and the second function portions 904fp1 and 904fp2. In the present embodiment, the functional layer 904f is the reflector structure layer, so that the first to the third function portions 904fp1 to 904fp3 may also be treated as the first to the third function portions. In the assembly process of the LED 900-1 and an external circuit, a device damage problem or an electricity leakage problem caused by the ability to withstand the force of the thimble produced by the die-bonding process may be prevented through the third function portion 904fp3 (the third reflector structure portion).

Referring to FIG. 71, a top view layout of an LED 900-2 of FIG. 71 is generally similar to the top view layout of the LED 900 of FIG. 69 since a major difference therebetween is the layouts of the cross-sectional structures. Thereby, the repetitive descriptions of the top view layout are omitted. A cross-sectional structure layout of the LED 900-2 is generally similar to the cross-sectional structure layout of the LED 900. The major difference therebetween lies in that: the functional layer 904f and the upper and the lower insulating layers 904u and 904d in the functional stacking layer 904 are exposed to the outside.

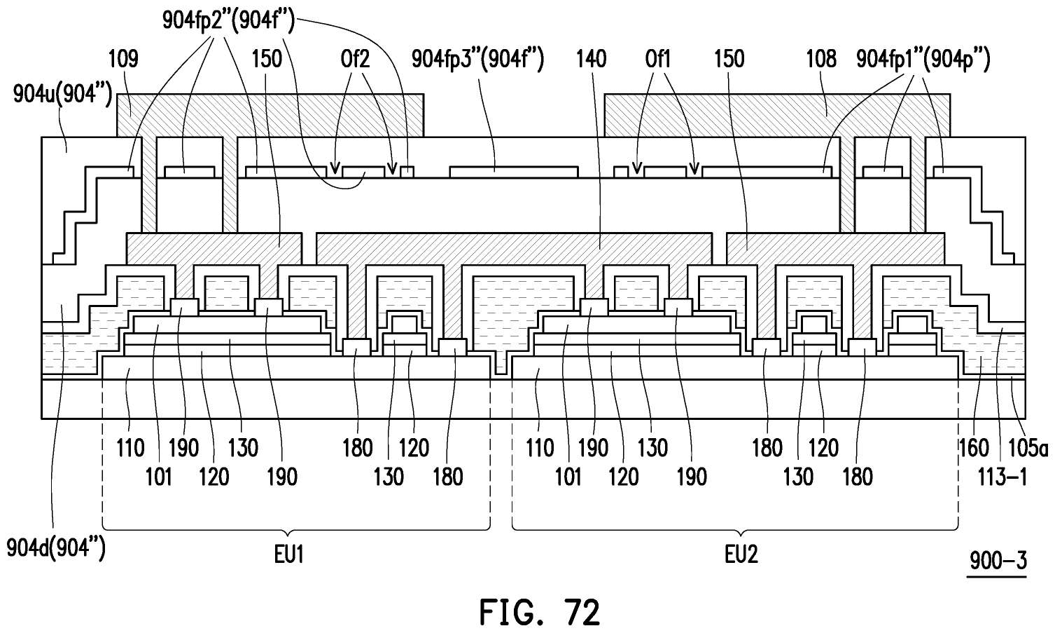

Referring to FIG. 72, a top view layout of an LED 900-3 of FIG. 72 is generally similar to the top view layout of the LED 900 of FIG. 69 since a major difference therebetween is the layouts of the cross-sectional structures. Thereby, the repetitive descriptions of the top view layout are omitted. A cross-sectional structure layout of the LED 900-3 is generally similar to the cross-sectional structure layout of the LED 900. The major difference therebetween lies in that: in the LED 900-3, a functional layer 904f′ in a functional stacking layer 904″ includes a first function portion 904fp1″, a second function portion 904fp2″, and a third function portion 904fp3″ separated from one another. Since the functional layer 904″ includes the buffer layer, the first to the third function portions 904fp1″ to 904fp3″ are also called as a first to a third buffer portions. The first and the second function portion 904fp1″ and 904fp2″ respectively overlap with the first and the second bonding layers 108 and 109.

Note that the first and the second function portions 904f1″ and 904f2″ respectively include a plurality of through holes OF1 and OF2. Because of the design of the through holes OF1 and OF2 and the through holes OF1 overlapping with the first bonding layer 108 and the through holes OF2 overlapping with the second bonding layer 109, when the first and the second bonding layers 108 and 109 are bonded to an external circuit, areas of the first and the second function portions 904f1″ and 904f2″ overlapping with the first and the second bonding layers 108 and 109 are reduced. In this way, heat dissipation efficiency increases.

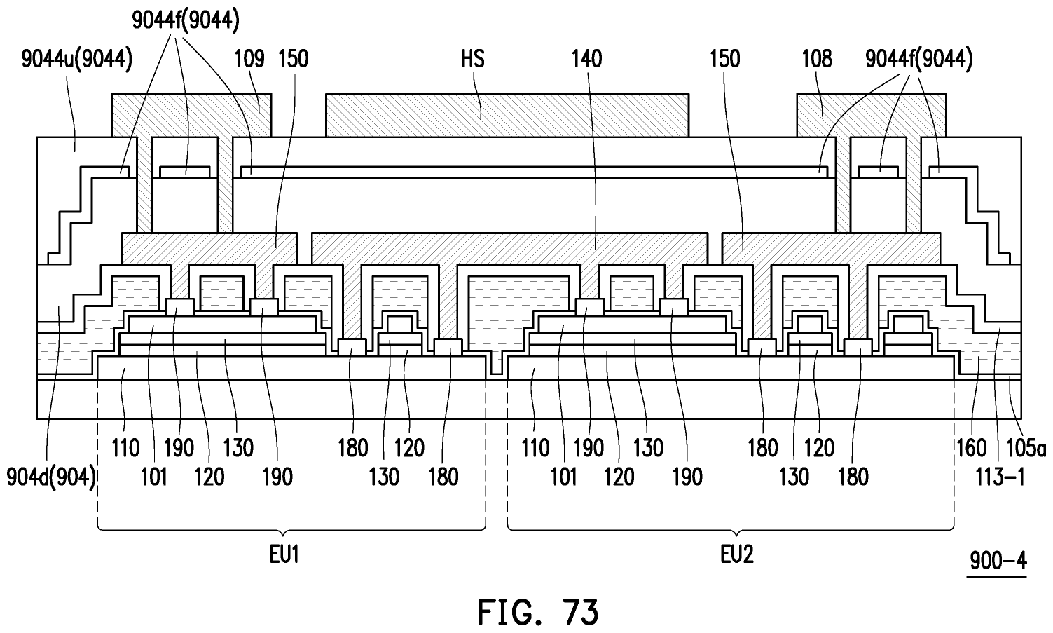

Referring to FIG. 73, a top view layout of an LED 900-4 of FIG. 73 is generally similar to the top view layout of the LED 900 of FIG. 69 since a major difference therebetween is the layouts of the cross-sectional structures. Thereby, the repetitive descriptions of the top view layout are omitted. A cross-sectional structure layout of the LED 900-4 is generally similar to the cross-sectional structure layout of the LED 900-3. The major difference therebetween lies in that: the LED 900-4 further includes a heat dissipation pad HS. Herein, a material of the heat dissipation pad HS is similar to the material of the first and the second bonding layers 108 and 109, and thereby, the repetitive descriptions are omitted. The heat dissipation pad HS is located between the first and the second bonding layers 108 and 109 and overlaps with a functional stacking layer 9044. Further, in the assembly process of the LED 900-4 and an external circuit, a device damage problem or an electricity leakage problem caused by the ability to withstand the force of the thimble produced by the die-bonding process may be prevented through the heat dissipation pad HS. Besides, the functional stacking layer 9044 includes an upper and a lower insulating layers 9044u and 9044d and a functional layer 9044f located between the upper and the lower insulating layers 9044u and 9044d. Herein, the functional layer 9044f includes the buffer layer and is a continuous buffer layer.

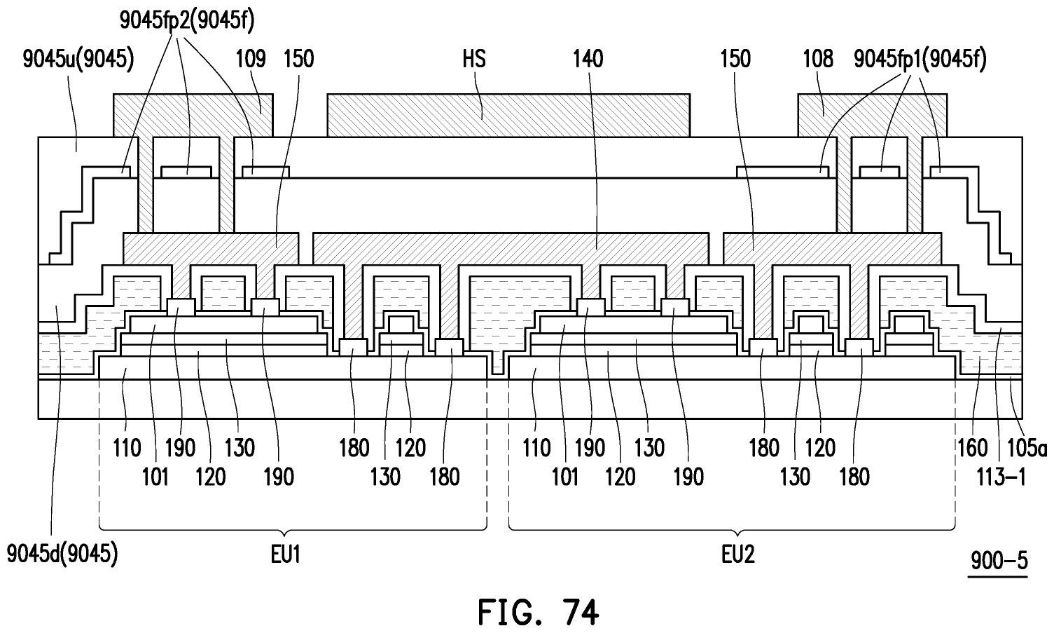

Referring to FIG. 74, a top view layout of an LED 900-5 of FIG. 74 is similar to the top view layout of the LED 900 of FIG. 69 since a major difference therebetween is the layouts of the cross-sectional structures. Thereby, the repetitive descriptions of the top view layout are omitted. A cross-sectional structure layout of the LED 900-5 is generally similar to the cross-sectional structure layout of the LED 900-4. The major difference therebetween lies in that: in a functional stacking layer 9045 of the LED 900-5, a functional layer 9045f includes a first and a second function portions 9045fp1 and 9045fp2 separated from each other, and the first and the second function portions 9045fp1 and 9045fp2 respectively overlap with the first and the second bonding layers 108 and 109. The heat dissipation pad HS does not overlap with the functional layer 9045f. In other words, the heat dissipation pad HS and the functional layer 9045f are displaced.

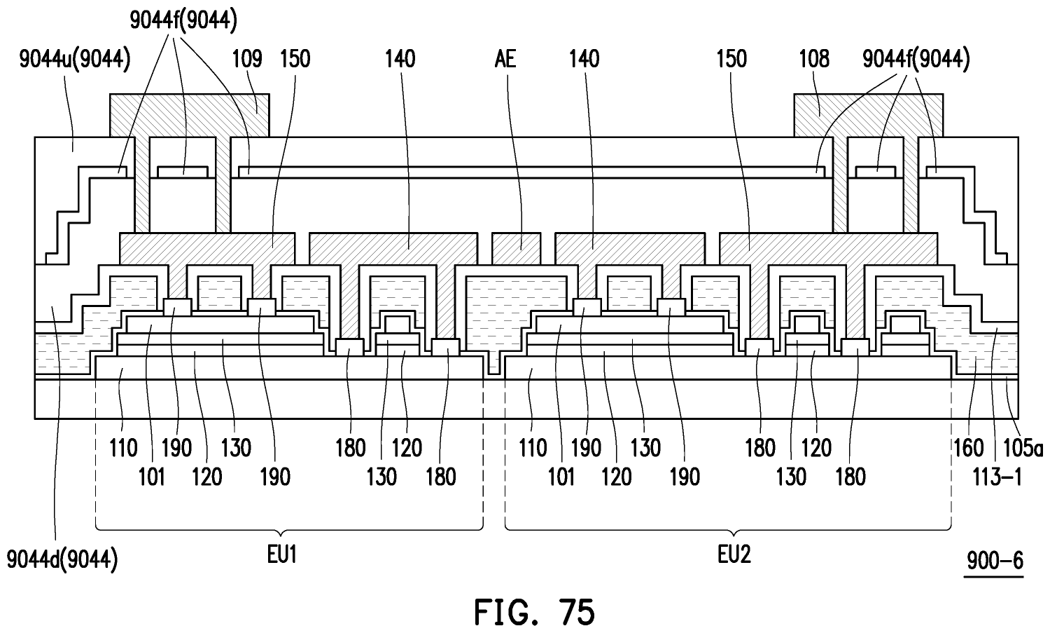

Referring to FIG. 75, a top view layout of an LED 900-6 of FIG. 75 is similar to the top view layout of the LED 900 of FIG. 69 since a major difference therebetween is the layouts of the cross-sectional structures. Thereby, the repetitive descriptions of the top view layout are omitted. A cross-sectional structure layout of the LED 900-6 is generally similar to the cross-sectional structure layout of the LED 900-4. The major difference therebetween lies in that: the LED 900-6 further includes an auxiliary electrode AE located between the first and the second current conducting layers 140 and 150 and overlaps with the functional layer 9044f. A material of the auxiliary electrode AE is generally similar to that of the first and the second current conducting layers 140 and 150, and thereby, the repetitive descriptions are omitted. Further, in the assembly process of the LED 900-6 and an external circuit, a device damage problem or an electricity leakage problem caused by the ability to withstand the force of the thimble produced by the die-bonding process may be prevented through the auxiliary electrode AE. Besides, the heat dissipation pad HS is not disposed on the LED 900-6.

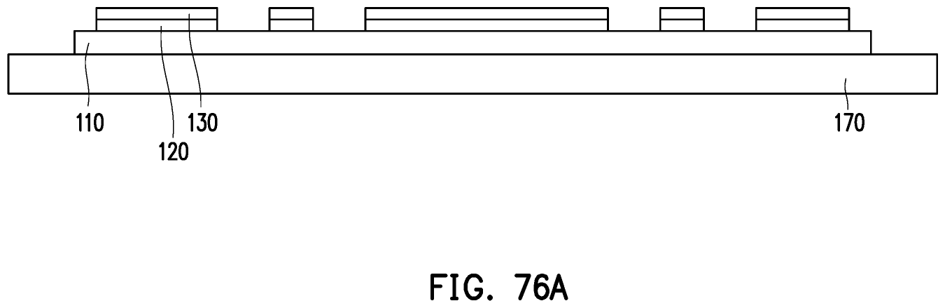

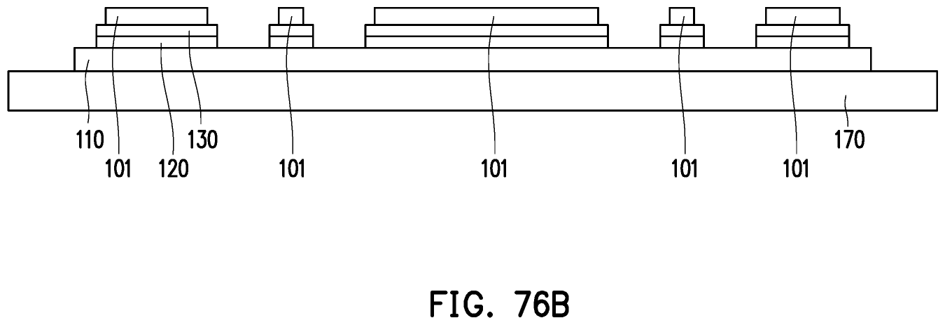

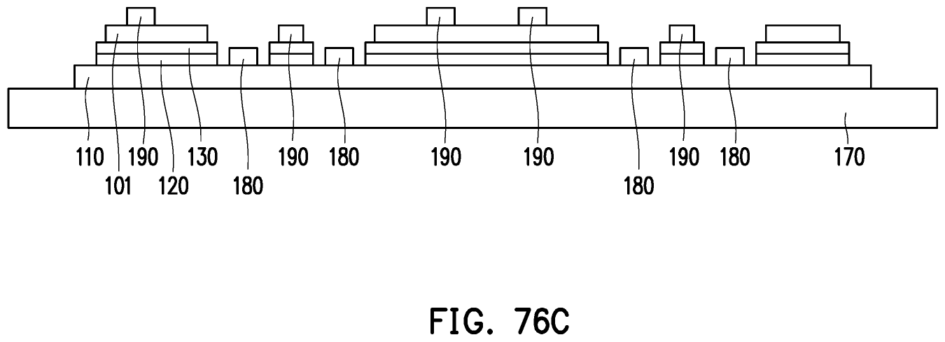

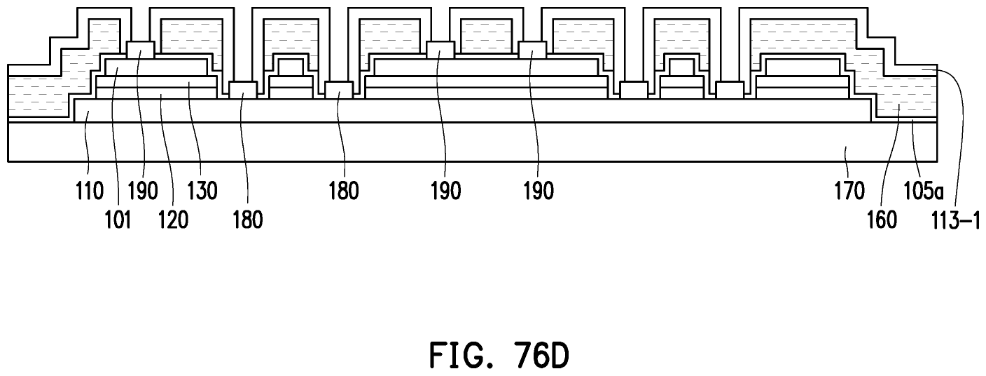

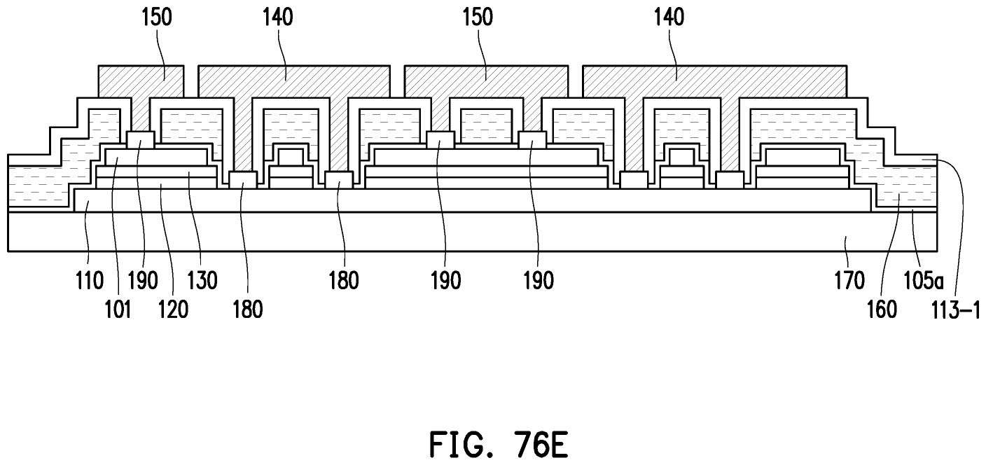

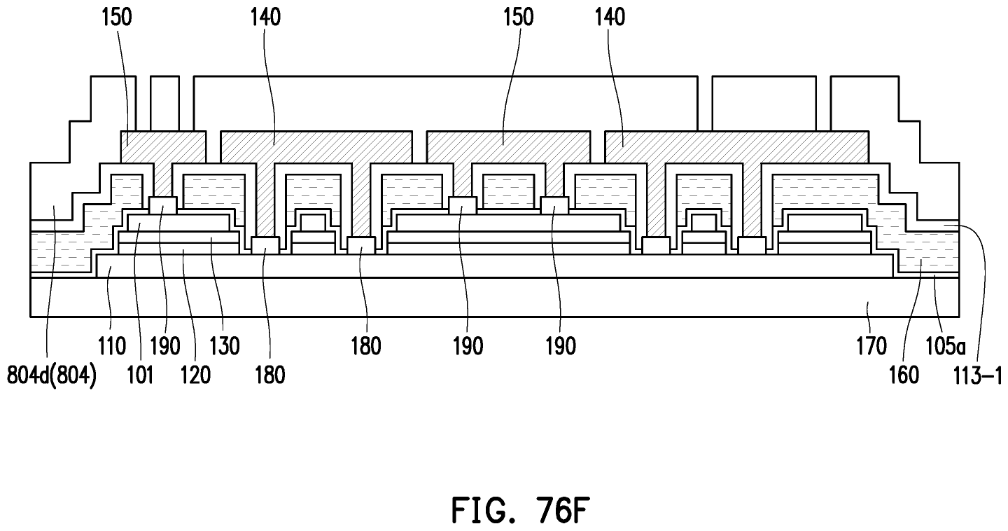

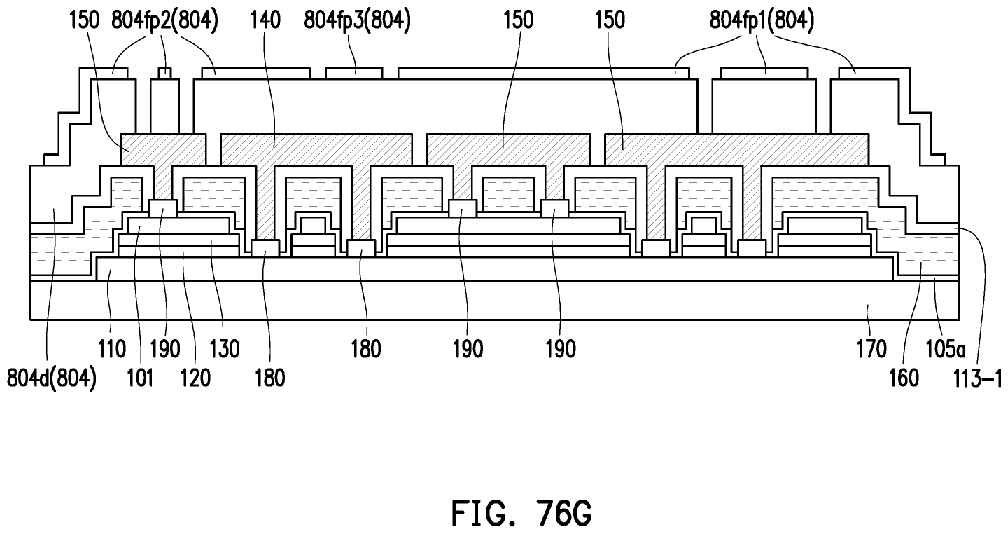

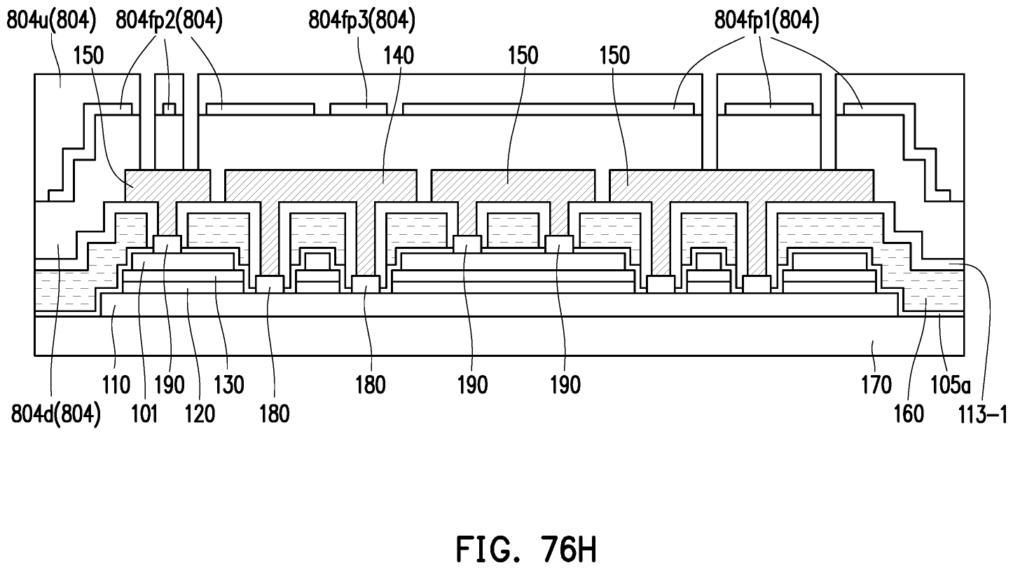

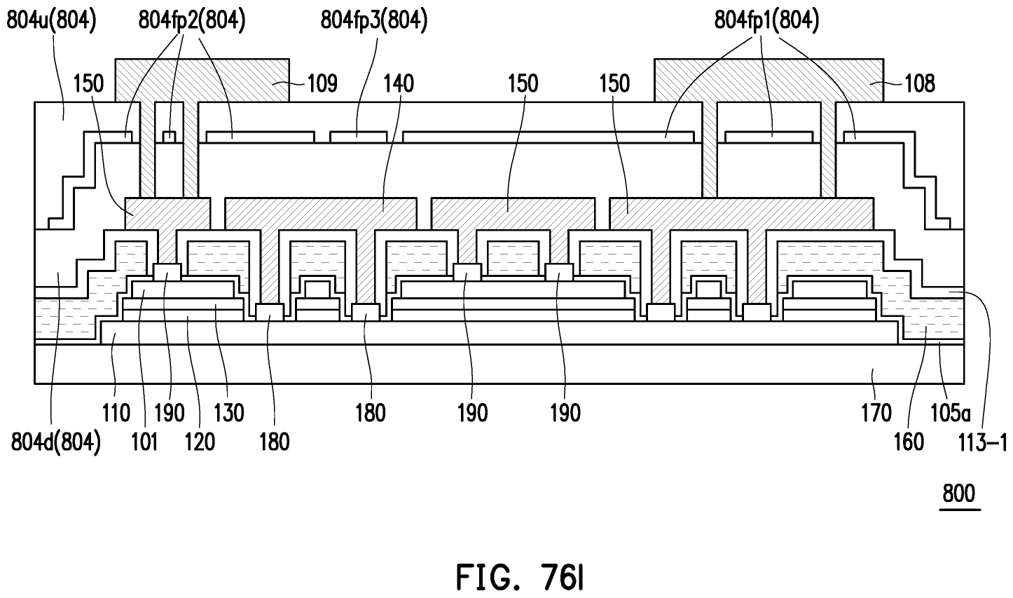

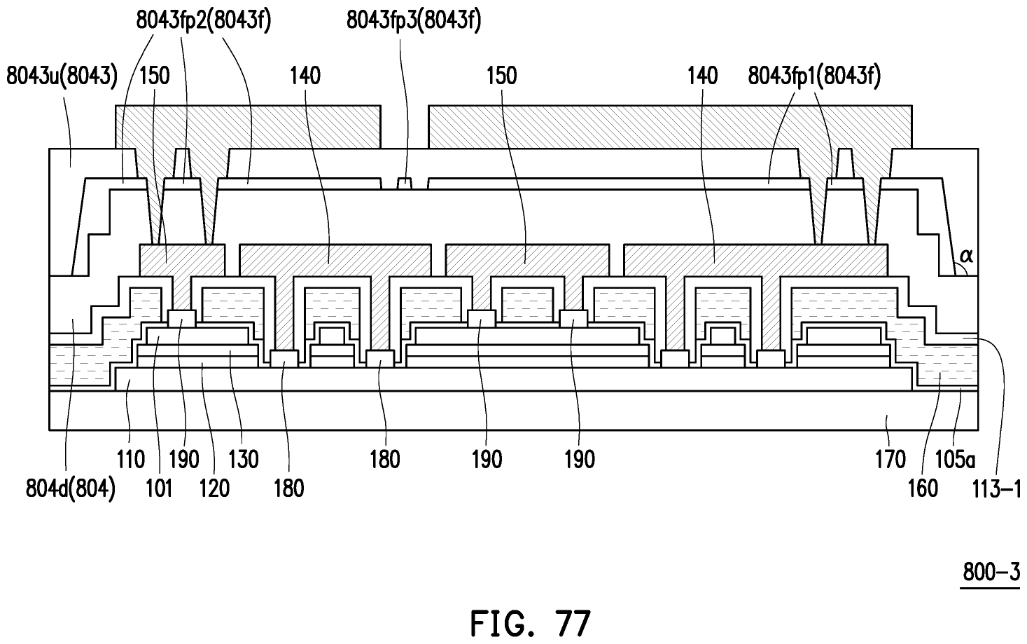

FIG. 76A to FIG. 76I are flowcharts illustrating manufacturing of the LED 800 of FIG. 66.

Referring to FIG. 76A, the first-type semiconductor layer 110, the light emitting layer 120, and the second-type semiconductor layer 130 are sequentially formed on the growth substrate 170, and Parts of the light emitting layer 120 and the second-type semiconductor layer 130 are etched, so that a partial surface of the first-type semiconductor layer 110 is exposed.

Referring to FIG. 76B, the conductive layer 101 is formed on the second-type semiconductor layer 130.

Referring to FIG. 76C, the first and the second metal layers 180 and 190 are respectively formed on the exposed surface of the first-type semiconductor layer 110 and the conductive layer 101, so that the first and the second metal layers 180 and 190 are electrically connected to the first-type semiconductor layer 110 and the conductive layer 101 respectively.

Referring to FIG. 76D, the first-type semiconductor layer 110, the light emitting layer 120, and the second-type semiconductor layer 130 may be treated as a light emitting unit. The insulating layer 105a, the Bragg reflector structure 160, and the insulating layer 113-1 are sequentially formed on the light emitting unit, and a part of the insulating layer 105a, a part of the Bragg reflector structure 160, and a part of the insulating layer 113-1 are etched to expose the first and the second metal layers 180 and 190.

Referring to FIG. 76E, the first and the second current conducting layers 140 and 150 are formed on the insulating layer 105a, the Bragg reflector structure 160, and the insulating layer 113-1, and the first and the second current conducting layers 140 and 150 are electrically connected to the first and the second metal layers 180 and 190 respectively.

Referring to FIG. 76F, the lower insulating layer 804d of the functional stacking layer 804 is formed, and a part of the lower insulating layer 804d is etched to expose parts of the first and the second current conducting layers 140 and 150.

Referring to FIG. 76G, the functional layer 804f of the functional stacking layer 804 is formed on the lower insulating layer 804d, and a part of the functional layer 804f is etched to form the first, the second, and the third function portions 804fp1 to 804fp3 separated from one another.

Referring to FIG. 76H, the upper insulating layer 804u of the functional stacking layer 804 is formed on the functional layer 804f, so that the upper insulating layer 804u covers the functional layer 804f. Besides, a part of the upper insulating layer 804u is etched to expose parts of the first and the second current conducting layers 140 and 150.

Referring to FIG. 76I, the first and the second bonding layers 108 and 109 are formed to be electrically connected to the first and the second current conducting layers 140 and 150 respectively. Manufacturing of the LED 800 is generally completed so far.

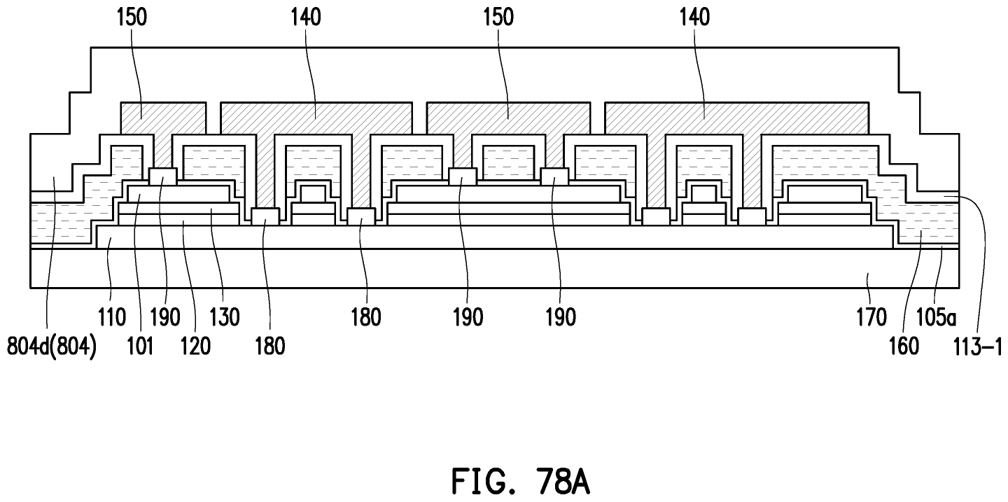

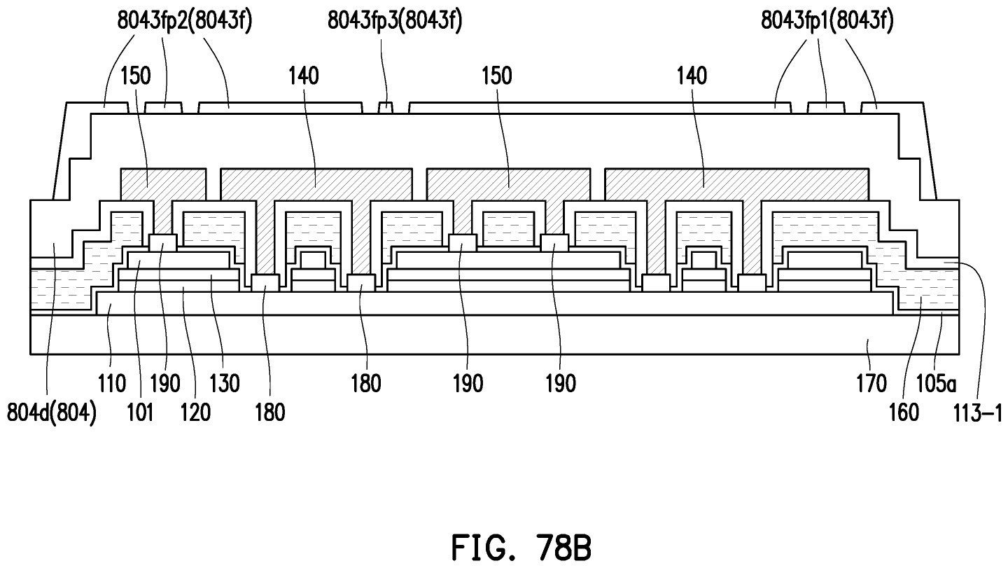

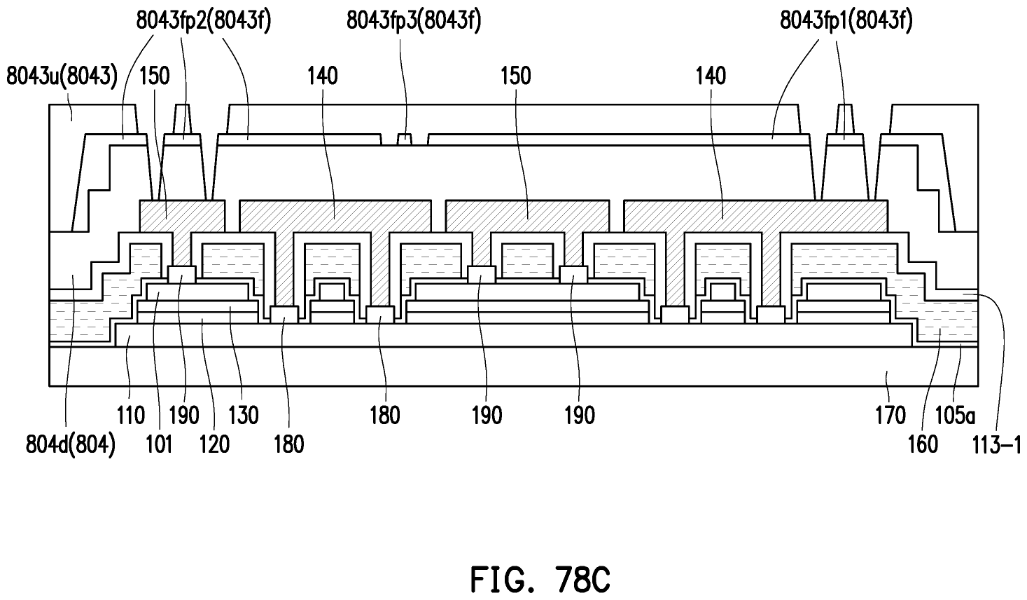

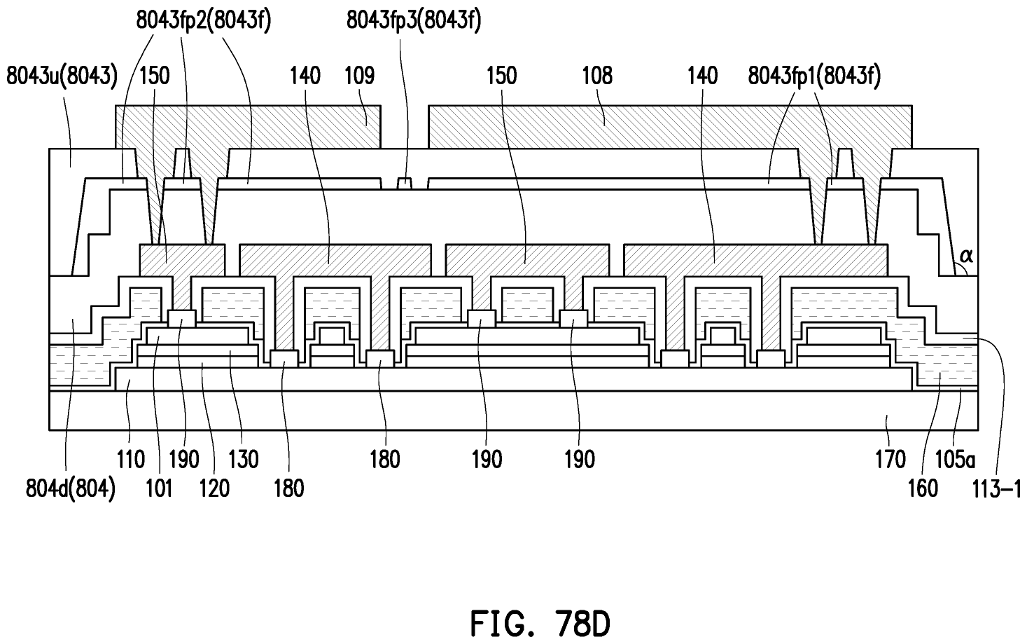

FIG. 77 is a schematic cross-sectional view of an LED according to an embodiment of the invention. FIG. 78A to FIG. 78D are partial flowcharts of manufacturing the LED of FIG. 77.

Referring to FIG. 77, an LED 800-3 of FIG. 77 is generally similar to the LED 800 of FIG. 66. The major difference therebetween lies in that: in the LED 800-3, a functional stacking layer 8043 includes an upper and a lower insulating layers 8043u and 8043d and a functional layer 8043f located between the upper and the lower insulating layers 8043u and 8043d. Herein, the functional layer 8043f is a buffer layer. In other words, the functional layer 8043f includes a first to a third function portions 8043fp1 to 8043fp3 separated from one another, which may also be called as the first to the third buffer portions.

It should be noted that the first function portion 8043fp1 is disposed between the first bonding layer 180 and the first current conducting layer 140, the second function portion 8043fp2 is disposed between the second bonding layer 190 and the second current conducting layer 140, and the first and the second function portions 8043fp1 and 8043fp2 are both buffer portions. In this way, a difference in polarity between the second bonding layer 190 and the first current conducting layer 140 may be reduced, and a short circuit problem caused by a difference in polarity between the first bonding layer 180 and the second current conducting layer 150 may also be solved. In addition, an obtuse angle α is provided between the functional layer 8043f and the lower insulating layer 8043d. Herein, the obtuse angle α preferably falls in a range from 120 degrees to 150 degrees.

In the following paragraph, a manufacturing method of the LED 800-3 of FIG. 77 is described.

Referring to FIG. 78A, a manufacturing method of manufacturing a structure of FIG. 78A may be found with reference to the manufacturing method shown in FIG. 76A to FIG. 76F, and thereby, the repetitive descriptions are omitted.

Referring to FIG. 78B, the functional layer 8043f of the functional stacking layer 8043 is formed on the lower insulating layer 8043d, and a part of the functional layer 8043f is etched to form the first, the second, and the third function portions 8043fp1 to 8043fp3 separated from one another. Herein, the functional layer 8043f includes the buffer layer. In an embodiment, the material of the buffer layer may be a photosensitive material, polyimide, or a polymer material. The buffer layer may be formed by a light source (for example, a light source that can emit light beams with a main emission wavelength of 300, 405, 436, or less than 300 nm) and then through a yellow light lithography process. Moreover, the buffer layer is subjected to a heat curing process next. A heating temperature is preferably not greater than 500 degrees (the heating temperature range most preferably falls from 200 degrees to 300 degrees) to cure the above-mentioned photosensitive material, polyimide, or polymer material.

Referring to FIG. 78C, the upper insulating layer 8043u of the functional stacking layer 8043 is formed on the functional layer 8043f, so that the upper insulating layer 8043u covers the functional layer 8043f. Besides, a part of the upper insulating layer 8043u is etched to expose parts of the first and the second current conducting layers 140 and 150.

Referring to FIG. 78D, the first and the second bonding layers 108 and 109 are formed on the functional layer 8043f to be electrically connected to the first and the second current conducting layers 180 and 190. Manufacturing of the LED 800-3 is generally completed so far.

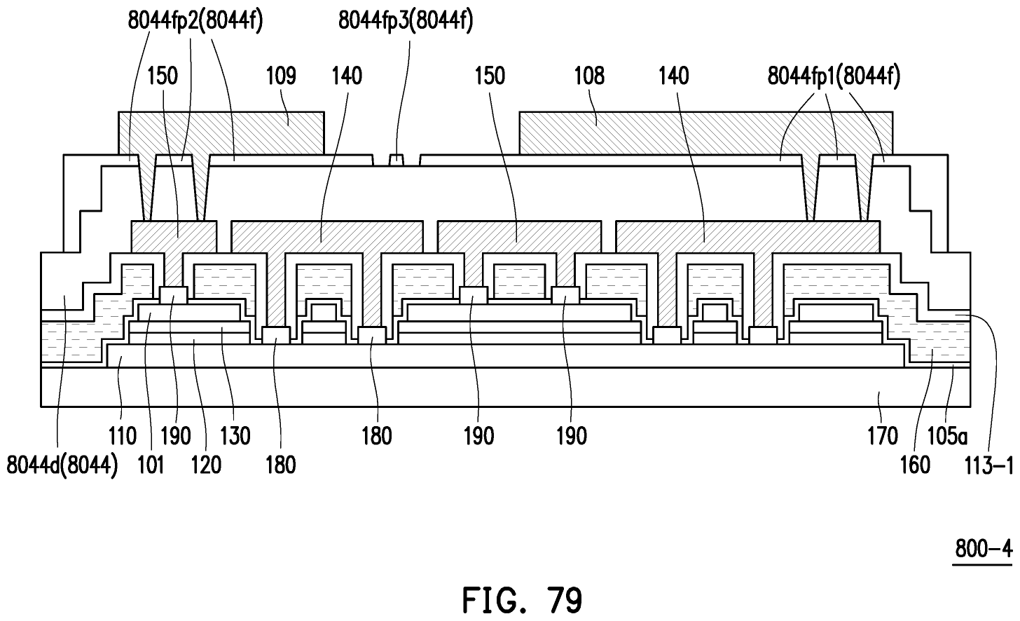

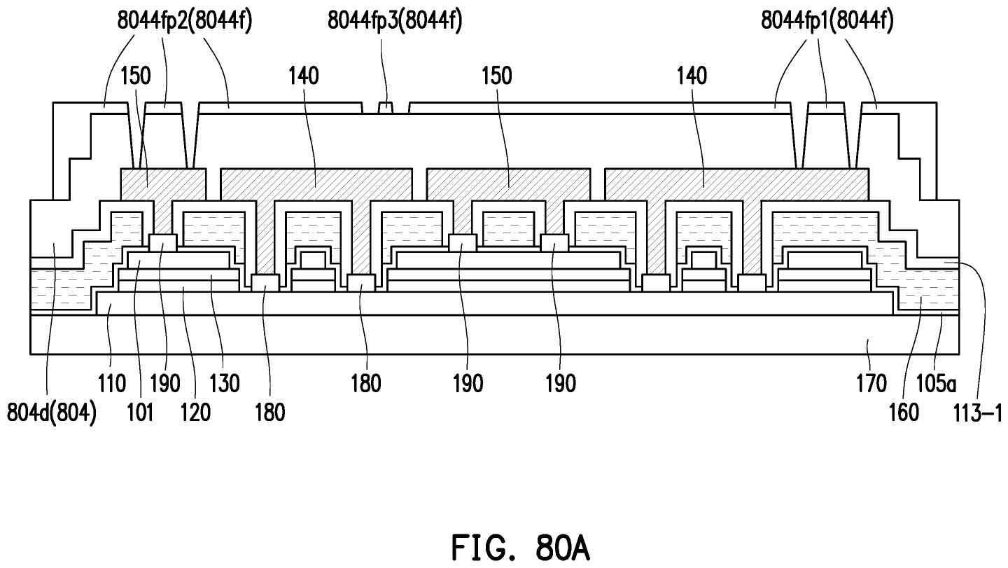

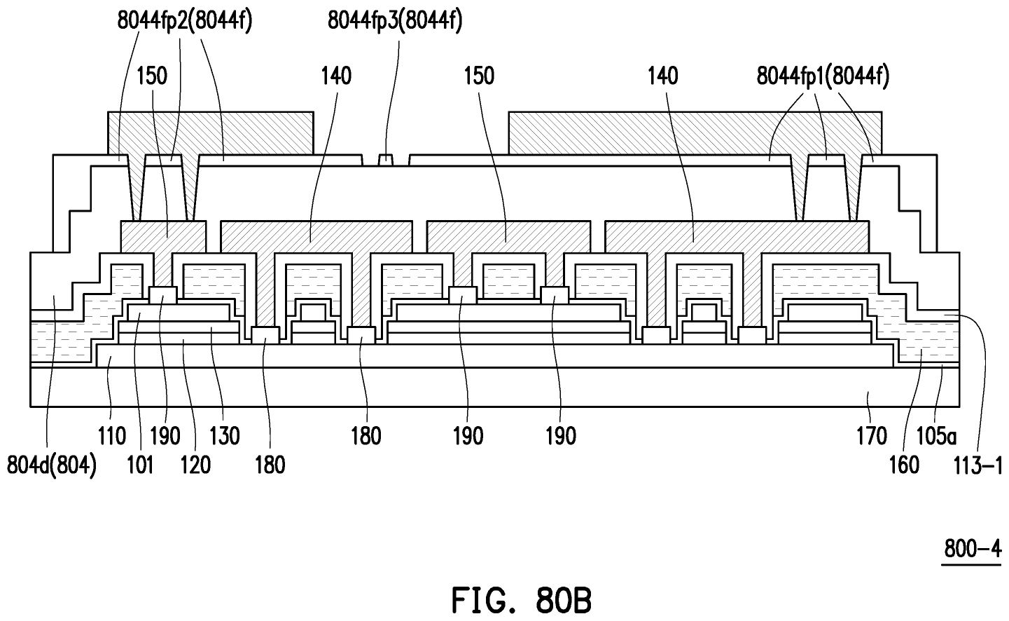

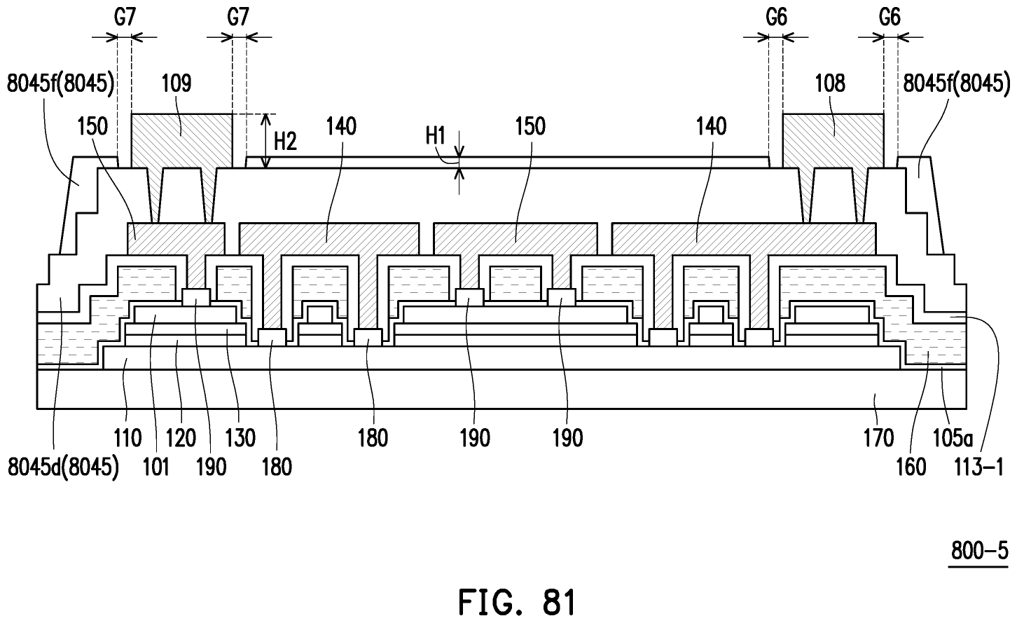

FIG. 79 is a schematic cross-sectional view of an LED according to an embodiment of the invention. FIG. 80A to FIG. 80B are partial flowcharts of manufacturing the LED of FIG. 79.

Referring to FIG. 79, an LED 800-4 of FIG. 79 is generally similar to the LED 800-3 of FIG. 77. The major difference therebetween lies in that: in the LED 800-4, a functional stacking layer 8044 includes two layers of stacked layers, that is, a lower insulating layer 8044d and a functional layer 8044f, and does not include an upper insulating layer as shown in FIG. 77. In other words, a number of the at least one insulating layer of the functional stacking layer 8044 is one. The lower insulating layer 8044d is disposed at one side of the functional layer 8044f. Moreover, the first bonding layer 108 and the second bonding layer 109 are in contact with an upper surface and a side surface of the functional layer 8044f directly.

In the following paragraph, a manufacturing method of the LED 800-4 of FIG. 79 is described.

Referring to FIG. 80A, a manufacturing method of manufacturing a structure of FIG. 80A may be found with reference to the manufacturing method shown in FIG. 76A to FIG. 76F and FIG. 78, and thereby, the repetitive descriptions are omitted.

Referring to FIG. 80B, the first and the second bonding layers 108 and 109 are formed on the functional layer 8044f to be electrically connected to the first and the second current conducting layers 180 and 190. Manufacturing of the LED 800-4 is generally completed so far.

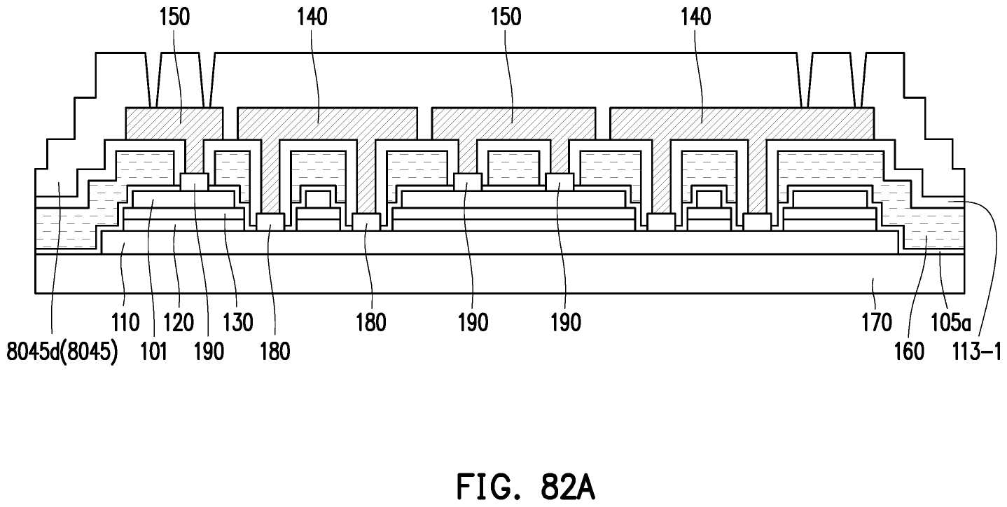

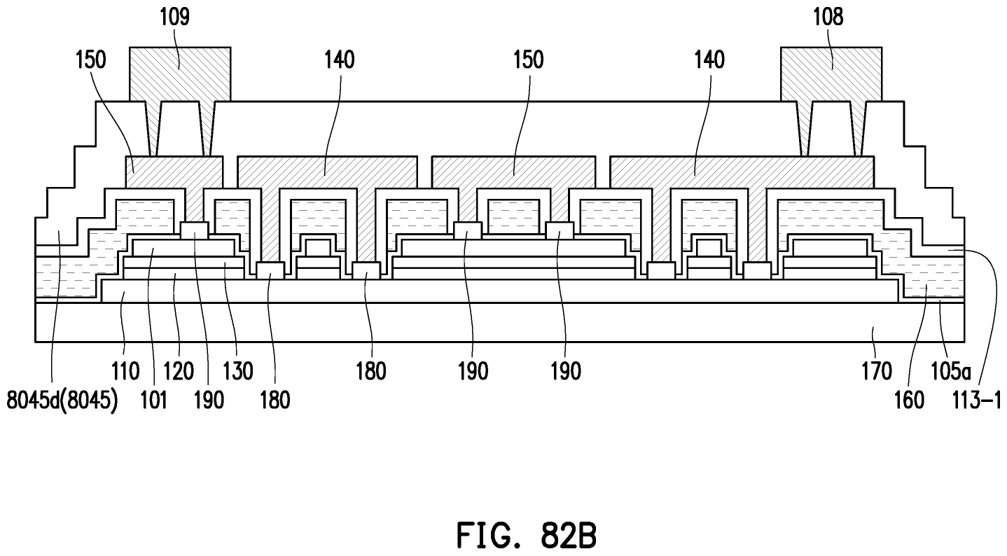

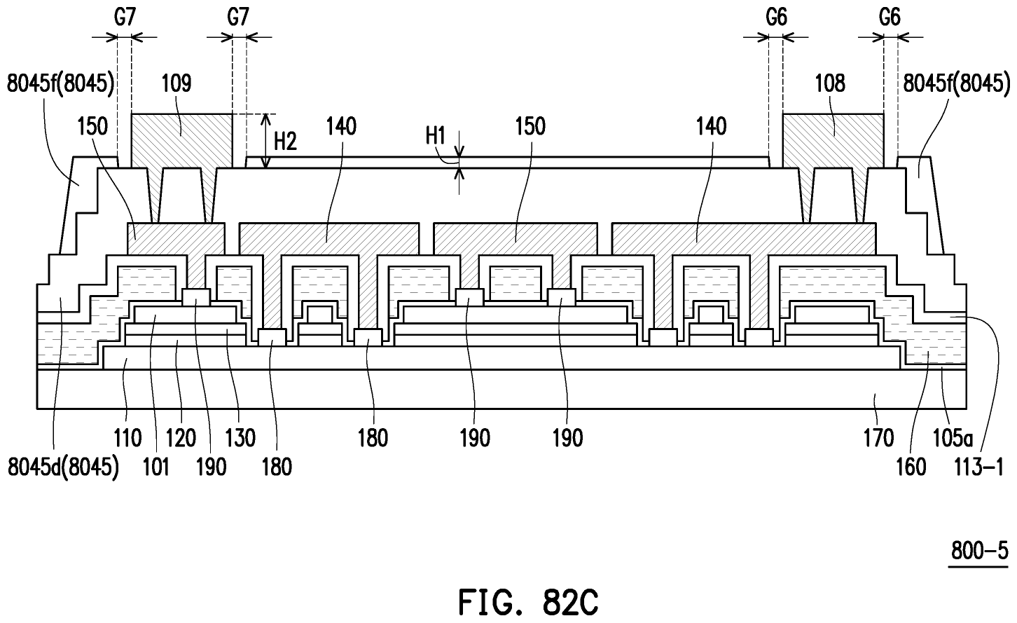

FIG. 81 is a schematic cross-sectional view of an LED according to an embodiment of the invention. FIG. 82A to FIG. 82C are partial flowcharts of manufacturing the LED of FIG. 81.

Referring to FIG. 81, an LED 800-5 of FIG. 81 is generally similar to the LED 800-4 of FIG. 79. The major difference therebetween lies in that: the first bonding layer 108 and the second bonding layer 109 are in contact with an upper surface of a lower insulating layer 8045d of a functional stacking layer 8045 directly, and the first bonding layer 108 and the second bonding layer 109 and the functional layer 8045f (the buffer layer) of the functional stacking layer 8045 are displaced. Further, a gap G6 exists between the functional layer 8045f and the first bonding layer 108, and a gap G7 exists between the functional layer 8045f and the second bonding layer 109. Besides, a height H2 of the first bonding layer 108 and the second bonding layer 109 is greater than a height H1 of the functional layer 8045f.

In the following paragraph, a manufacturing method of the LED 800-5 of FIG. 81 is described.

Referring to FIG. 82A, continuing the step of FIG. 76E, the lower insulating layer 8045d of the functional stacking layer 8045 is formed on the first and the second current conducting layers 140 and 150, and the lower insulating layer 8045d is etched to expose parts of the first and the second current conducting layers 140 and 150.

Referring to FIG. 82B, the first and the second bonding layers 108 and 109 are formed to be electrically connected to the first and the second current conducting layers 140 and 150 respectively.

Referring to FIG. 82C, the functional layer 8045f of the functional stacking layer 8045 is formed on the lower insulating layer 8045d, and the functional layer 8045f is a continuous buffer layer herein. Manufacturing of the LED 800-5 is generally completed so far.

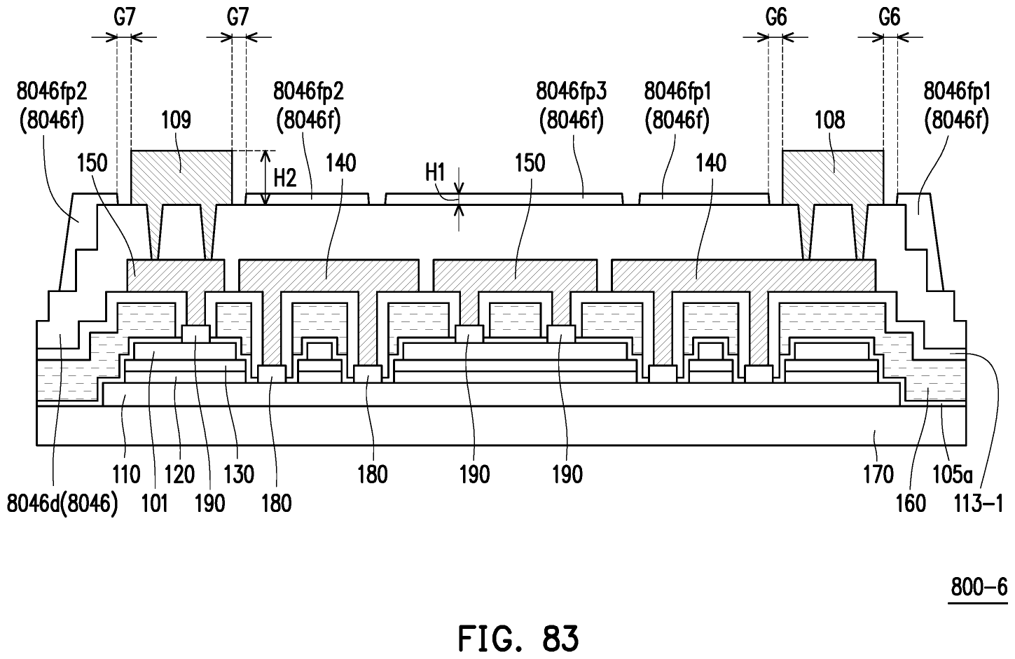

FIG. 83 is a schematic cross-sectional view of an LED according to another embodiment of the invention.

Referring to FIG. 83, an LED 800-6 of FIG. 83 is generally similar to the LED 800-5 of FIG. 81. The major difference therebetween lies in that: a functional layer 8046f (the buffer layer) includes a first, a second, and a third function portions 8046fp1 to 8046fp3 separated from one another. Herein, a gap G6 exists between the first function portion 8046fp1 and the first bonding layer 108, a gap G7 exists between the second function portion 8046fp2 and the second bonding layer 109, and the third function portion 8046fp3 is located between the first function portion 8046fp1 and the second function portion 8046fp2. In addition, a manufacturing method of manufacturing the LED 800-6 is generally similar to the method of manufacturing the LED 800-5. The major difference therebetween lies in that: when the functional layer 8046f is manufactured, etching is performed, so that the functional layer 8046f forms the first, the second, and the third function portions 8046fp1 to 8046fp3 separated from one another.

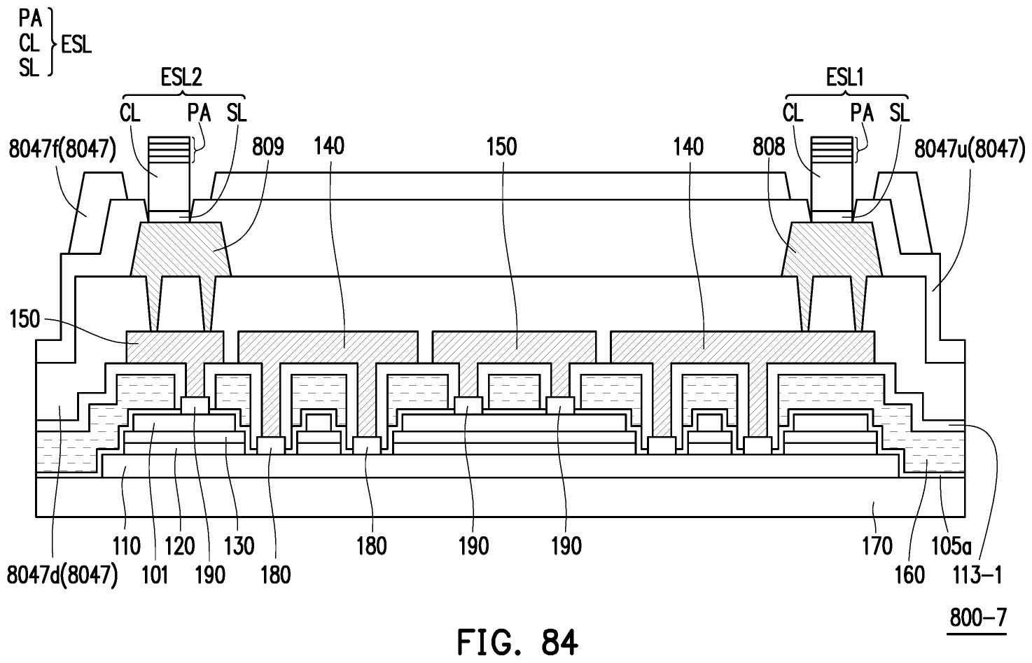

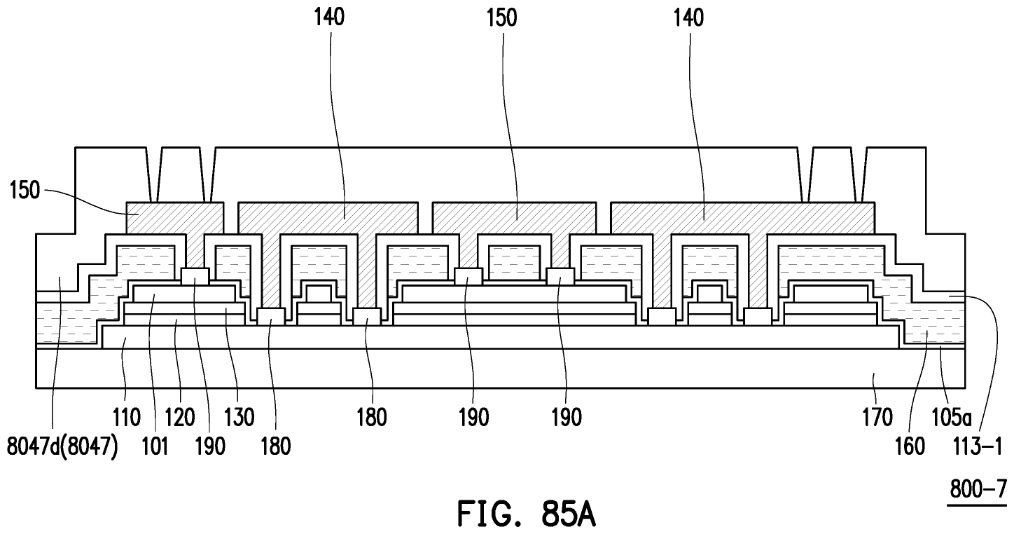

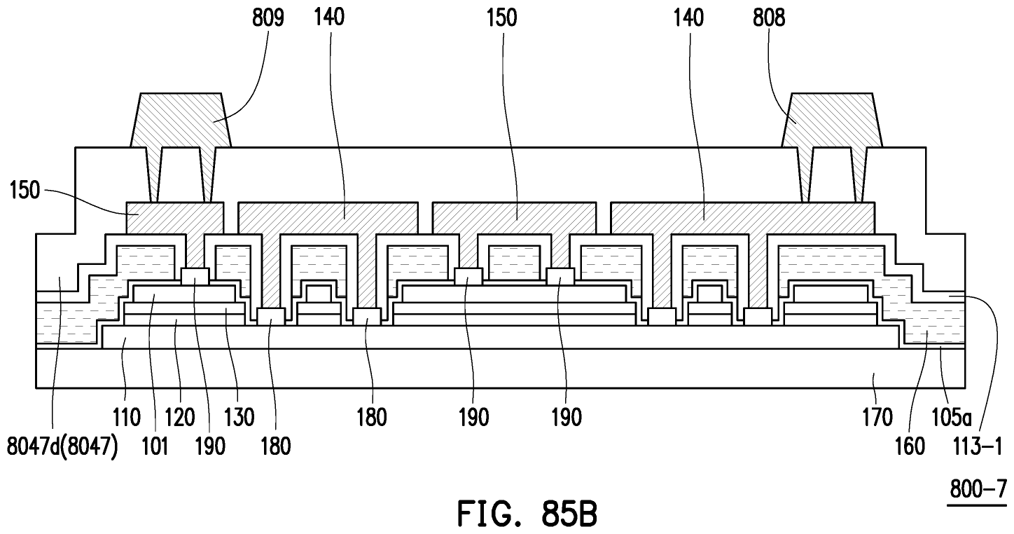

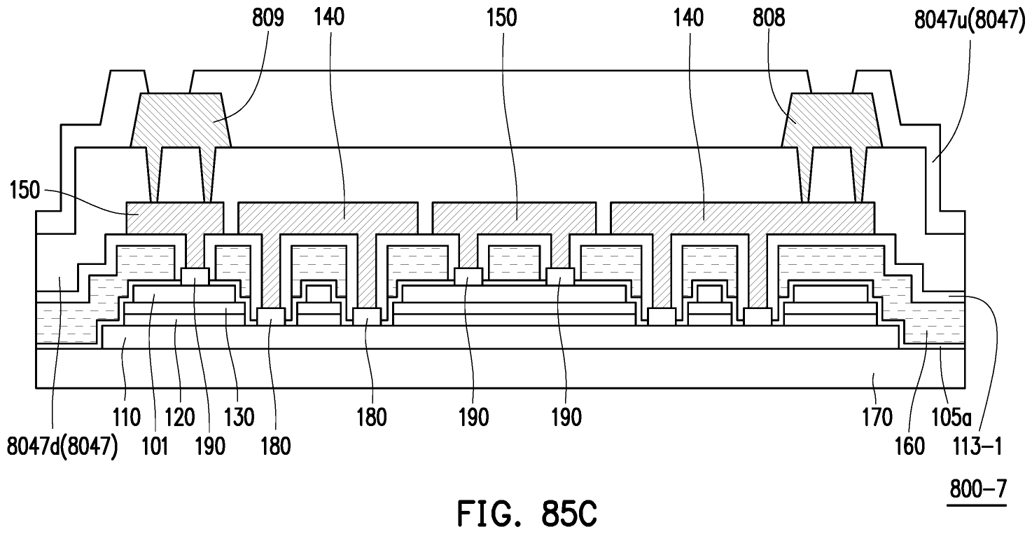

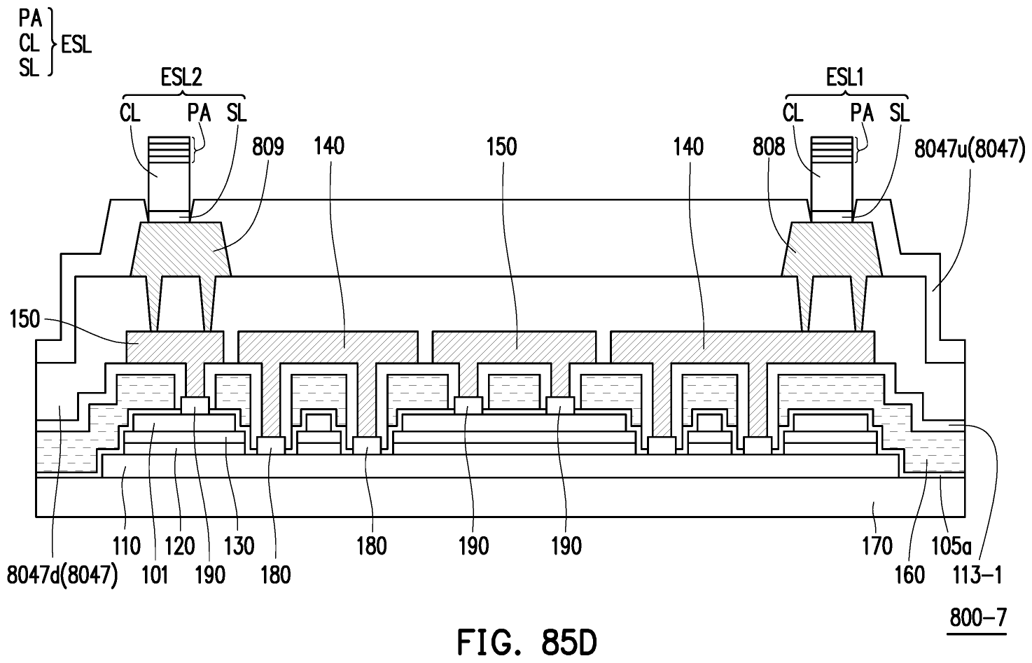

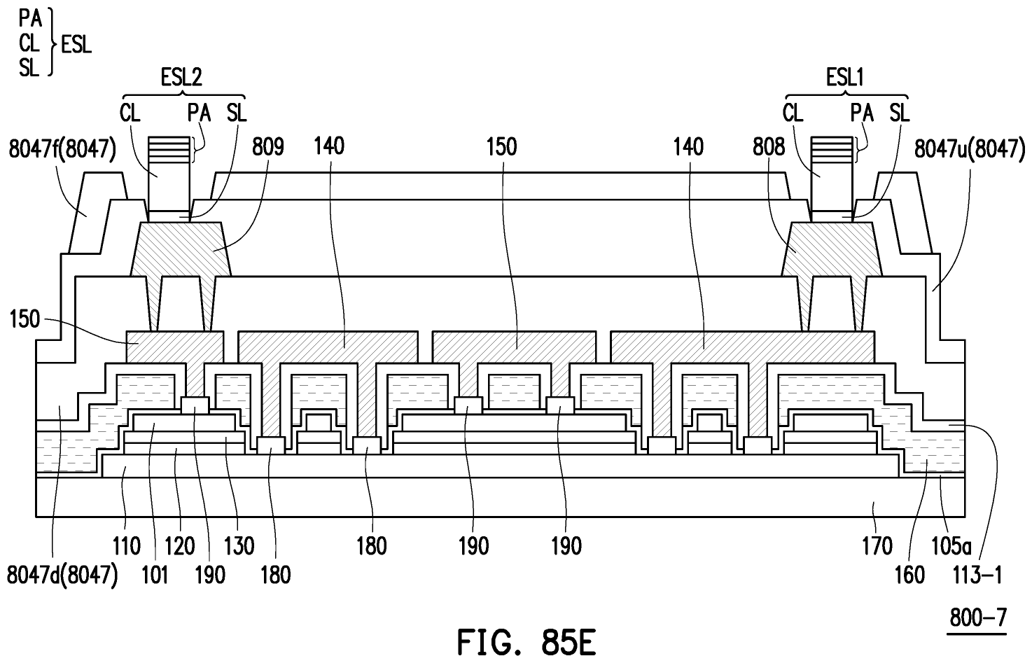

FIG. 84 is a schematic cross-sectional view of an LED according to still another embodiment of the invention. FIG. 85A to FIG. 85E are schematic partial flowcharts of manufacturing the LED of FIG. 84.

Referring to FIG. 84, an LED 800-7 of FIG. 84 is generally similar to the LED 800-5 of FIG. 81. The major difference therebetween lies in that: in the LED 800-7, a number of at least one insulating layer of a functional stacking layer 8047 is two, and the insulating layers are called as a first and a second insulating layers 8047u and 8047d, for example. The first insulating layer 8047u is located between the second insulating layer 8047d and the second-type semiconductor layer 130. A first bonding layer 808 is covered by the first insulating layer 8047u and the second insulating layer 8047d together. A second bonding layer 809 is covered by the first insulating layer 8047u and the second insulating layer 8047d together.

In addition, the LED 800-7 further includes a plurality of electrode stacked layers ESL. The electrode stacked layers ESL include a first electrode stacked layer ESL1 and a second electrode stacked layer ESL2 electrically connected to the first bonding layer 808 and the second bonding layer 809 respectively, and the first electrode stacked layer ESL1 and the second electrode stacked layer ESL2 and a functional layer 8047f are displaced. Each of the electrode stacked layers ESL includes an adhesive layer SL, a protection layer PL, and a connection layer CL. The connection layer CL connects the adhesive layer SL and the protection layer PL, and each of the electrode stacked layers ESL is electrically connected to the corresponding bonding layer 808 (809) via the adhesive layer SL.

In the present embodiment, a material of the first and the second bonding layers 808 and 809 is slightly different from that of the aforementioned first and second bonding layers 108 and 109. The material of the first and the second bonding layers 808 and 809 includes Ti, Al, Pt, Ni, Au, or Sn. A material of the adhesive layer SL includes Al, Ti, Ni, Pt, or a combination stacked layer of the foregoing. A material of the connection layer CL includes Au, Cu, Sn, Alloy Sn/Ag/Cu, Alloy Au/Sn, or a combination stacked layer or an alloy layer of the foregoing. A material of the protection layer PL includes Al, Ti, Ni, Pt, Au, Alloy Au/Sn, or a combination stacked layer or an alloy layer of the foregoing.

In the following paragraph, a manufacturing method of the LED 800-7 of FIG. 84 is described.

Referring to FIG. 85A, a manufacturing method of manufacturing a structure of FIG. 85A may be found with reference to the manufacturing method shown in FIG. 82A, and thereby, the repetitive descriptions are omitted.

Referring to FIG. 85B, the first and the second bonding layers 808 and 809 are formed on the second insulating layer 8047d to be electrically connected to the first and the second current conducting layers 180 and 190.

Referring to FIG. 82C, the second insulating layer 8047u of the functional stacking layer 8047 is formed on the first insulating layer 8047d and the first and the second bonding layers 808 and 809, and a portion of the second insulating layer 8047u is etched, so that the first and the second bonding layers 808 and 809 are exposed.

Referring to FIG. 82D, the first and the second electrode stacked layers ESL1 and ESL2 are formed on the first and the second bonding layers 808 and 809 to be electrically connected to the first and the second bonding layers 808 and 809.

Referring to FIG. 82E, the functional layer 8047f of the functional stacking layer 8047 is formed on the lower insulating layer 8047d, and the functional layer 8047f is a continuous buffer layer herein. Moreover, the functional layer 8047f is subjected to a heat curing process. Herein, a temperature of the heat curing process falls from 150 degrees to 300 degrees, and a most preferable heat curing temperature is 260 degrees. Manufacturing of the LED 800-5 is generally completed so far.

In view of the above, in the LED of the embodiments of the invention, the at least one functional stacking layer is disposed, and the functional layer in the at least one functional stacking layer may be the reflector structure layer which is electrically floating or the buffer layer. When the functional layer is the reflector structure layer, increased light beams from the light emitting layer are emitted from the LED, and that light emission efficiency is improved. When the functional layer is the buffer layer, even though the LED may generate heat owing to long-term use and an internal device in the LED may generate thermal stress owing to such heat, an effect generated by such stress may be effectively reduced by the buffer layer. Therefore, the LED exhibits good device reliability. In addition, the manufacturing method of manufacturing the LED is also provided by the embodiments of the invention.

It will be apparent to those skilled in the art that various modifications and variations can be made to the disclosed embodiments without departing from the scope or spirit of the invention. In view of the foregoing, it is intended that the invention covers modifications and variations provided that they fall within the scope of the following claims and their equivalents.

What is claimed is:

1. A light emitting diode, comprising:
a first-type semiconductor layer;
a second-type semiconductor layer;
a light emitting layer, located between the first-type semiconductor layer and the second-type semiconductor layer;
a first metal layer, located on the first-type semiconductor layer and electrically connected to the first-type semiconductor layer;
a second metal layer, located on the second-type semiconductor layer and electrically connected to the second-type semiconductor layer;
a first current conducting layer, wherein the first metal layer is located between the first current conducting layer and the first-type semiconductor layer, and the first current conducting layer is electrically connected to the first-type semiconductor layer via the first metal layer;
a second current conducting layer, wherein the second metal layer is located between the second current conducting layer and the second-type semiconductor layer, and the second current conducting layer is electrically connected to the second-type semiconductor layer via the second metal layer;
at least one functional stacking layer disposed on the first-type semiconductor layer, the light emitting layer, and the second-type semiconductor layer, comprising at least one insulating layer and a functional layer stacked on each other, the functional layer comprising a reflector structure layer which is electrically floating or a buffer layer;
a first bonding layer, electrically connected to the first-type semiconductor layer via the first current conducting layer and the first metal layer; and
a second bonding layer, electrically connected to the second-type semiconductor layer via the second current conducting layer and the second metal layer.

2. The light emitting diode according to claim 1, wherein
the at least one functional stacking layer comprises a first functional stacking layer and a second functional stacking layer,
wherein the first functional stacking layer comprises a first upper insulating layer, a first functional layer, and a first lower insulating layer, and the second functional stacking layer comprises a second upper insulating layer, a second functional layer, and a second lower insulating layer, wherein the first functional layer comprises the reflector structure layer which is electrically floating, and the second functional layer comprises the buffer layer,
wherein the first functional stacking layer is located between the second-type semiconductor layer and the second functional stacking layer.

3. The light emitting diode according to claim 2, wherein the first current conducting layer and the second current conducting layer are located between the first functional stacking layer and the second functional stacking layer, and the first functional stacking layer is located between the first current conducting layer and the second-type semiconductor layer and is located between the second current conducting layer and the second-type semiconductor layer.

4. The light emitting diode according to claim 1, wherein the reflector structure layer comprises a first reflector structure portion, a second reflector structure portion, and a third reflector structure portion separated from one another,
wherein the first bonding layer overlaps with the first reflector structure portion, the second bonding layer overlaps with and the second reflector structure portion, and the third reflector structure portion is located between the first reflector structure portion and the second reflector structure portion.

5. The light emitting diode according to claim 4, wherein the light emitting diode further comprises a growth substrate, the first-type semiconductor layer, the light emitting layer, the second-type semiconductor layer, the first metal layer, the second metal layer, the first current conducting layer, the second current conducting layer, the at least one functional stacking layer, the first bonding layer, and the second bonding layer are disposed on the growth substrate, and a partial surface of the growth substrate is exposed by the first-type semiconductor layer, wherein the first reflector structure portion and the second reflector structure portion overlap with the partial surface.

6. The light emitting diode according to claim 4, wherein the light emitting diode further comprises a growth substrate, the first-type semiconductor layer, the light emitting layer, the second-type semiconductor layer, the first metal layer, the second metal layer, the first current conducting layer, the second current conducting layer, the at least one functional stacking layer, the first bonding layer, and the second bonding layer are disposed on the growth substrate, and a partial surface of the growth substrate is exposed by the first-type semiconductor layer, wherein the first reflector structure portion and the second reflector structure portion do not overlap with the partial surface.

7. The light emitting diode according to claim 4, wherein
the light emitting layer and the second-type semiconductor layer have a plurality of through holes, the first metal layer is disposed in the through holes,
the first bonding layer and the second bonding layer respectively overlap with the second-type semiconductor layer, and the first bonding layer and the second bonding layer and the first metal layer are respectively displaced.

8. The light emitting diode according to claim 4, wherein
parts of the first-type semiconductor layer, parts of the light emitting layer, and parts of the second-type semiconductor layer form a first light emitting unit, and
other parts of the first-type semiconductor layer, other parts of the light emitting layer, and other parts of the second-type semiconductor layer form a second light emitting unit, wherein the first light emitting unit is different from the second light emitting unit,
wherein the parts of the first-type semiconductor layer are separated from the other parts of the first-type semiconductor layer, the parts of the light emitting layer are separated from the other parts of the light emitting layer, and the parts of the second-type semiconductor layer are separated from the other parts of the second-type semiconductor layer,
wherein the first current conducting layer connects the first light emitting unit and the second light emitting unit so that the two are connected in series.

9. The light emitting diode according to claim 1, wherein the reflector structure layer is a continuous reflector structure layer,
parts of the first-type semiconductor layer, parts of the light emitting layer, and parts of the second-type semiconductor layer form a first light emitting unit, and
other parts of the first-type semiconductor layer, other parts of the light emitting layer, and other parts of the second-type semiconductor layer form a second light emitting unit, wherein the first light emitting unit is different from the second light emitting unit,
wherein the parts of the first-type semiconductor layer are separated from the other parts of the first-type semiconductor layer, the parts of the light emitting layer are separated from the other parts of the light emitting layer, and the parts of the second-type semiconductor layer are separated from the other parts of the second-type semiconductor layer,
wherein the first current conducting layer connects the first light emitting unit and the second light emitting unit so that the two are connected in series.

10. The light emitting diode according to claim 1, wherein the buffer layer comprises a first buffer portion, a second buffer portion, and a third buffer portion separated from one another,
wherein the first bonding layer overlaps with the first buffer portion, the second bonding layer overlaps with the second buffer portion, and the third buffer portion is located between the first buffer portion and the second buffer portion.

11. The light emitting diode according to claim 10, wherein a plurality of through holes of the first buffer portion overlap with the first bonding layer, and a plurality of through holes of the second buffer portion overlap with the second bonding layer.

12. The light emitting diode according to claim 10, wherein the light emitting diode further comprises a heat dissipation pad located on the functional stacking layer and located between the first electrode pad and the second electrode pad, wherein the heat dissipation pad does not overlap with the first buffer portion and the second buffer portion.

13. The light emitting diode according to claim 10, wherein the light emitting diode further comprises a heat dissipation pad located on the functional stacking layer and located between the first electrode pad and the second electrode pad, wherein the heat dissipation pad overlaps with the third buffer portion.

14. The light emitting diode according to claim 1, wherein the first bonding layer and the second bonding layer respectively overlap with the second-type semiconductor layer.

15. The light emitting diode according to claim 1, wherein the at least one insulating layer of the at least one functional stacking layer comprises a first insulating layer and a second insulating layer, wherein the second insulating layer is located between the functional layer and the first insulating layer, and the first insulating layer is located between the second insulating layer and the second-type semiconductor layer,
wherein the first bonding layer is covered by the first insulating layer and the second insulating layer together, and the second bonding layer is covered by the first insulating layer and the second insulating layer together.

16. The light emitting diode according to claim 1, further comprising a plurality of electrode stacked layers, wherein the electrode stacked layers comprise a first electrode stacked layer and a second electrode stacked layer electrically connected to the first bonding layer and the second bonding layer respectively, and the first electrode stacked layer and the second electrode stacked layer and the functional layer are displaced
wherein each of the electrode stacked layers comprises an adhesive layer, a protection layer, and a connection layer, the connection layer connects the adhesive layer and the protection layer, and each of the electrode stacked layers is electrically connected to the corresponding bonding layer via the adhesive layer.

17. A manufacturing method of a light emitting diode, comprising:
forming at least one light emitting unit on a growth substrate, wherein each of the at least one light emitting unit comprises a first-type semiconductor layer, a second-type semiconductor layer, and a light emitting layer located between the first-type semiconductor layer and the second-type semiconductor layer;
forming a first insulating layer on the at least one light emitting unit and a groove of the growth substrate, wherein the first insulating layer covers a side wall of the first-type semiconductor layer of each of the at least one light emitting unit and has a plurality of first through holes and a plurality of second through holes;
forming a plurality of first current conducting layers and a plurality of second current conducting layers filled into the first through holes and the second through holes respectively, so as to be electrically connected to the first-type semiconductor layer and the second-type semiconductor layer of the at least one light emitting unit respectively;
forming at least one functional stacking layer on the at least one light emitting unit, wherein the at least one functional stacking layer comprises an upper insulating layer, a lower insulating layer, and a functional layer located between the upper insulating layer and the lower insulating layer, wherein the functional layer comprises a reflector structure layer which is electrically floating or a buffer layer, and the at least one functional stacking layer has a plurality of third through holes;
forming a first bonding layer and a second bonding layer on the at least one functional stacking layer, wherein the first bonding layer and the second bonding layer respectively are filled into some of the third through holes, so as to be electrically connected to first current conducting layers and the second current conducting layers respectively; and
dividing the growth substrate along the groove of the growth substrate to form a plurality of light emitting diodes.

18. The manufacturing method of the light emitting diode according to claim 17, wherein the step of forming the at least one functional stacking layer is performed after the step of forming the first current conducting layers and the second current conducting layers is performed.

19. The manufacturing method of the light emitting diode according to claim 17, wherein the step of forming the at least one functional stacking layer is performed before the step of forming the first current conducting layers and the second current conducting layers is performed.

20. The manufacturing method of the light emitting diode according to claim 17, wherein in the step of forming the at least one functional stacking layer, a number of the at least one functional stacking layer to be formed is plural, the step of forming the first current conducting layers and the second current conducting layers is performed next after some of the functional stacking layers are formed, and the step of forming the other functional stacking layers is then performed.
